(19) United States
(12) Patent Application Publication
(10) Pub. No.: US 2026/0247789 A1
(43) Pub. Date: Aug. 20, 2026

(54) COMPOUND AND ORGANIC LIGHT-EMITTING DEVICE COMPRISING SAME

(71) Applicant: LG CHEM, LTD., Seoul (KR)

(72) Inventors: Yongbum CHA, Daejeon (KR); Kyunghee KIM, Daejeon (KR); Moung Gon KIM, Daejeon (KR); Woochul LEE, Daejeon (KR); Sunghyun HWANG, Daejeon (KR)

(21) Appl. No.: 19/165,390

(22) PCT Filed: Apr. 12, 2024
(86) PCT No.: PCT/KR2024/004950

§ 371 Date: Sep. 15, 2025

(30) Foreign Application Priority Data
Apr. 14, 2023 (KR) 10-2023-0049418

(51) Int. Cl. H10K 50/12; C07B 59/00; C07F 7/08; H10K 50/18; H10K 85/30; H10K 85/40; H10K 85/60; H10K 101/00

(52) U.S. Cl. CPC H10K 50/12; C07B 59/002; C07F 7/0805; H10K 50/181; H10K 85/346; H10K 85/40; H10K 85/654; H10K 85/6572; H10K 85/6574; H10K 85/6576; C07B 2200/05; H10K 2101/90

(57) ABSTRACT

A compound of the following Chemical Formula 1 and an organic light-emitting device including the same:

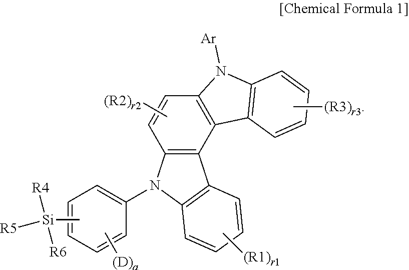

The compound of Chemical Formula 1 is characterized by including an indolo[2,3-c]carbazole as a main backbone, and an arylsilyl or alkylsilyl group. Ar is a C6-18-aryl group, which is unsubstituted or substituted with at least one selected from the group consisting of deuterium, a cyano group, an alkyl group, a cycloalkyl group, and an aryl group, or is an unsubstituted or substituted C6-18 heteroaryl group containing at least one of O and S. The bulky-structured silyl group can stabilize the excited and polaronic states of Chemical Formula 1 by participating in a conjugation system through the hyperconjugation effect. The indolo[2,3-c]carbazole core can increase the LUMO energy level of the compound to prevent the host-guest electrostatic bonding state of the organic material layer.

### CROSS-REFERENCE TO RELATED APPLICATIONS

This application is a National Stage Application of International Application No. PCT/KR2024/004950 filed on Apr. 12, 2024, which claims priority to and the benefit of Korean Patent Application No. 10-2023-0049418 filed in the Korean Intellectual Property Office on Apr. 14, 2023, the entire contents of which are incorporated herein by reference.

### TECHNICAL FIELD

The present specification relates to a compound and an organic light emitting device including the same.

### BACKGROUND ART

An organic light emission phenomenon generally refers to a phenomenon converting electrical energy to light energy using an organic material. An organic light emitting device using the organic light emitting phenomenon usually has a structure including an anode, a cathode, and an organic material layer interposed therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In the structure of the organic light emitting device, if a voltage is applied between two electrodes, holes are injected from an anode into the organic material layer and electrons are injected from a cathode into the organic material layer, and when the injected holes and electrons meet each other, an exciton is formed, and light is emitted when the exciton falls down again to a ground state.

There is a continuous need for developing a new material for the aforementioned organic light emitting device.

### BRIEF DESCRIPTION

The present application has been made in an effort to provide a compound and an organic light emitting device including the same.

An exemplary embodiment of the present specification provides a compound of the following Chemical Formula 1:

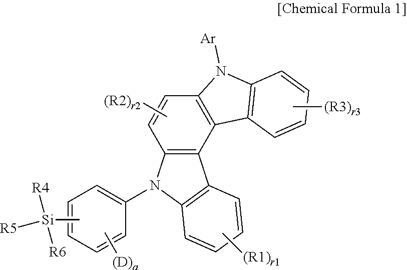

In Chemical Formula 1,
Ar is an aryl group having 6 to 18 carbon atoms, which is unsubstituted or substituted with at least one selected from the group consisting of deuterium, a cyano group, an alkyl group, a cycloalkyl group, and an aryl group, or a substituted or unsubstituted heteroaryl group having 2 to 18 carbon atoms, including at least one of O and S,
R1 to R3 are the same as or different from each other, and are each independently hydrogen, deuterium, or a substituted or unsubstituted aryl group,
R4 to R6 are the same as or different from each other, and are each independently an aryl group having 6 to 12 carbon atoms, which is unsubstituted or substituted with deuterium, or an alkyl group unsubstituted or substituted with deuterium,
r1 is an integer from 1 to 4, and when r1 is 2 or higher, two or more R1s are the same as or different from each other,
r2 is 1 or 2, and when r2 is 2, two R2s are the same as or different from each other,
r3 is an integer from 1 to 4, and when r3 is 2 or higher, two or more R3s are the same as or different from each other, and
a is an integer from 0 to 4, and means the number of deuterium atoms represented by D.

Another exemplary embodiment of the present specification provides an organic light emitting device including an anode; a cathode; and an organic material layer having one or more layers provided between the anode and the cathode, in which one or more layers of the organic material layer include the compound of Chemical Formula 1.

### Advantageous Effects

The compound according to an exemplary embodiment of the present invention can be used as a material for an organic material layer of an organic light emitting device.

The compound according to an exemplary embodiment of the present invention may be used as a material for a light emitting layer of an organic light emitting device.

The compound according to an exemplary embodiment of the present invention may be used as a material for an electron blocking layer of an organic light emitting device.

The compound according to an exemplary embodiment of the present invention can be included in an organic light emitting device to improve device properties, such as the device having low driving voltage, excellent efficiency, and/or excellent service life.

### BRIEF DESCRIPTION OF THE DRAWINGS

FIGS. 1 to 3 illustrate examples of organic light emitting devices according to some exemplary embodiments of the present invention.

FIG. 4 is an MS graph of Compound A.

### EXPLANATION OF REFERENCE NUMERALS AND SYMBOLS

1: Substrate
2: Anode
3: Organic material layer
4: Cathode
5: Hole injection layer
6: Hole Transport layer
7: Light Emitting Layer
8: Electron transport layer
9: Electron blocking layer
10: Hole blocking layer
11: Electron injection and transport layer

### DETAILED DESCRIPTION

Hereinafter, the present specification will be described in more detail.

The present specification provides a compound of the following Chemical Formula 1.

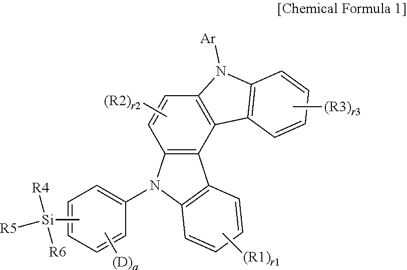

In Chemical Formula 1,
Ar is an aryl group having 6 to 18 carbon atoms, which is unsubstituted or substituted with at least one selected from the group consisting of deuterium, a cyano group, an alkyl group, a cycloalkyl group, and an aryl group, or a substituted or unsubstituted heteroaryl group having 2 to 18 carbon atoms, including at least one of O and S,
R1 to R3 are the same as or different from each other, and are each independently hydrogen, deuterium, or a substituted or unsubstituted aryl group,
R4 to R6 are the same as or different from each other, and are each independently an aryl group having 6 to 12 carbon atoms, which is unsubstituted or substituted with deuterium, or an alkyl group unsubstituted or substituted with deuterium,
r1 is an integer from 1 to 4, and when r1 is 2 or higher, two or more R1s are the same as or different from each other,
r2 is 1 or 2, and when r2 is 2, two R2s are the same as or different from each other,
r3 is an integer from 1 to 4, and when r3 is 2 or higher, two or more R3s are the same as or different from each other, and
a is an integer from 0 to 4, and means the number of deuterium atoms represented by D.

The compound according to an exemplary embodiment of the present specification is represented by Chemical Formula 1 as described above. The compound of Chemical Formula 1 is characterized by including an indolo[2,3-c]carbazole group and an aryl (or alkyl)silyl group.

The bulky-structured silyl group of Chemical Formula 1 above has a structural feature of stabilizing the excited and polaronic states of Chemical Formula 1 above by participating in a conjugation system through the hyperconjugation effect. In addition, by including an indolo[2,3-c]carbazole core, the LUMO energy level of the compound may be increased to prevent the host-guest electrostatic bonding state of the organic material layer of an organic light emitting device including the same.

When the compound is applied to an organic light emitting device having the structural features described above, it is possible to exhibit low voltage, high efficiency and/or long service life effects.

Furthermore, the compound of Chemical Formula 1 may include one or more deuterium atoms. Since the frequency according to the vibrational mode between carbon and deuterium is smaller than the frequency according to the vibrational mode between carbon and other substituents, when deuterium is included, it has an effect of increasing the electrical stability of the molecule.

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

In the present specification, the “layer” has a meaning compatible with a “film” usually used in the art, and means a coating covering a target region. The size of the “layer” is not limited, and the sizes of the respective “layers” may be the same as or different from one another. In an exemplary embodiment, the size of the “layer” may be the same as that of the entire device, may correspond to the size of a specific functional region, and may also be as small as a single sub-pixel.

In the present specification, “X % deuterated”, “X % degree of deuteration”, or “X % deuterium substitution rate” means that X % of the hydrogens at substitutable positions in the corresponding structure are substituted with deuterium. For example, when the corresponding structure is dibenzofuran, the dibenzofuran being “25% deuterated”, “25% degree of deuteration” of the dibenzofuran, or “25% deuterium substitution rate” of the dibenzofuran means that 2 of the 8 hydrogens at the substitutable positions of the dibenzofuran are substituted with deuterium.

In the present specification, the “degree of deuteration” or “deuterium substitution rate” may be confirmed by a known method such as nuclear magnetic resonance spectroscopy (1H NMR), thin-layer chromatography mass spectrometry (TLC/MS), or gas chromatography mass spectrometry (GC/MS).

Specifically, when the “degree of deuteration” or “deuterium substitution rate” is analyzed using nuclear magnetic resonance spectroscopy (1H NMR), the degree of deuteration or deuterium substitution rate may be calculated from the integral amount of the total peak through the integration ratio on 1H NMR by adding dimethylformamide (DMF) as an internal standard.

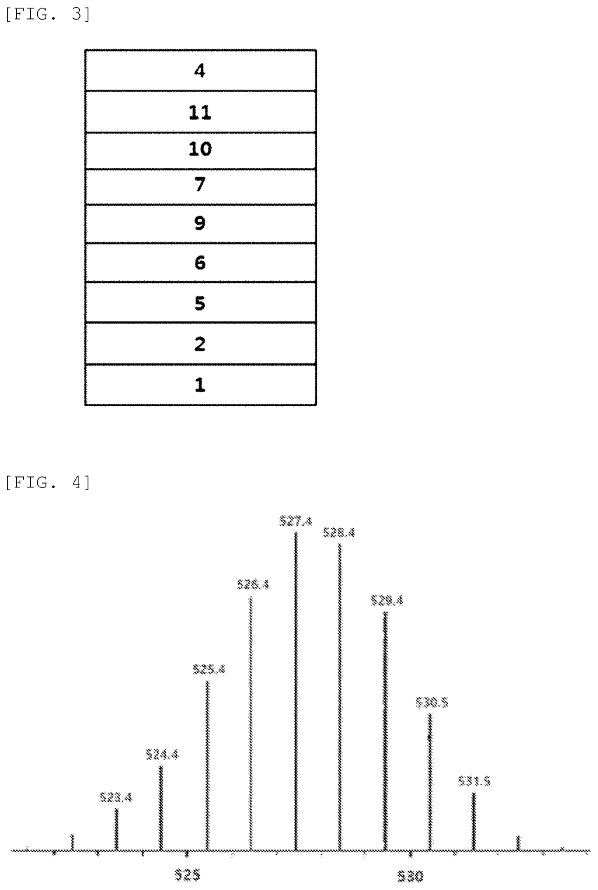

In addition, when the “degree of deuteration” or “deuterium substitution rate” is analyzed by thin-layer chromatography/mass spectrometry (TLC/MS), the substitution rate may be calculated based on the maximum value (median value) of the distribution of molecular weights at the end of the reaction. For example, when the degree of deuteration of the following Compound A is analyzed, the molecular weight of the following starting material is set to 506 and the maximum molecular weight (median value) of the following Compound A is set to 527 in the MS graph of FIG. 4, then it may be calculated that about 81% of the hydrogen has been deuterated because 21 hydrogens of the hydrogens (26 ea) at the substitutable positions in the following starting material have been substituted with deuterium.

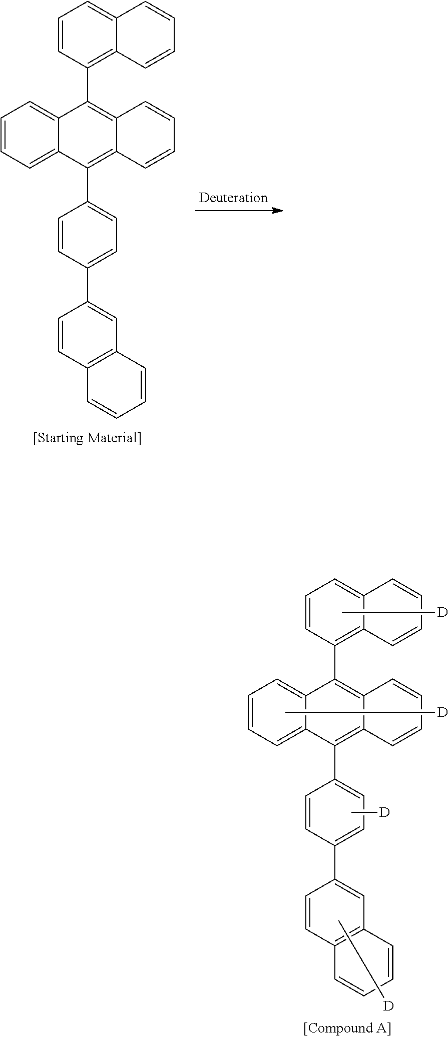

In the present specification, “or” refers to an inclusive “or” and not to an exclusive “or.” For example, condition A or B is satisfied by any one of the followings: A is true (or is present), B is false (or is not present), A is false (or is not present) and B is true (or is present), and both A and B are true (or are present).

In the present specification, “substituted with at least one selected from the group consisting of A, B, and C” means being substituted with one or more substituents selected from the group, or being substituted with a substituent to which two or more groups selected from the group are linked together.

In the present invention, “-----” and “*” each mean a moiety bonded to another substituent or a bonding portion.

In the present specification, Cn means that the number of carbon atoms is n, and Cn-Cm means that the number of carbon atoms is n to m.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present invention, the term “substituted or unsubstituted” means being substituted with one or two or more substituents selected from the group consisting of deuterium; a halogen group; a nitrile group (—CN); a nitro group; a hydroxyl group; an alkyl group; a cycloalkyl group; an alkoxy group; a phosphine oxide group; an aryloxy group; an alkylthioxy group; an arylthioxy group; an alkylsulfoxy group; an arylsulfoxy group; an alkenyl group; a silyl group; a boron group; an amine group; an aryl group; or a heterocyclic group, being substituted with a substituent to which two or more substituents among the exemplified substituents are linked together, or having no substituent. For example, “the substituent to which two or more substituents are linked together” may be a biphenyl group. That is, the biphenyl group may also be an aryl group, and may be interpreted as a substituent to which two phenyl groups are linked together.

In the present specification, the term “substituted or unsubstituted” means being substituted with one or two or more substituents selected from the group consisting of deuterium; a halogen group; a nitrile group; a silyl group; an alkoxy group; an aryloxy group; an alkyl group; an aryl group; and a heterocyclic group, being substituted with a substituent to which two or more substituents among the exemplified substituents are linked together, or having no substituent.

In the present specification, the term “substituted or unsubstituted” means being substituted with one or two or more substituents selected from the group consisting of deuterium; an alkyl group; an aryl group; and a heterocyclic group, being substituted with a substituent to which two or more substituents among the exemplified substituents are linked together, or having no substituent. For example, “the substituent to which two or more substituents are linked together” may be a biphenyl group. That is, the biphenyl group may also be an aryl group, and may be interpreted as a substituent to which two phenyl groups are linked.

In an exemplary embodiment of the present specification, the “substituted or unsubstituted” means being substituted with one or more substituents selected from the group consisting of deuterium; a halogen group; a cyano group (—CN); a silyl group; a C1-C20 alkyl group; a C3-C60 cycloalkyl group; a C6-C60 aryl group; and a C2-C60 heterocyclic group, being substituted with a substituent to which two or more groups selected from the above group are linked together, or having no substituent.

In an exemplary embodiment of the present specification, the “substituted or unsubstituted” means being substituted with one or more substituents selected from the group consisting of deuterium; a halogen group; a cyano group (—CN); a silyl group; a C1-C10 alkyl group; a C3-C30 cycloalkyl group; a C6-C30 aryl group; and a C2-C30 heterocyclic group, being substituted with a substituent to which two or more groups selected from the above group are linked together, or having no substituent.

In an exemplary embodiment of the present specification, the “substituted or unsubstituted” means being substituted with one or more substituents selected from the group consisting of deuterium; a halogen group; a cyano group (—CN); a silyl group; a C1-C6 alkyl group; a C3-C20 cycloalkyl group; a C6-C20 aryl group; and a C2-C20 heterocyclic group, being substituted with a substituent to which two or more groups selected from the above group are linked together, or having no substituent.

In the present specification, the fact that two or more substituents are linked together indicates that hydrogen of any one substituent is replaced with another substituent. For example, an isopropyl group and a phenyl group may be linked to each other to become a substituent of

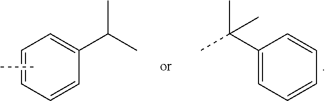

In the present specification, the fact that three substituents are linked to one another includes not only a case where (Substituent 1)-(Substituent 2)-(Substituent 3) are consecutively linked to one another, but also a case where (Substituent 2) and (Substituent 3) are linked to (Substituent 1). For example, two phenyl groups and an isopropyl group may be linked to each other to become a substituent of

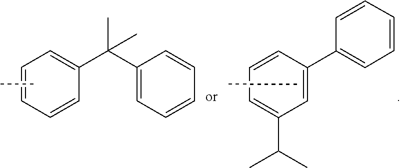

The same also applies to the case where four or more substituents are linked to one another.

In the present specification, “substituted with A or B” includes not only the case of being substituted with A alone or with B alone, but also the case of being substituted with A and B.

Examples of the substituents will be described below; however, the substituents are not limited thereto.

In the present specification, examples of a halogen group include fluorine (—F), chlorine (—Cl), bromine (—Br) or iodine (—I).

In the present specification, a silyl group is the chemical formula of —SiYaYbYc, and Ya, Yb, and Yc may be each hydrogen; a substituted or unsubstituted alkyl group; or a substituted or unsubstituted aryl group. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the present specification, a boron group is the chemical formula of —BYdYe, and Yd and Ye may be each hydrogen; a substituted or unsubstituted alkyl group; or a substituted or unsubstituted aryl group. Specific examples of the boron group include a trimethylboron group, a triethylboron group, a t-butyldimethylboron group, a triphenylboron group, a phenylboron group, and the like, but are not limited thereto.

In the present specification, an alkyl group may be straight-chained or branched, and the number of carbon atoms thereof is not particularly limited, but is preferably 1 to 60. In an exemplary embodiment, the number of carbon atoms of the alkyl group is 1 to 30. In another exemplary embodiment, the number of carbon atoms of the alkyl group is 1 to 20. In still another exemplary embodiment, the number of carbon atoms of the alkyl group is 1 to 10. Specific examples of the alkyl group include a methyl group, an ethyl group, a propyl group, an n-propyl group, an isopropyl group, a butyl group, an n-butyl group, an isobutyl group, a tert-butyl group, a pentyl group, an n-pentyl group, a hexyl group, an n-hexyl group, a heptyl group, an n-heptyl group, an octyl group, an n-octyl group, and the like, but are not limited thereto.

In the present specification, an alkoxy group may be straight-chained, branched, or cyclic. The number of carbon atoms of the alkoxy group is not particularly limited, but is preferably 1 to 20. Specific examples thereof include methoxy, ethoxy, n-propoxy, isopropoxy, i-propyloxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, and the like, but are not limited thereto.

Substituents including an alkyl group, an alkoxy group, and other alkyl group moieties described in the present specification include both a straight-chained form and a branched form.

In the present specification, an alkenyl group may be straight-chained or branched, and the number of carbon atoms thereof is not particularly limited, but is preferably 2 to 40. In an exemplary embodiment, the number of carbon atoms of the alkenyl group is 2 to 20. In another exemplary embodiment, the number of carbon atoms of the alkenyl group is 2 to 10. In still another exemplary embodiment, the number of carbon atoms of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present specification, a cycloalkyl group is not particularly limited, but has preferably 3 to 60 carbon atoms, and in an exemplary embodiment, the number of carbon atoms of the cycloalkyl group is 3 to 30. In another exemplary embodiment, the number of carbon atoms of the cycloalkyl group is 3 to 20. In still another exemplary embodiment, the number of carbon atoms of the cycloalkyl group is 3 to 6. Specific examples thereof may include a cyclopropyl group, a cyclobutyl group, a cyclopentyl group, a cyclohexyl group, a cycloheptyl group, a cyclooctyl group and the like, but are not limited thereto.

In the present specification, an amine group is —NH₂, and the amine group may be substituted with the above-described alkyl group, aryl group, heterocyclic group, alkenyl group, cycloalkyl group, a combination thereof, and the like. The number of carbon atoms of the substituted amine group is not particularly limited, but is preferably 1 to 30. In an exemplary embodiment, the number of carbon atoms of the amine group is 1 to 20. In an exemplary embodiment, the number of carbon atoms of the amine group is 1 to 10. Specific examples of the substituted amine group include a methylamine group, a dimethylamine group, an ethylamine group, a diethylamine group, a phenylamine group, a 9,9-dimethylfluorenylphenylamine group, a pyridylphenylamine group, a diphenylamine group, a phenylpyridylamine group, a naphthylamine group, a biphenylamine group, an anthracenylamine group, a dibenzofuranylphenylamine group, a 9-methylanthracenylamine group, a phenylnaphthylamine group, a ditolylamine group, a phenyltolylamine group, and the like, but are not limited thereto.

In the present specification, an aryl group is not particularly limited, but has preferably 6 to 60 carbon atoms, and may be a monocyclic aryl group or a polycyclic aryl group. According to an exemplary embodiment, the number of carbon atoms of the aryl group is from 6 to 30. According to an exemplary embodiment, the number of carbon atoms of the aryl group is from 6 to 20. Examples of a monocyclic aryl group as the aryl group include a phenyl group, a biphenyl group, a terphenyl group, and the like, but are not limited thereto. Examples of the polycyclic aryl group include a naphthyl group, an anthracenyl group, a phenanthrenyl group, a pyrenyl group, a perylenyl group, a triphenylenyl group, a chrysenyl group, and the like, but are not limited thereto.

In the present specification, the aryl group may also include a form in which an aliphatic ring is fused to an aromatic ring. For example, a fluorenyl group, a spirofluorenyl group, a spirobifluorenyl group, a tetrahydronaphthalenyl group, a dihydroindenyl group, a dihydroanthracenyl group, or the like are included in the aryl group. In the following structure, one of the carbons of a benzene ring may be linked to another position.

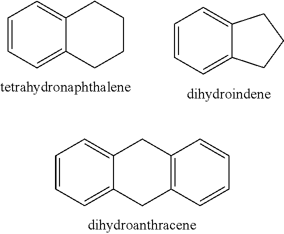

In the present specification, No. 9 carbon atom (C) of a fluorenyl group may be substituted with an alkyl group, an aryl group, or the like, and two substituents may be bonded to each other to form a spiro structure such as cyclopentane or fluorene.

In the present specification, the above-described description of the aryl group may be applied to an arylene group except that the arylene group is divalent.

In the present specification, the above-described description of the aryl group may be applied to an aryl group in an aryloxy group.

In the present specification, a heterocyclic group is a cyclic group including one or more of N, O, P, S, Si, and Se as a heteroatom, and the number of carbon atoms thereof is not particularly limited, but is preferably 2 to 60. According to one embodiment, the number of carbon atoms of the heterocyclic group is from 2 to 30. According to one embodiment, the number of carbon atoms of the heterocyclic group is from 2 to 20. Examples of the heterocyclic group include a pyridyl group; a quinoline group; a thiophene group; a dibenzothiophene group; a furan group; a dibenzofuran group; a naphthobenzofuran group; a carbazole group; a benzocarbazole group; a naphthobenzothiophene group; a dibenzosilole group; a naphthobenzosilole group; a hexahydrocarbazole group; dihydroacridine group; a dihydrodibenzoazasiline group; a phenoxazine group; a phenothiazine group; a spiro(dibenzosilole-dibenzoazasiline) group; a spiro(acridine-fluorene) group, and the like, but are not limited thereto.

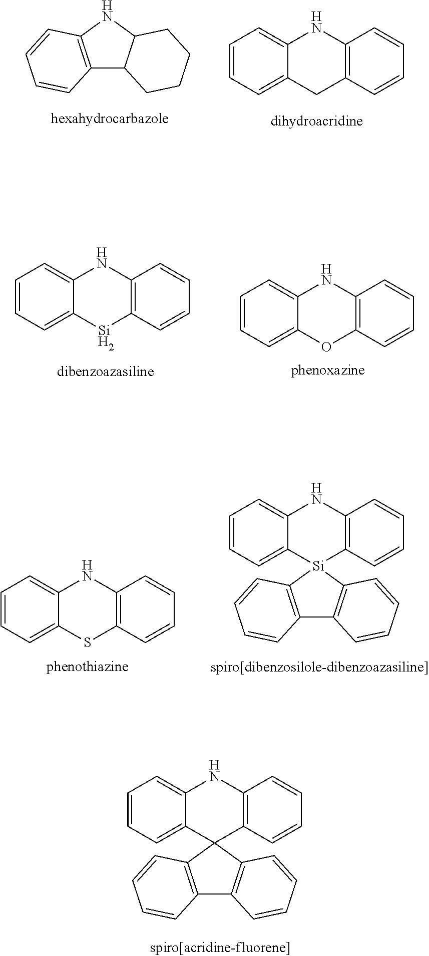

In the present specification, the above-described description of the heterocyclic group may be applied to a heteroaryl group except for an aromatic heteroaryl group.

In the present specification, the description of the aryl group may be applied to an arylene group except for a divalent arylene group.

Hereinafter, the compound of Chemical Formula 1 will be described in detail.

In an exemplary embodiment of the present specification, Ar is an aryl group having 6 to 18 carbon atoms, which is unsubstituted or substituted with at least one selected from the group consisting of deuterium, a cyano group, an alkyl group, a cycloalkyl group, and an aryl group, or is a substituted or unsubstituted heteroaryl group having 2 to 18 carbon atoms, including at least one of O and S.

In an exemplary embodiment of the present specification, Ar is an aryl group having 6 to 18 carbon atoms, which is unsubstituted or substituted with at least one selected from the group consisting of deuterium, a cyano group, an alkyl group, a cycloalkyl group, and an aryl group, or is a substituted or unsubstituted heteroaryl group having 6 to 18 carbon atoms, including at least one of O and S.

In an exemplary embodiment of the present specification, Ar is any one of the following structures, and the following structures may be unsubstituted or substituted with deuterium.

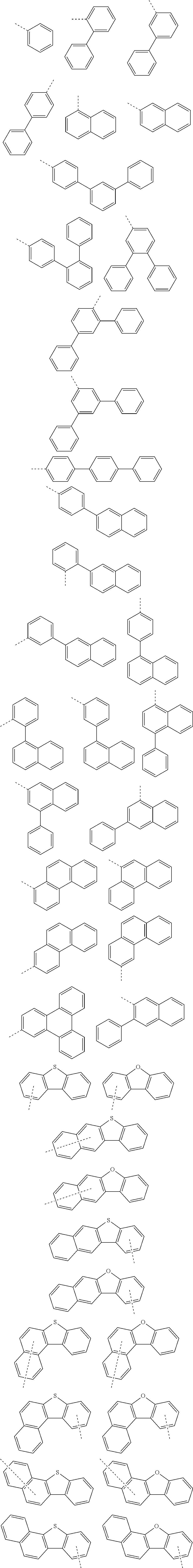

In the structures, [symbol] is a moiety bonded to Chemical Formula 1.

In an exemplary embodiment of the present specification, Chemical Formula 1 is the following Chemical Formula 1-A.

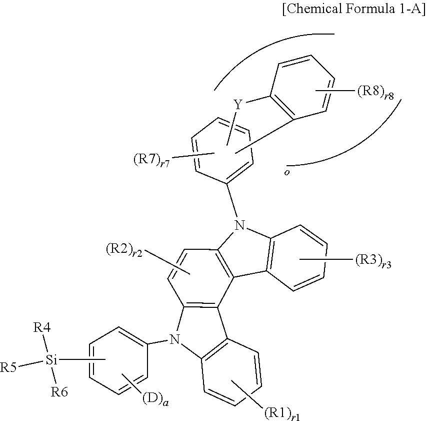

In Chemical Formula 1-A,
R1 to R6, r1 to r3, and a are the same as those defined in Chemical Formula 1,
Y is O or S,
R7 is hydrogen, deuterium, or a substituted or unsubstituted aryl group having 6 to 12 carbon atoms,
R8 is hydrogen or deuterium,
r7 is an integer from 1 to 5, and when r7 is 2 or higher, two or more R7s are the same as or different from each other,
r8 is an integer from 1 to 4, and when r8 is 2 or higher, two or more R8s are the same as or different from each other, and
o is 0 or 1.

In an exemplary embodiment of the present specification, the compound of Chemical Formula 1-A includes at least one deuterium.

In an exemplary embodiment of the present specification, Chemical Formula 1 is the following Chemical Formula 1-A-a or 1-A-b.

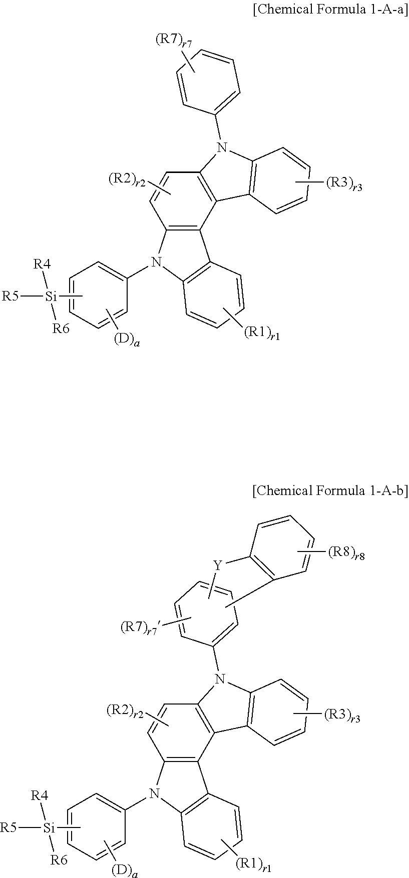

In Chemical Formula 1-A-a or 1-A-b,
R1 to R6, r1 to r3, and a are the same as those defined in Chemical Formula 1,
Y is O or S,
R7 is hydrogen, deuterium, or a substituted or unsubstituted aryl group having 6 to 12 carbon atoms,
R8 is hydrogen or deuterium,
r7 is an integer from 1 to 5, and when r7 is 2 or higher, two or more R7s are the same as or different from each other,
r7′ is an integer from 1 to 3, and when r7′ is 2 or higher, two or more R7's are the same as or different from each other, and
r8 is an integer from 1 to 4, and when r8 is 2 or higher, two or more R8s are the same as or different from each other.

In an exemplary embodiment of the present specification, R1 to R3 are the same as or different from each other, and may be each independently hydrogen, deuterium, or a substituted or unsubstituted aryl group.

In an exemplary embodiment of the present specification, the compound of Chemical Formula 1-A-a or 1-A-b includes at least one deuterium.

In an exemplary embodiment of the present specification, R1 to R3 are the same as or different from each other, and may be each independently hydrogen, deuterium, or a substituted or unsubstituted aryl group having 6 to 60 carbon atoms.

In an exemplary embodiment of the present specification, R1 to R3 are the same as or different from each other, and may be each independently hydrogen, deuterium, or a substituted or unsubstituted aryl group having 6 to 30 carbon atoms.

In an exemplary embodiment of the present specification, R1 to R3 are the same as or different from each other, and may be each independently hydrogen, deuterium, or a substituted or unsubstituted aryl group having 6 to 10 carbon atoms.

In an exemplary embodiment of the present specification, R1 to R3 are the same as or different from each other, and may be each independently hydrogen, deuterium, or an aryl group having 6 to 10 carbon atoms, which is unsubstituted or substituted with deuterium.

In an exemplary embodiment of the present specification, R1 to R3 are the same as or different from each other, and may be each independently hydrogen or deuterium.

In an exemplary embodiment of the present specification, Chemical Formula 1 is any one of the following Chemical Formulae 1-1 to 1-3.

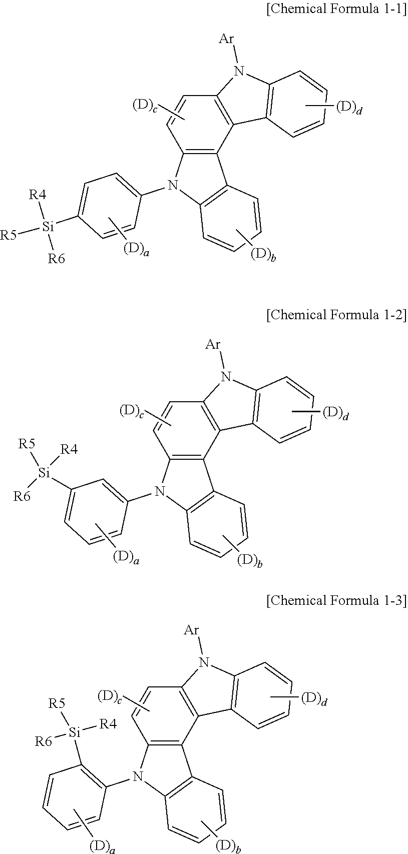

In Chemical Formulae 1-1 to 1-3,
Ar, a, and R4 to R6 are the same as those defined in Chemical Formula 1, and
b and d are each an integer from 0 to 4, c is an integer from 0 to 2, and b to d each mean the number of deuterium atoms represented by D.

In an exemplary embodiment of the present specification, each of the compounds of Chemical Formulae 1-1 to 1-3 includes at least one deuterium.

In an exemplary embodiment of the present specification, Chemical Formula 1 is any one of the following Chemical Formulae 1-A-1 to 1-A-3.

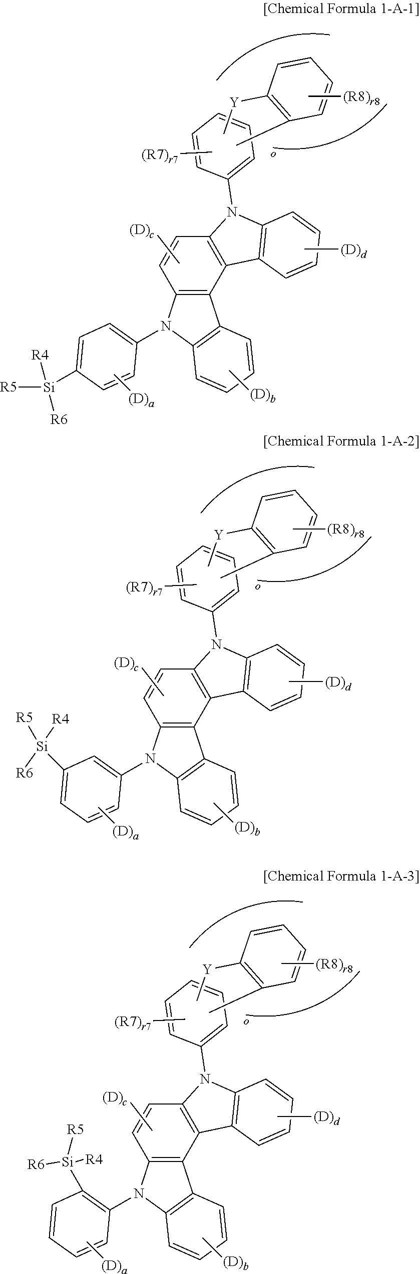

In Chemical Formulae 1-A-1 to 1-A-3,
R4 to R6 and a are the same as those defined in Chemical Formula 1,
Y is O or S,
R7 is hydrogen, deuterium, or a substituted or unsubstituted aryl group having 6 to 12 carbon atoms,
R8 is hydrogen or deuterium,
r7 is an integer from 1 to 5, and when r7 is 2 or higher, two or more R7s are the same as or different from each other,
r8 is an integer from 1 to 4, and when r8 is 2 or higher, two or more R8s are the same as or different from each other,
o is 0 or 1, and
b and d are each an integer from 0 to 4, c is an integer from 0 to 2, and b to d each mean the number of deuterium atoms represented by D.

In an exemplary embodiment of the present specification, each of the compounds of Chemical Formulae 1-A-1 to 1-A-3 includes at least one deuterium.

In an exemplary embodiment of the present specification, R4 to R6 are the same as or different from each other, and may be each independently an aryl group having 6 to 12 carbon atoms, which is unsubstituted or substituted with deuterium, or an alkyl group that is unsubstituted or substituted with deuterium.

In an exemplary embodiment of the present specification, R4 to R6 are the same as or different from each other, and may be each independently an alkyl group that is unsubstituted or substituted with deuterium.

In an exemplary embodiment of the present specification, R4 to R6 are the same as or different from each other, and may be each independently an alkyl group having 1 to 30 carbon atoms, which is unsubstituted or substituted with deuterium.

In an exemplary embodiment of the present specification, R4 to R6 are the same as or different from each other, and may be each independently an alkyl group having 1 to 20 carbon atoms, which is unsubstituted or substituted with deuterium.

In an exemplary embodiment of the present specification, R4 to R6 are the same as or different from each other, and may be each independently an alkyl group having 1 to 10 carbon atoms, which is unsubstituted or substituted with deuterium.

In an exemplary embodiment of the present specification, R4 to R6 are the same as or different from each other, and may be each independently an aryl group having 6 to 12 carbon atoms, which is unsubstituted or substituted with deuterium.

In an exemplary embodiment of the present specification, R4 to R6 are the same as or different from each other, and may be each independently a phenyl group that is unsubstituted or substituted with deuterium.

In an exemplary embodiment of the present specification, Chemical Formula 1 is the following Chemical Formula 1-B.

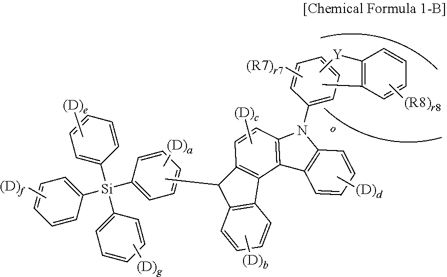

In Chemical Formula 1-B,
Y is O or S,
R7 is hydrogen, deuterium, or a substituted or unsubstituted aryl group having 6 to 12 carbon atoms,
R8 is hydrogen or deuterium,
r7 is an integer from 1 to 5, and when r7 is 2 or higher, two or more R7s are the same as or different from each other,
r8 is an integer from 1 to 4, and when r8 is 2 or higher, two or more R8s are the same as or different from each other,
o is 0 or 1, and
a, b, and d are each an integer from 0 to 4, c is an integer from 0 to 2, e to g are each an integer from 0 to 5, and a to g each mean the number of deuterium atoms represented by D.

In an exemplary embodiment of the present specification, at least one of a to g of Chemical Formula 1-B is 1 or higher. Specifically, the compound of Chemical Formula 1-B includes at least one deuterium.

In an exemplary embodiment of the present specification, Chemical Formula 1-B is the following Chemical Formula 1-B-1 or 1-B-2.

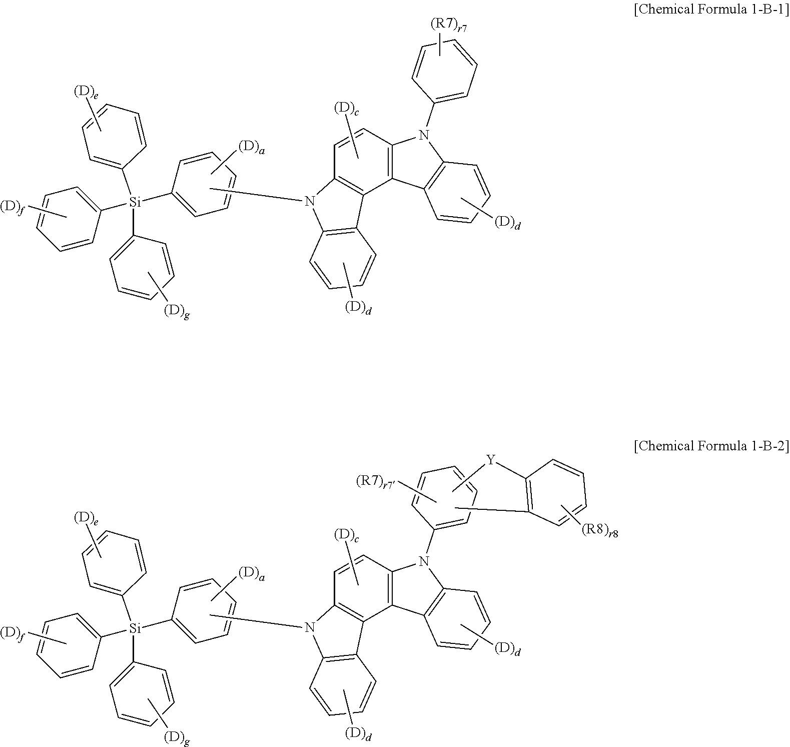

In Chemical Formulae 1-B-1 and 1-B-2,
Y is O or S,
R7 is hydrogen, deuterium, or a substituted or unsubstituted aryl group having 6 to 12 carbon atoms,
R8 is hydrogen or deuterium,
r7 is an integer from 1 to 5, and when r7 is 2 or higher, two or more R7s are the same as or different from each other,
r7′ is an integer from 1 to 3, and when r7′ is 2 or higher, two or more R7's are the same as or different from each other,
r8 is an integer from 1 to 4, and when r8 is 2 or higher, two or more R8s are the same as or different from each other, and
a, b, and d are each an integer from 0 to 4, c is an integer from 0 to 2, e to g are each an integer from 0 to 5, and a to g each mean the number of deuterium atoms represented by D.

In an exemplary embodiment of the present specification, each of the compounds of Chemical Formulae 1-B-1 to 1-B-2 includes at least one deuterium.

In an exemplary embodiment of the present specification, Chemical Formula 1-B-1 is any one of the following Chemical Formulae 1-B-1-a to 1-B-1-c.

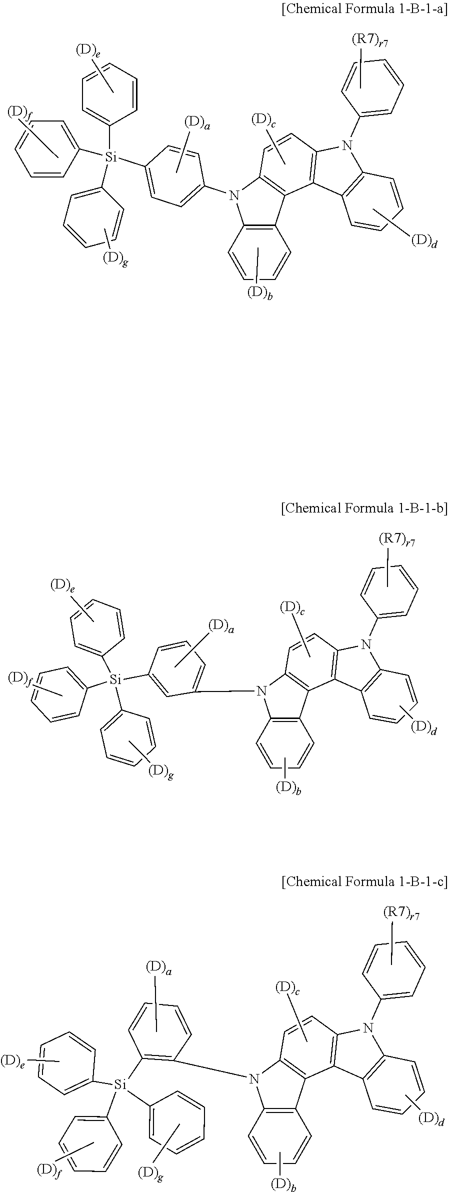

In Chemical Formulae 1-B-1-a to 1-B-1-c,
R7, r7, and a to g are the same as those defined in Chemical Formula 1-B-1.

In an exemplary embodiment of the present specification, each of the compounds of Chemical Formulae 1-B-1-a to 1-B-1-c includes at least one deuterium.

In an exemplary embodiment of the present specification, Chemical Formula 1-B-2 is any one of the following Chemical Formulae 1-B-2-a to 1-B-2-c.

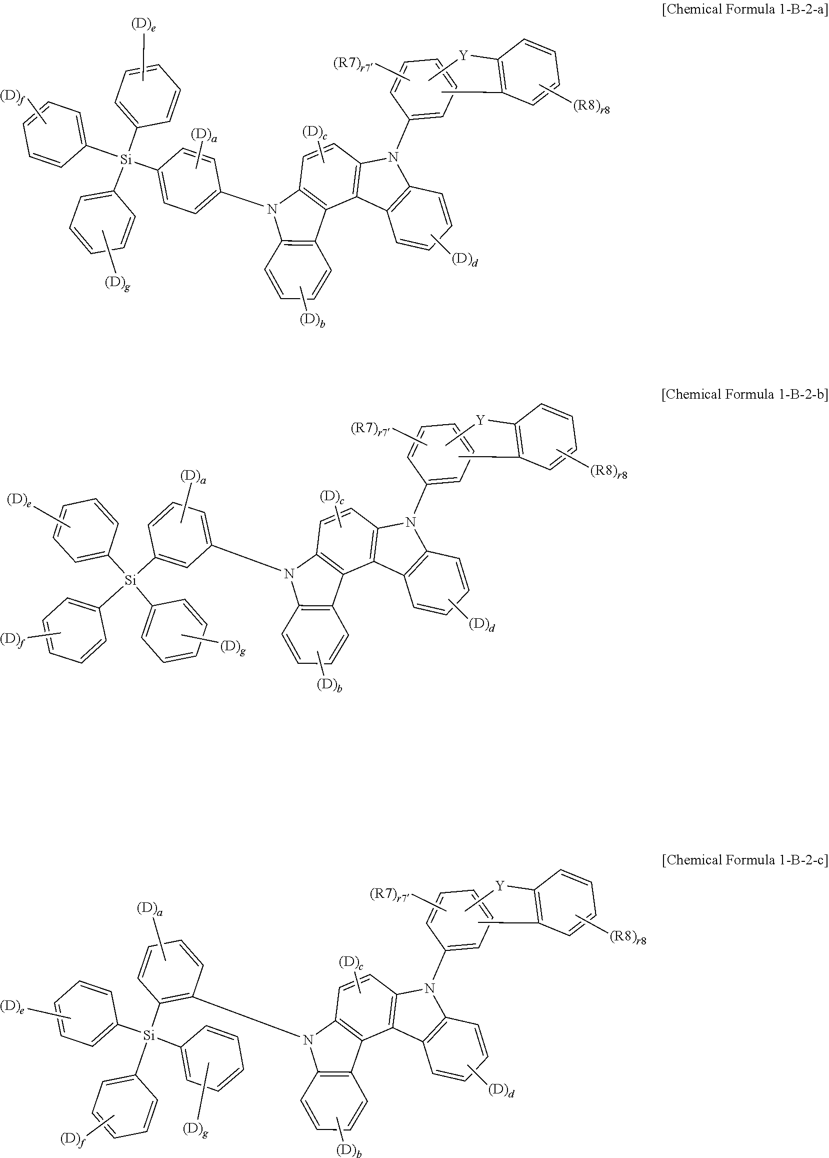

In Chemical Formulae 1-B-2-a to 1-B-2-c,
R7, r7′, R8, r8, and a to g are the same as those defined in Chemical Formula 1-B-2.

In an exemplary embodiment of the present specification, each of the compounds of Chemical Formulae 1-B-2-a to 1-B-2-c includes at least one deuterium.

In an exemplary embodiment of the present specification, at least one of Ar and R1 to R6 of Chemical Formula 1 includes deuterium.

In an exemplary embodiment of the present specification, the compound of Chemical Formula 1 includes one or more deuterium atoms.

In an exemplary embodiment of the present specification, the compound of Chemical Formula 1 includes two or more deuterium atoms.

In an exemplary embodiment of the present specification, the compound of Chemical Formula 1 includes three or more deuterium atoms.

In an exemplary embodiment of the present specification, the compound of Chemical Formula 1 includes four or more deuterium atoms.

In an exemplary embodiment of the present specification, the compound of Chemical Formula 1 includes 5 or more deuterium atoms, specifically 5 deuterium atoms.

In an exemplary embodiment of the present specification, the compound of Chemical Formula 1 includes 6 or more deuterium atoms.

In an exemplary embodiment of the present specification, the compound of Chemical Formula 1 includes 7 or more deuterium atoms.

In an exemplary embodiment of the present specification, the compound of Chemical Formula 1 includes 8 or more deuterium atoms.

In an exemplary embodiment of the present specification, the compound of Chemical Formula 1 includes 9 or more deuterium atoms.

In an exemplary embodiment of the present specification, the compound of Chemical Formula 1 includes 10 or more deuterium atoms, specifically 10 deuterium atoms.

In an exemplary embodiment of the present specification, the compound of Chemical Formula 1 includes 11 or more deuterium atoms.

In an exemplary embodiment of the present specification, the compound of Chemical Formula 1 includes 12 or more deuterium atoms.

In an exemplary embodiment of the present specification, the compound of Chemical Formula 1 includes 13 or more deuterium atoms.

In an exemplary embodiment of the present specification, the compound of Chemical Formula 1 includes 14 or more deuterium atoms.

In an exemplary embodiment of the present specification, the compound of Chemical Formula 1 includes 15 or more deuterium atoms, specifically 15 deuterium atoms.

In an exemplary embodiment of the present specification, Ar includes deuterium, and R1 to R6 does not include deuterium and a=0.

In an exemplary embodiment of the present specification, R1 to R3 are deuterium, Ar includes deuterium, and R4 to R6 do not include deuterium and a=0.

In an exemplary embodiment of the present specification, R1 to R3 are deuterium, and Ar and R4 to R6 do not include deuterium and a=0.

In an exemplary embodiment of the present specification, R1 to R6 are deuterium, and Ar includes deuterium and a=4.

In an exemplary embodiment of the present specification, Chemical Formula 1 is any one of Chemical Formulae 1-1 to 1-3, and Ar is substituted with deuterium.

In an exemplary embodiment of the present specification, Chemical Formula 1 is any one of Chemical Formulae 1-1 to 1-3, c is 2, and b and d are 4.

In an exemplary embodiment of the present specification, Chemical Formula 1 is any one of Chemical Formulae 1-1 to 1-3, Ar is substituted with deuterium, R4 to R6 are an aryl group substituted with deuterium, a is 4, c is 2, and b and d are 4.

In an exemplary embodiment of the present specification, Chemical Formula 1 is any one of Chemical Formulae 1-A-1 to 1-A-3, and R7 and R8 each include deuterium.

In an exemplary embodiment of the present specification, Chemical Formula 1 is any one of Chemical Formulae 1-A-1 to 1-A-3, c is 2, and b and d are 4.

In an exemplary embodiment of the present specification, Chemical Formula 1 is any one of Chemical Formulae 1-A-1 to 1-A-3, R7 and R8 each includes deuterium, R4 to R6 are an aryl group substituted with deuterium, a is 4, c is 2, and b and d are 4.

In an exemplary embodiment of the present specification, Chemical Formula 1 is any one of Chemical Formulae 1-A-1 to 1-A-3, R7 and R8 are each deuterium, R4 to R6 are an aryl group substituted with deuterium, a is 4, c is 2, and b and d are 4.

In an exemplary embodiment of the present specification, Chemical Formula 1 is Chemical Formula 1-B, and R7 and R8 each include deuterium.

In an exemplary embodiment of the present specification, Chemical Formula 1 is Chemical Formula 1-B, c is 2, and b and d are 4.

In an exemplary embodiment of the present specification, Chemical Formula 1 is Chemical Formula 1-B, R7 and R8 each include deuterium, a is 4, c is 2, b and d are 4, and e to g are each 5.

In an exemplary embodiment of the present specification, Chemical Formula 1 is Chemical Formula 1-B, R7 and R8 are each deuterium, a is 4, c is 2, b and d are 4, and e to g are each 5.

In an exemplary embodiment of the present specification, Chemical Formula 1 is Chemical Formula 1-B-1 or 1-B-2, and R7 and R8 each include deuterium.

In an exemplary embodiment of the present specification, Chemical Formula 1 is Chemical Formula 1-B-1 or 1-B-2, c is 2, and b and d are 4.

In an exemplary embodiment of the present specification, Chemical Formula 1 is Chemical Formula 1-B-1 or 1-B-2, R7 and R8 each include deuterium, a is 4, c is 2, b and d are 4, and e to g are each 5.

In an exemplary embodiment of the present specification, Chemical Formula 1 is Chemical Formula 1-B-1 or 1-B-2, R7 and R8 are each deuterium, a is 4, c is 2, b and d are 4, and e to g are each 5.

In an exemplary embodiment of the present specification, Chemical Formula 1 is any one of Chemical Formulae 1-B-1-a to 1-B-1-c, and R7 includes deuterium.

In an exemplary embodiment of the present specification, Chemical Formula 1 is any one of Chemical Formulae 1-B-1-a to 1-B-1-c, c is 2, and b and d are 4.

In an exemplary embodiment of the present specification, Chemical Formula 1 is any one of Chemical Formulae 1-B-1-a to 1-B-1-c, R7 each includes deuterium, a is 4, c is 2, b and d are 4, and e to g are each 5.

In an exemplary embodiment of the present specification, Chemical Formula 1 is any one of Chemical Formulae 1-B-1-a to 1-B-1-c, R7 is deuterium, r7 is 5, a is 4, c is 2, b and d are 4, and e to g are each 5.

In an exemplary embodiment of the present specification, Chemical Formula 1 is any one of Chemical Formulae 1-B-2-a to 1-B-2-c, and R7 and R8 each include deuterium.

In an exemplary embodiment of the present specification, Chemical Formula 1 is any one of Chemical Formulae 1-B-2-a to 1-B-2-c, c is 2, and b and d are 4.

In an exemplary embodiment of the present specification, Chemical Formula 1 is any one of Chemical Formulae 1-B-2-a to 1-B-2-c, R7 and R8 each include deuterium, a is 4, c is 2, b and d are 4, and e to g are each 5.

In an exemplary embodiment of the present specification, Chemical Formula 1 is any one of Chemical Formulae 1-B-2-a to 1-B-2-c, R7 and R8 are each deuterium, r7′ is 3, r8 is 4, a is 4, c is 2, b and d are 4, and e to g are each 5.

In an exemplary embodiment of the present specification, the deuterium substitution rate of the compound of Chemical Formula 1 is 15% or more.

In an exemplary embodiment of the present specification, the deuterium substitution rate of the compound of Chemical Formula 1 is 15% to 100%.

In an exemplary embodiment of the present specification, the deuterium substitution rate of the compound of Chemical Formula 1 is 20% to 100%.

In an exemplary embodiment of the present specification, the deuterium substitution rate of the compound of Chemical Formula 1 is 30% to 100%.

In an exemplary embodiment of the present specification, the deuterium substitution rate of the compound of Chemical Formula 1 is 40% to 100%.

In an exemplary embodiment of the present specification, the deuterium substitution rate of the compound of Chemical Formula 1 is 50% to 100%.

In an exemplary embodiment of the present specification, the compound of Chemical Formula 1 is any one compound selected from the following compounds.

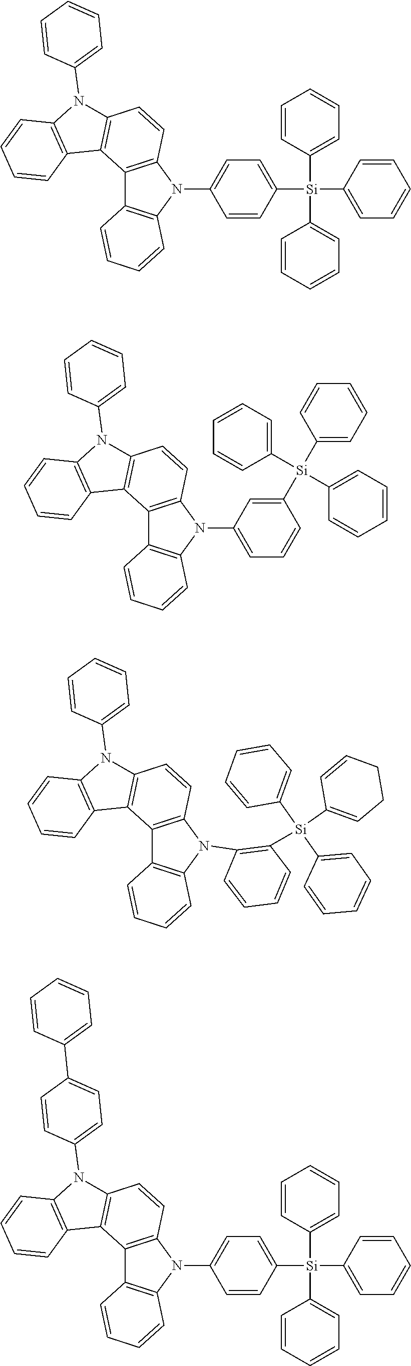 [SMILES: c1ccc(-n2c3ccccc3c3c4c5ccccc5n(-c5ccc([Si](c6ccccc6)(c6ccccc6)c6ccccc6)cc5)c4ccc32)cc1 ; c1ccc(-n2c3ccccc3c3c4c5ccccc5n(-c5cccc([Si](c6ccccc6)(c6ccccc6)c6ccccc6)c5)c4ccc32)cc1 ; C1=CC([Si](c2ccccc2)(c2ccccc2)c2ccccc2-n2c3ccccc3c3c4c5ccccc5n(-c5ccccc5)c4ccc32)=CCC1 ; c1ccc(-c2ccc(-n3c4ccccc4c4c5c6ccccc6n(-c6ccc([Si](c7ccccc7)(c7ccccc7)c7ccccc7)cc6)c5ccc43)cc2)cc1]

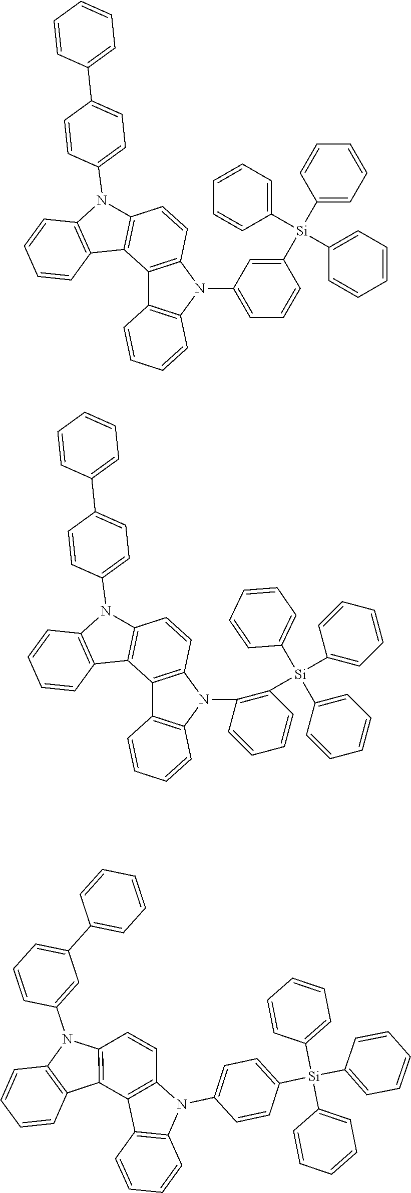 [SMILES: c1ccc(-c2ccc(-n3c4ccccc4c4c5c6ccccc6n(-c6cccc([Si](c7ccccc7)(c7ccccc7)c7ccccc7)c6)c5ccc43)cc2)cc1 ; c1ccc(-c2ccc(-n3c4ccccc4c4c5c6ccccc6n(-c6ccccc6[Si](c6ccccc6)(c6ccccc6)c6ccccc6)c5ccc43)cc2)cc1 ; c1ccc(-c2cccc(-n3c4ccccc4c4c5c6ccccc6n(-c6ccc([Si](c7ccccc7)(c7ccccc7)c7ccccc7)cc6)c5ccc43)c2)cc1]

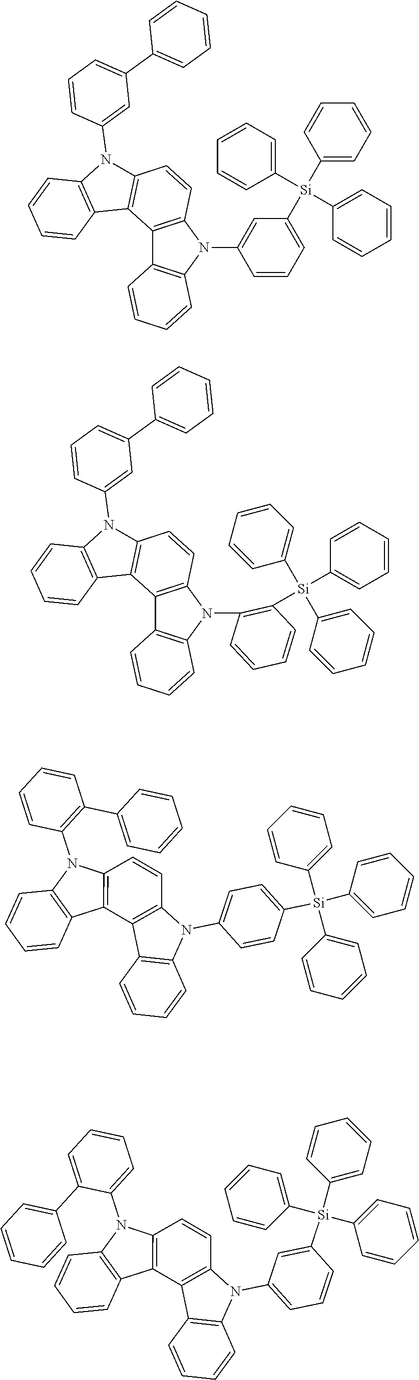

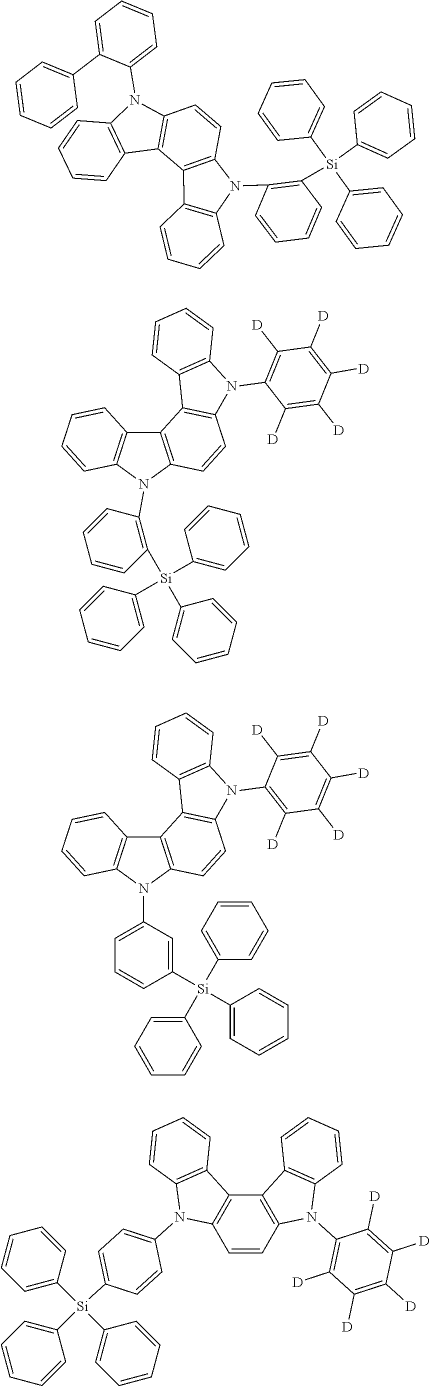

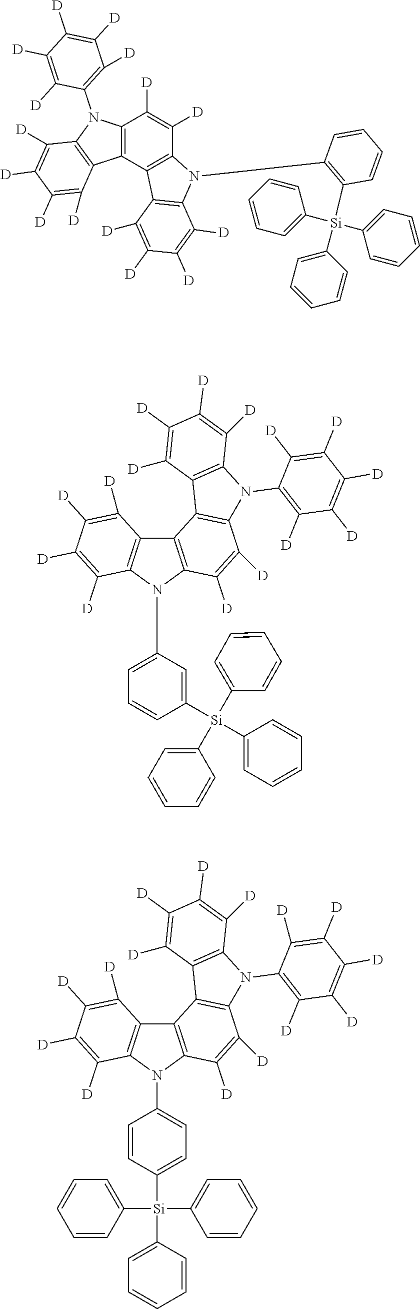

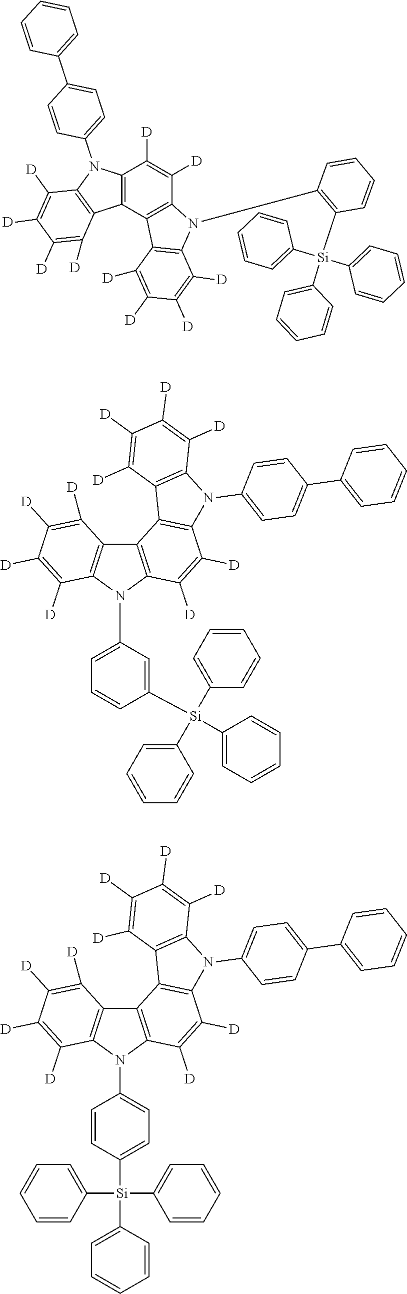 [SMILES: [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1ccc(-c2ccccc2)cc1 ; [2H]c1c([2H])c([2H])c2c(c1[2H])c1c3c4c([2H])c([2H])c([2H])c([2H])c4n(-c4cccc([Si](c5ccccc5)(c5ccccc5)c5ccccc5)c4)c3c([2H])c([2H])c1n2-c1ccc(-c2ccccc2)cc1 ; [2H]c1c([2H])c([2H])c2c(c1[2H])c1c3c4c([2H])c([2H])c([2H])c([2H])c4n(-c4ccc([Si](c5ccccc5)(c5ccccc5)c5ccccc5)cc4)c3c([2H])c([2H])c1n2-c1ccc(-c2ccccc2)cc1]

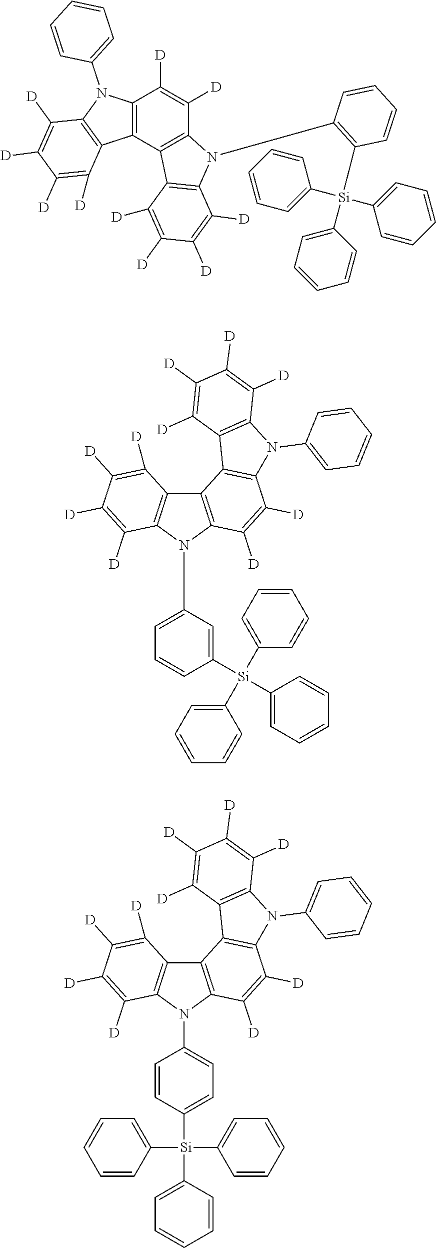

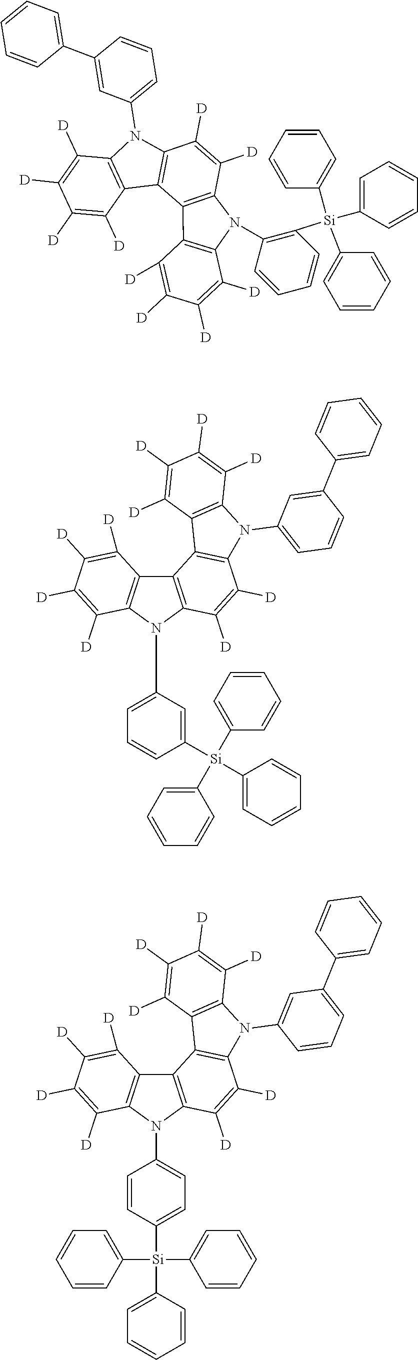 [SMILES: [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1cccc(-c2ccccc2)c1 ; [2H]c1c([2H])c([2H])c2c(c1[2H])c1c3c4c([2H])c([2H])c([2H])c([2H])c4n(-c4cccc([Si](c5ccccc5)(c5ccccc5)c5ccccc5)c4)c3c([2H])c([2H])c1n2-c1cccc(-c2ccccc2)c1 ; [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1ccc([Si](c2ccccc2)(c2ccccc2)c2ccccc2)cc1]

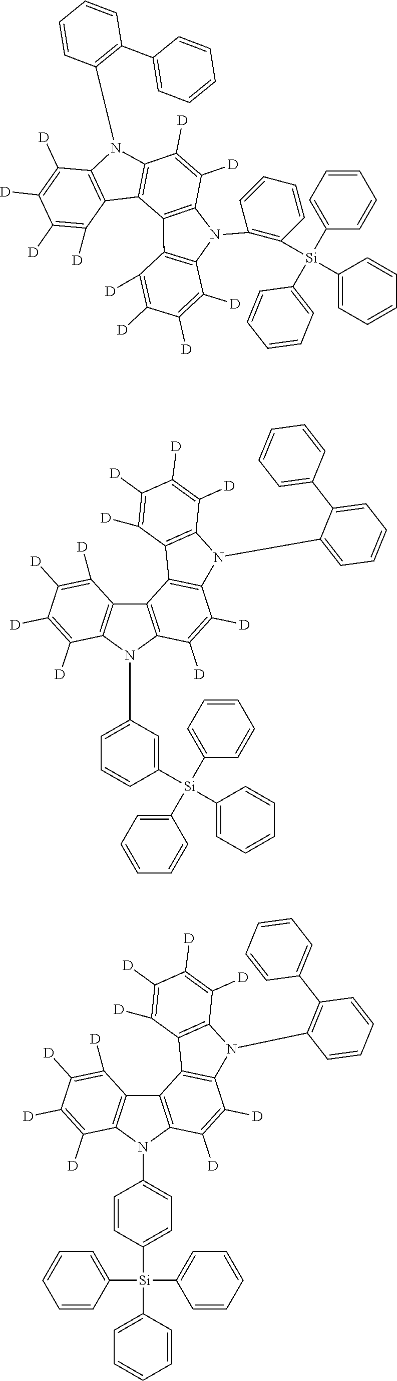 [SMILES: [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1ccccc1-c1ccccc1 ; [2H]c1c([2H])c([2H])c2c(c1[2H])c1c3c4c([2H])c([2H])c([2H])c([2H])c4n(-c4ccccc4-c4ccccc4)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4ccccc4-c4ccccc4)c3c([2H])c([2H])c1n2-c1ccc([Si](c2ccccc2)(c2ccccc2)c2ccccc2)cc1]

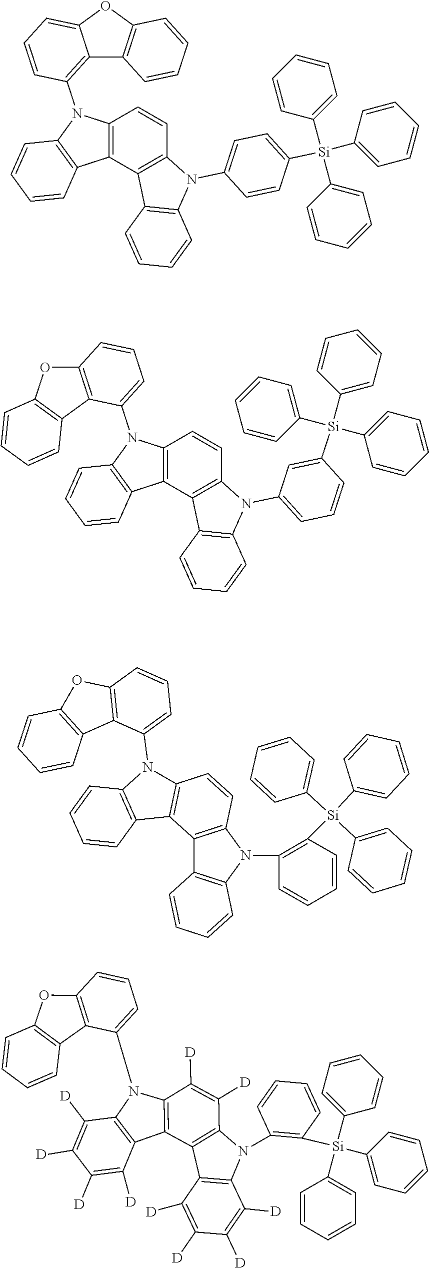 [SMILES: c1ccc([Si](c2ccccc2)(c2ccccc2)c2ccc(-n3c4ccccc4c4c5c6ccccc6n(-c6cccc7oc8ccccc8c67)c5ccc43)cc2)cc1 ; c1ccc([Si](c2ccccc2)(c2ccccc2)c2cccc(-n3c4ccccc4c4c5c6ccccc6n(-c6cccc7oc8ccccc8c67)c5ccc43)c2)cc1 ; c1ccc([Si](c2ccccc2)(c2ccccc2)c2ccccc2-n2c3ccccc3c3c4c5ccccc5n(-c5cccc6oc7ccccc7c56)c4ccc32)cc1 ; [2H]c1c([2H])c([2H])c2c(c1[2H])c1c3c4c([2H])c([2H])c([2H])c([2H])c4n(-c4cccc5oc6ccccc6c45)c3c([2H])c([2H])c1n2-c1ccccc1[Si](c1ccccc1)(c1ccccc1)c1ccccc1]

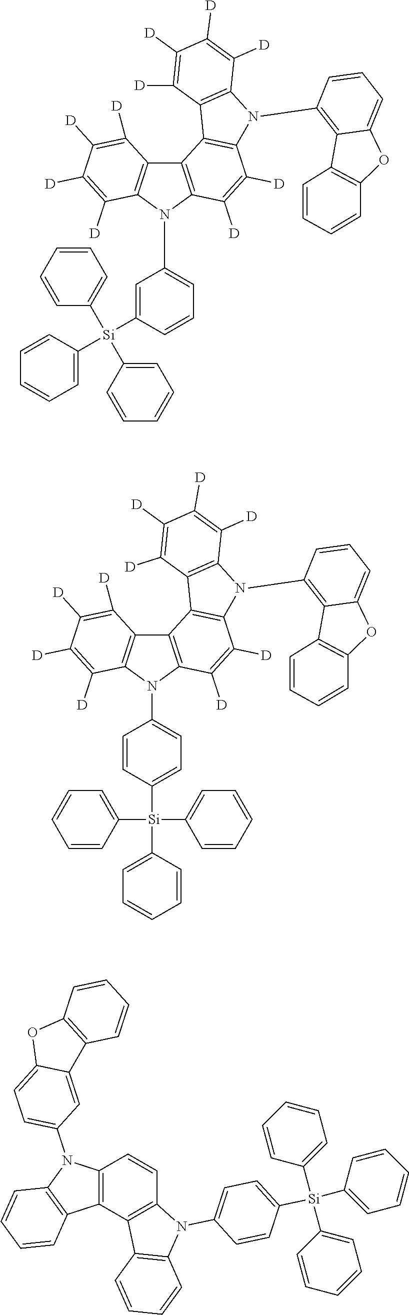 [SMILES: [2H]c1c([2H])c([2H])c2c(c1[2H])c1c3c4c([2H])c([2H])c([2H])c([2H])c4n(-c4cccc5oc6ccccc6c45)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4cccc5oc6ccccc6c45)c3c([2H])c([2H])c1n2-c1ccc([Si](c2ccccc2)(c2ccccc2)c2ccccc2)cc1 ; c1ccc([Si](c2ccccc2)(c2ccccc2)c2ccc(-n3c4ccccc4c4c5c6ccccc6n(-c6ccc7oc8ccccc8c7c6)c5ccc43)cc2)cc1]

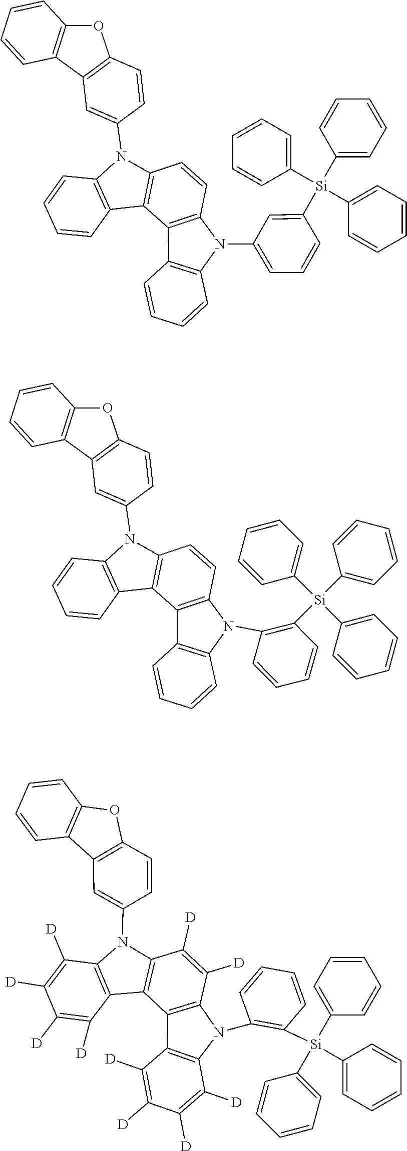 [SMILES: c1ccc([Si](c2ccccc2)(c2ccccc2)c2cccc(-n3c4ccccc4c4c5c6ccccc6n(-c6ccc7oc8ccccc8c7c6)c5ccc43)c2)cc1 ; c1ccc([Si](c2ccccc2)(c2ccccc2)c2ccccc2-n2c3ccccc3c3c4c5ccccc5n(-c5ccc6oc7ccccc7c6c5)c4ccc32)cc1 ; [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1ccc2oc3ccccc3c2c1]

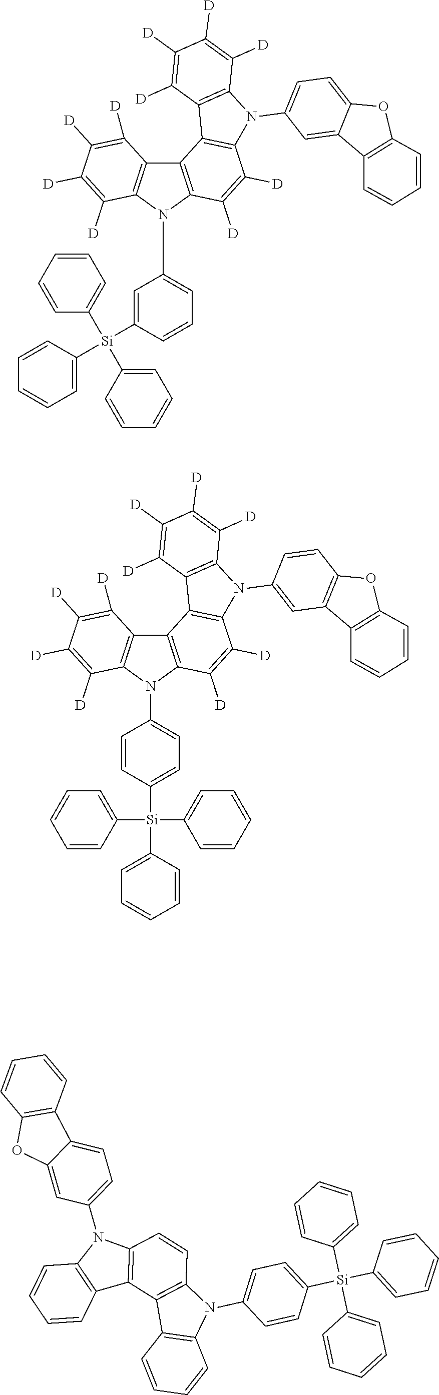 [SMILES: [2H]c1c([2H])c([2H])c2c(c1[2H])c1c3c4c([2H])c([2H])c([2H])c([2H])c4n(-c4ccc5oc6ccccc6c5c4)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4ccc5oc6ccccc6c5c4)c3c([2H])c([2H])c1n2-c1ccc([Si](c2ccccc2)(c2ccccc2)c2ccccc2)cc1 ; c1ccc([Si](c2ccccc2)(c2ccccc2)c2ccc(-n3c4ccccc4c4c5c6ccccc6n(-c6ccc7c(c6)oc6ccccc67)c5ccc43)cc2)cc1]

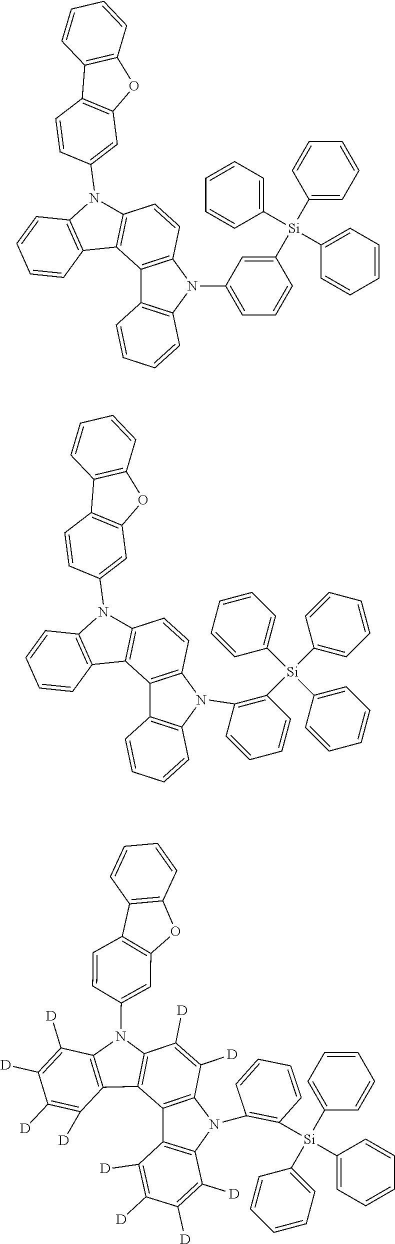 [SMILES: c1ccc([Si](c2ccccc2)(c2ccccc2)c2cccc(-n3c4ccccc4c4c5c6ccccc6n(-c6ccc7c(c6)oc6ccccc67)c5ccc43)c2)cc1 ; c1ccc([Si](c2ccccc2)(c2ccccc2)c2ccccc2-n2c3ccccc3c3c4c5ccccc5n(-c5ccc6c(c5)oc5ccccc56)c4ccc32)cc1 ; [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1ccc2c(c1)oc1ccccc12]

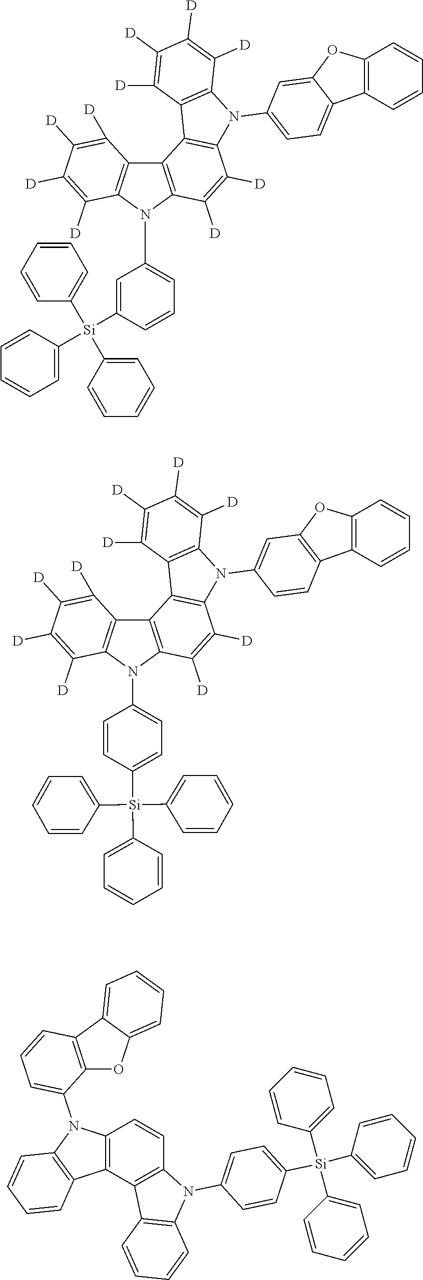 [SMILES: [2H]c1c([2H])c([2H])c2c(c1[2H])c1c3c4c([2H])c([2H])c([2H])c([2H])c4n(-c4ccc5c(c4)oc4ccccc45)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4ccc5c(c4)oc4ccccc45)c3c([2H])c([2H])c1n2-c1ccc([Si](c2ccccc2)(c2ccccc2)c2ccccc2)cc1 ; c1ccc([Si](c2ccccc2)(c2ccccc2)c2ccc(-n3c4ccccc4c4c5c6ccccc6n(-c6cccc7c6oc6ccccc67)c5ccc43)cc2)cc1]

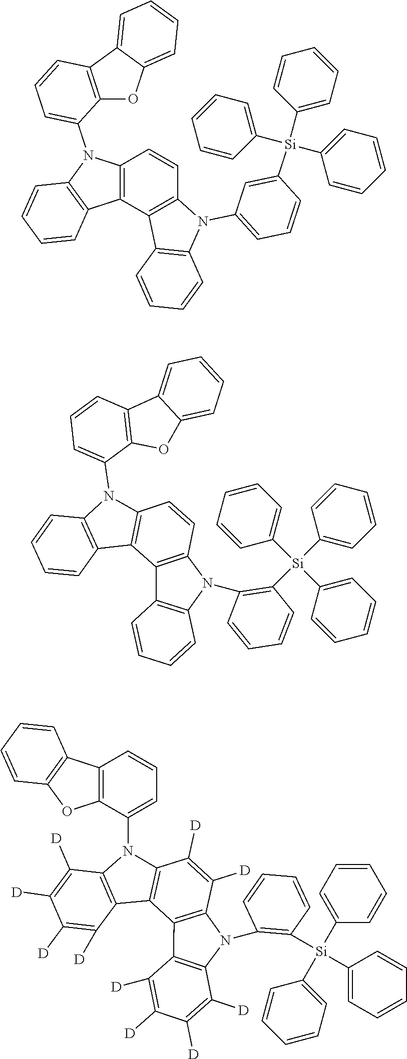 [SMILES: c1ccc([Si](c2ccccc2)(c2ccccc2)c2cccc(-n3c4ccccc4c4c5c6ccccc6n(-c6cccc7c6oc6ccccc67)c5ccc43)c2)cc1 ; c1ccc([Si](c2ccccc2)(c2ccccc2)c2ccccc2-n2c3ccccc3c3c4c5ccccc5n(-c5cccc6c5oc5ccccc56)c4ccc32)cc1 ; [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1ccccc1[Si](c1ccccc1)(c1ccccc1)c1ccccc1]

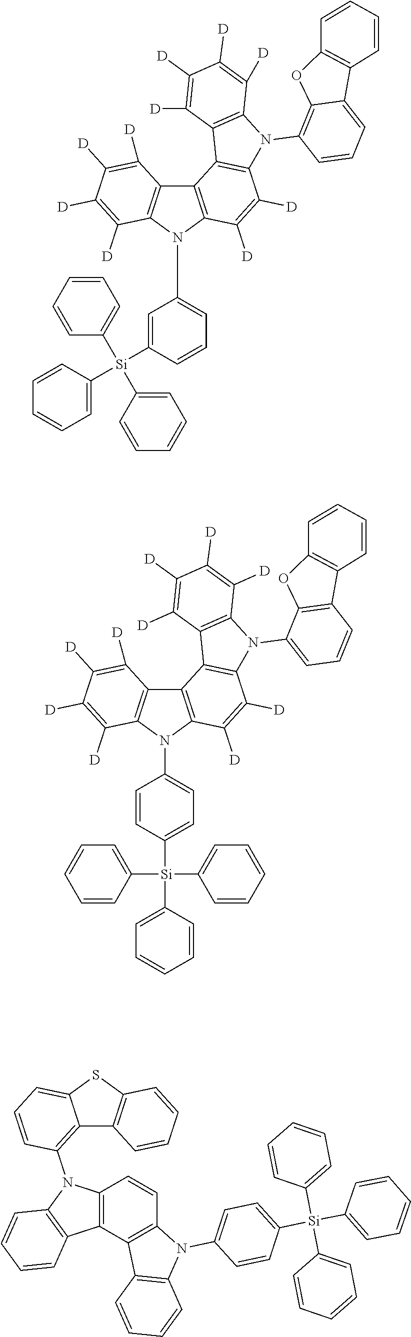 [SMILES: [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1ccc([Si](c2ccccc2)(c2ccccc2)c2ccccc2)cc1 ; c1ccc([Si](c2ccccc2)(c2ccccc2)c2ccc(-n3c4ccccc4c4c5c6ccccc6n(-c6cccc7sc8ccccc8c67)c5ccc43)cc2)cc1]

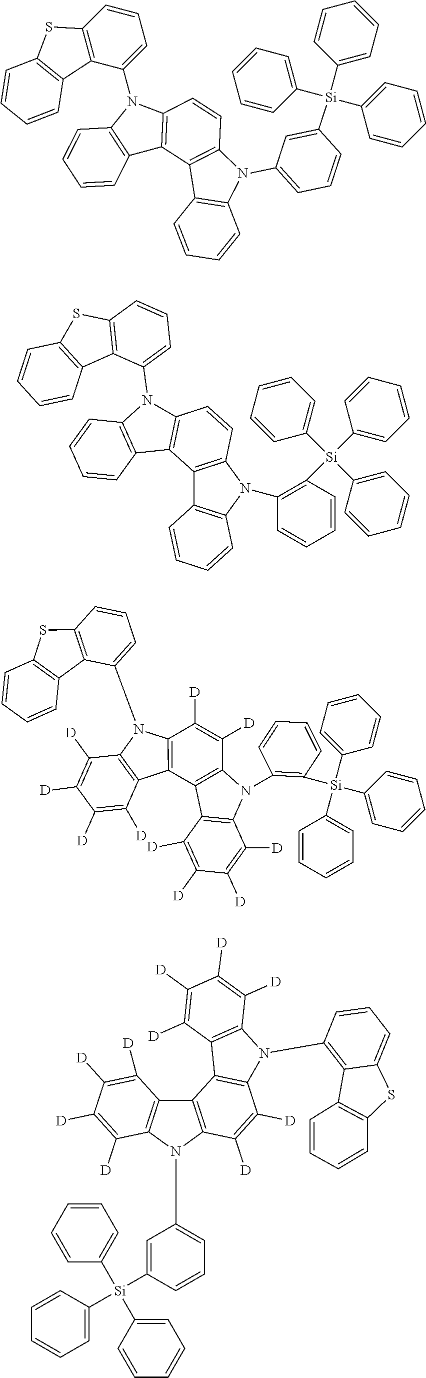

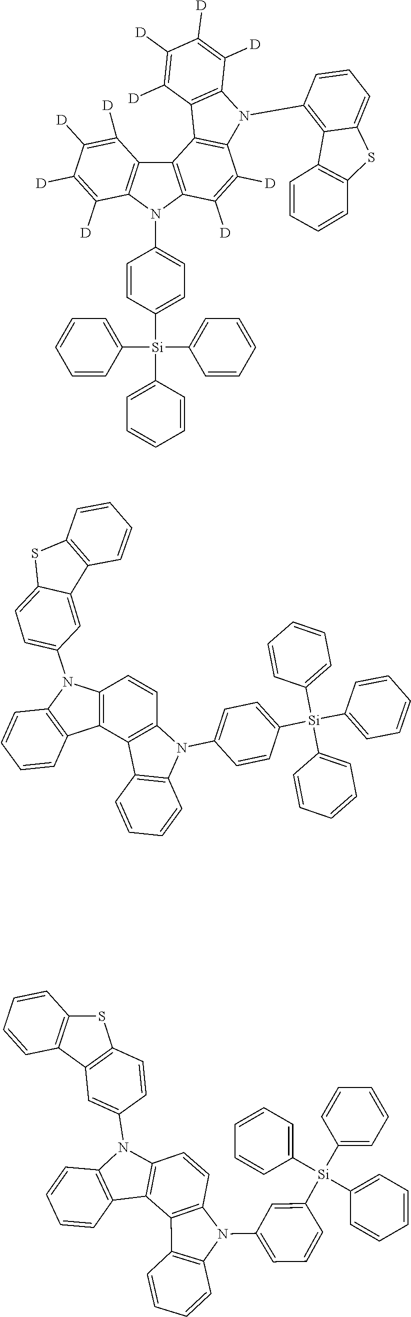 [SMILES: [2H]c1c([2H])c([2H])c2c(c1[2H])c1c3c4c([2H])c([2H])c([2H])c([2H])c4n(-c4cccc5sc6ccccc6c45)c3c([2H])c([2H])c1n2-c1ccc([Si](c2ccccc2)(c2ccccc2)c2ccccc2)cc1 ; c1ccc([Si](c2ccccc2)(c2ccccc2)c2ccc(-n3c4ccccc4c4c5c6ccccc6n(-c6ccc7sc8ccccc8c7c6)c5ccc43)cc2)cc1 ; c1ccc([Si](c2ccccc2)(c2ccccc2)c2cccc(-n3c4ccccc4c4c5c6ccccc6n(-c6ccc7sc8ccccc8c7c6)c5ccc43)c2)cc1]

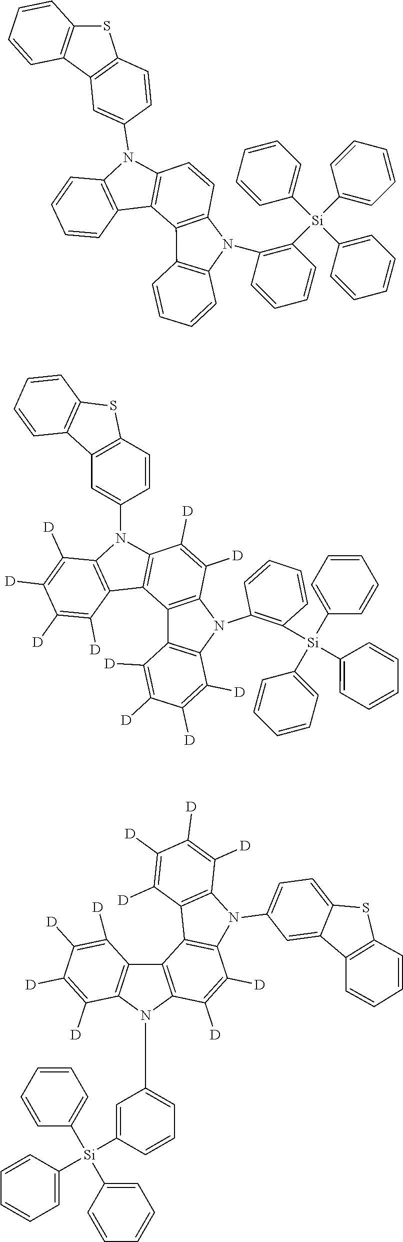 [SMILES: c1ccc([Si](c2ccccc2)(c2ccccc2)c2ccccc2-n2c3ccccc3c3c4c5ccccc5n(-c5ccc6sc7ccccc7c6c5)c4ccc32)cc1 ; [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1ccc2sc3ccccc3c2c1 ; [2H]c1c([2H])c([2H])c2c(c1[2H])c1c3c4c([2H])c([2H])c([2H])c([2H])c4n(-c4ccc5sc6ccccc6c5c4)c3c([2H])c([2H])c1n2-c1cccc([Si](c2ccccc2)(c2ccccc2)c2ccccc2)c1]

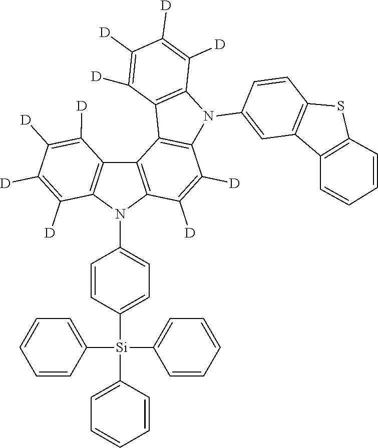 [SMILES: [2H]c1c([2H])c([2H])c2c(c1[2H])c1c3c4c([2H])c([2H])c([2H])c([2H])c4n(-c4ccc5sc6ccccc6c5c4)c3c([2H])c([2H])c1n2-c1ccc([Si](c2ccccc2)(c2ccccc2)c2ccccc2)cc1]

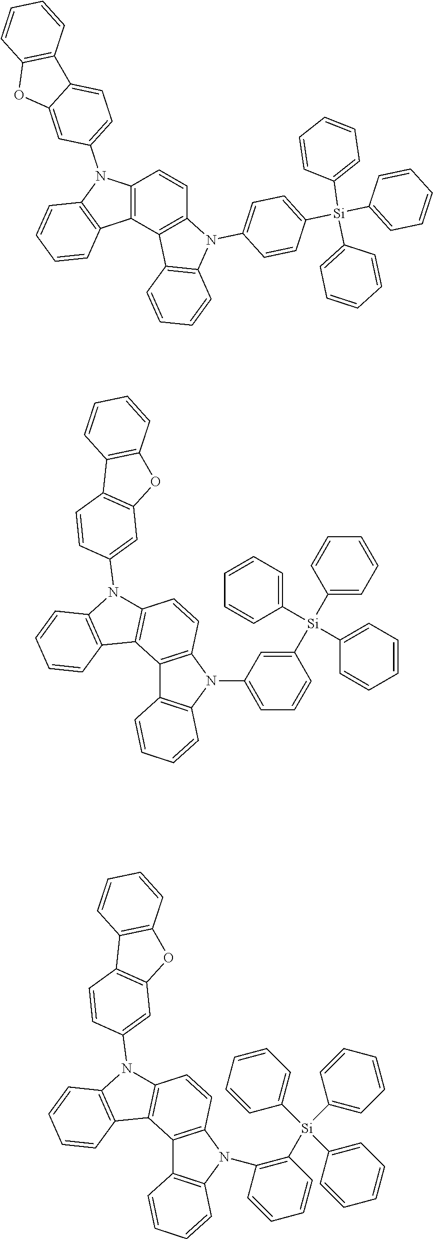 [SMILES: c1ccc([Si](c2ccccc2)(c2ccccc2)c2ccc(-n3c4ccccc4c4c5c6ccccc6n(-c6ccc7c(c6)oc6ccccc67)c5ccc43)cc2)cc1 ; c1ccc([Si](c2ccccc2)(c2ccccc2)c2cccc(-n3c4ccccc4c4c5c6ccccc6n(-c6ccc7c(c6)oc6ccccc67)c5ccc43)c2)cc1 ; c1ccc([Si](c2ccccc2)(c2ccccc2)c2ccccc2-n2c3ccccc3c3c4c5ccccc5n(-c5ccc6c(c5)oc5ccccc56)c4ccc32)cc1]

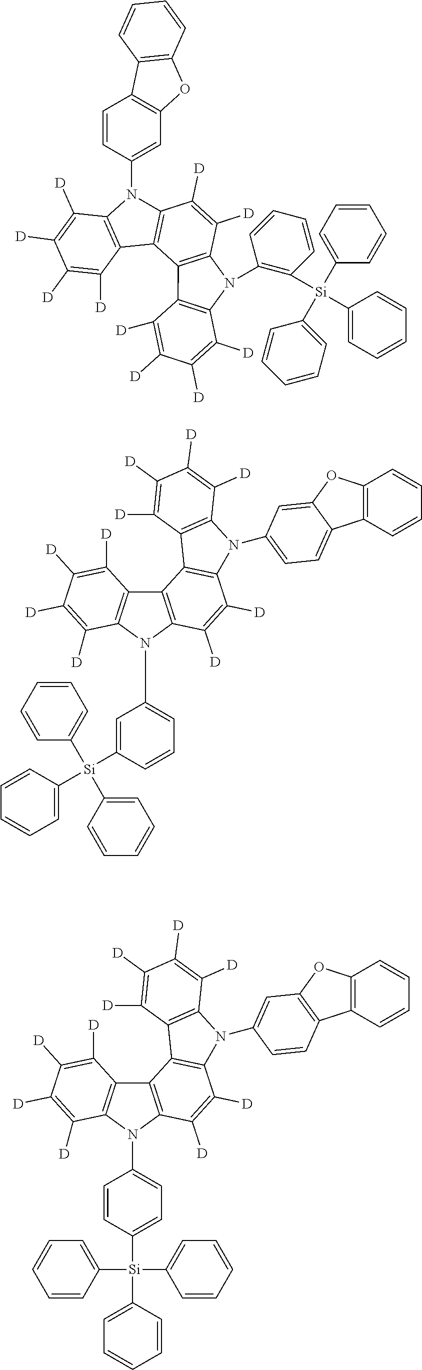

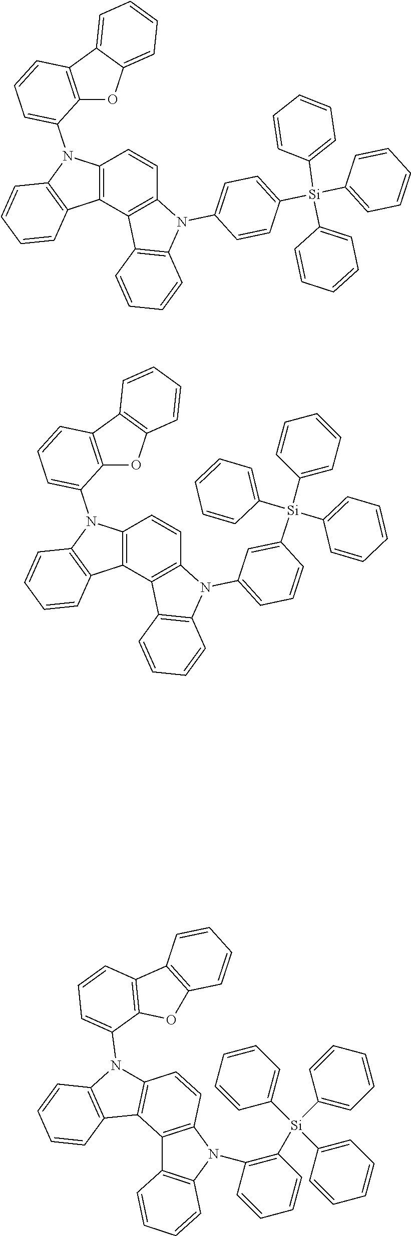 [SMILES: c1ccc([Si](c2ccccc2)(c2ccccc2)c2ccc(-n3c4ccccc4c4c5c6ccccc6n(-c6cccc7c6oc6ccccc67)c5ccc43)cc2)cc1 ; c1ccc([Si](c2ccccc2)(c2ccccc2)c2cccc(-n3c4ccccc4c4c5c6ccccc6n(-c6cccc7c6oc6ccccc67)c5ccc43)c2)cc1 ; c1ccc([Si](c2ccccc2)(c2ccccc2)c2ccccc2-n2c3ccccc3c3c4c5ccccc5n(-c5cccc6c5oc5ccccc56)c4ccc32)cc1]

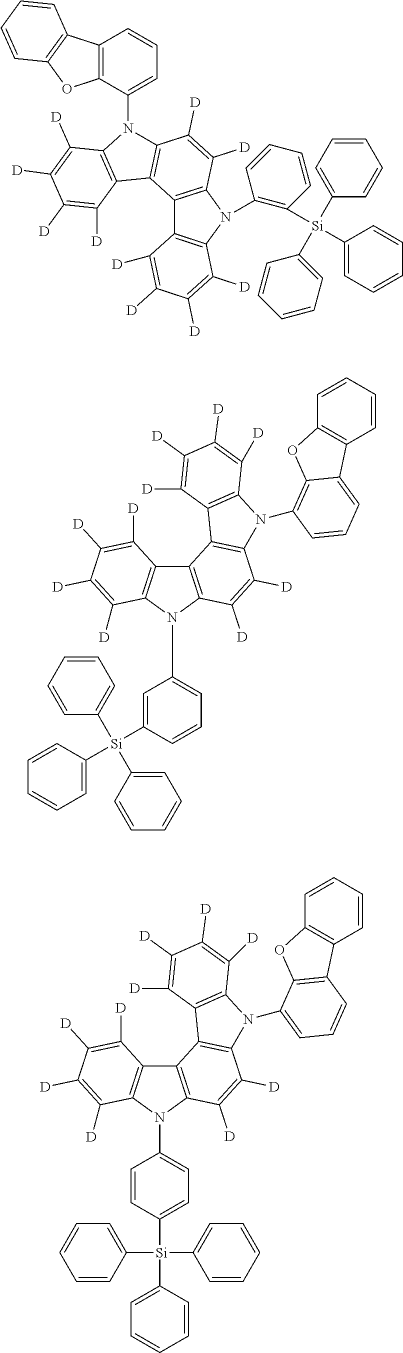 [SMILES: [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1ccccc1[Si](c1ccccc1)(c1ccccc1)c1ccccc1 ; [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1ccc([Si](c2ccccc2)(c2ccccc2)c2ccccc2)cc1]

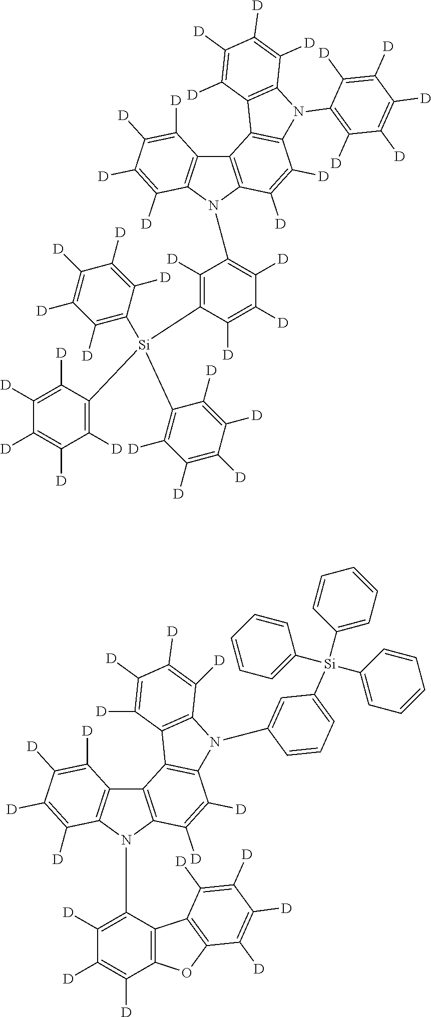 [SMILES: [2H]c1c([2H])c([2H])c(-n2c3c([2H])c([2H])c([2H])c([2H])c3c3c4c5c([2H])c([2H])c([2H])c([2H])c5n(-c5c([2H])c([2H])c([2H])c([Si](c6c([2H])c([2H])c([2H])c([2H])c6[2H])(c6c([2H])c([2H])c([2H])c([2H])c6[2H])c6c([2H])c([2H])c([2H])c([2H])c6[2H])c5[2H])c4c([2H])c([2H])c32)c([2H])c1[2H] ; [2H]c1c([2H])c([2H])c2c(oc3c([2H])c([2H])c([2H])c(-n4c5c([2H])c([2H])c([2H])c([2H])c5c5c6c7c([2H])c([2H])c([2H])c([2H])c7n(-c7cccc([Si](c8ccccc8)(c8ccccc8)c8ccccc8)c7)c6c([2H])c([2H])c54)c32)c1[2H]]

Hereinafter, an organic light emitting device will be described in detail.

An exemplary embodiment of the present specification provides an organic light emitting device including: an anode; a cathode; and an organic material layer having one or more layers provided between the anode and the cathode, in which one or more layers of the organic material layer include the compound of Chemical Formula 1.

Specifically, the organic light emitting device includes: an anode; a cathode; and one or more organic material layers, which includes a light emitting layer, provided between the anode and the cathode, and one or more layers of the organic material layer include the compound of Chemical Formula 1.

The organic light emitting device of the present specification may be manufactured using typical manufacturing methods and materials of an organic light emitting device, except that the above-described compound is used to form an organic material layer having one or more layers.

In an exemplary embodiment of the present specification, the organic material layer including the compound of Chemical Formula 1 has a thickness of 10 Å to 600 Å, preferably 50 Å to 500 Å, and more preferably 50 Å to 400 Å.

The compound may be formed as an organic material layer by not only a vacuum deposition method, but also a solution application method when an organic light emitting device is manufactured. Here, the solution coating method means spin coating, dip coating, inkjet printing, screen printing, doctor blading, a spray method, roll coating, and the like, but is not limited thereto.

For example, the organic light emitting device of the present specification may be manufactured by sequentially stacking an anode, an organic material layer, and a cathode on a substrate. In this case, the organic light emitting device may be manufactured by forming an anode on a substrate by depositing a metal, a metal oxide having conductivity, or an alloy thereof using a physical vapor deposition (PVD) method such as sputtering or e-beam evaporation, and forming an organic material layer thereon, and then depositing a material capable of being used as a cathode thereon. In addition to the method described above, an organic light emitting device may be made by sequentially depositing a cathode material, an organic material layer, and an anode material on a substrate.

In an exemplary embodiment of the present specification, the organic material layer may be composed of a single-layered structure, and may also composed of a multi-layered structure in which two or more organic material layers are stacked. For example, when the organic light emitting device includes a plurality of organic material layers, the organic material layer may have a multi-layered structure including a hole injection layer, a hole transport layer, a hole injection and transport layer, an electron blocking layer, a light emitting layer, an electron transport layer, an electron injection layer, and an electron injection and transport layer, and the like. However, the structure of the organic light emitting device is not limited thereto, and may include a fewer or greater number of organic material layers.

The organic material layer may be formed of the same material or different materials. Further, the organic material layer may be formed by a vapor deposition method and/or a solution process using various polymeric materials.

In an exemplary embodiment of the present specification, the organic material layer includes a light emitting layer. In this case, the light emitting layer may or may not include the compound of Chemical Formula 1.

In an exemplary embodiment of the present specification, the organic material layer includes one or more layers selected from the group consisting of a hole blocking layer, an electron transport layer, and an electron injection layer. In this case, the hole blocking layer, the electron transport layer, and the electron injection layer may or may not include the compound of Chemical Formula 1.

In an exemplary embodiment of the present specification, the organic material layer includes one or more layers selected from the group consisting of a hole injection layer, a hole transport layer, and an electron blocking layer. In this case, the hole injection layer, the hole transport layer, and the electron blocking layer may or may not include the compound of Chemical Formula 1.

In an exemplary embodiment of the present specification, the organic material layer including the compound of Chemical Formula 1 is one or more selected from the group consisting of a hole injection layer, a hole transport layer, an electron blocking layer, and a light emitting layer.

In an exemplary embodiment of the present specification, the organic material layer including the compound of Chemical Formula 1 is one or more selected from the group consisting of an electron blocking layer and a light emitting layer.

In an exemplary embodiment of the present specification, the organic material layer including the compound of Chemical Formula 1 is a light emitting layer, and the light emitting layer includes the compound of Chemical Formula 1 as a host.

The light emitting layer including the compound of Chemical Formula 1 may include only a single material, or may further include an additional material. For example, the compound of Chemical Formula 1 may serve as a host in the light emitting layer, and in this case, an additional host and/or dopant may be further included.

In an exemplary embodiment of the present specification, the organic light emitting device includes: an anode; a cathode; and a light emitting layer provided between the anode and the cathode, and further includes a single-layered organic material layer between the light emitting layer and the anode, and the light emitting layer includes the compound of Chemical Formula 1.

In an exemplary embodiment of the present specification, the organic light emitting device includes: an anode; a cathode; and a light emitting layer provided between the anode and the cathode, and further includes a multi-layered organic material layer between the light emitting layer and the anode, and the light emitting layer includes the compound of Chemical Formula 1. In this case, the multi-layered organic material layer may or may not include the compound of Chemical Formula 1.

In an exemplary embodiment of the present specification, the organic light emitting device includes: an anode; a cathode; and a light emitting layer provided between the anode and the cathode, and further includes one or more layers of a hole injection layer, a hole transport layer, and an electron blocking layer between the light emitting layer and the anode, and the light emitting layer includes the compound of Chemical Formula 1. In this case, one or more layer of the hole injection layer, the hole transport layer, and the electron blocking layer may or may not include the compound of Chemical Formula 1.

In an exemplary embodiment of the present specification, the organic light emitting device includes: an anode; a cathode; and a light emitting layer provided between the anode and the cathode, and includes a hole injection layer, a hole transport layer, and an electron blocking layer between the anode and the light emitting layer, and the light emitting layer includes the compound of Chemical Formula 1. In this case, the electron blocking layer may or may not include the compound of Chemical Formula 1.

In an exemplary embodiment of the present specification, the organic light emitting device has a structure in which an anode; a hole injection layer; a hole transport layer; an electron blocking layer; a light emitting layer; and a cathode are sequentially stacked, and the light emitting layer includes the compound of Chemical Formula 1. In this case, an additional organic material layer may be further provided between each of the layers.

In an exemplary embodiment of the present specification, the organic light emitting device includes: an anode; a cathode; and a light emitting layer provided between the anode and the cathode, and further includes a single-layered organic material layer between the light emitting layer and the cathode, and the light emitting layer includes the compound of Chemical Formula 1.

In an exemplary embodiment of the present specification, the organic light emitting device includes: an anode; a cathode; and a light emitting layer provided between the anode and the cathode, and further includes a multi-layered organic material layer between the light emitting layer and the cathode, and the light emitting layer includes the compound of Chemical Formula 1.

In an exemplary embodiment of the present specification, the organic light emitting device includes: an anode; a cathode; and a light emitting layer provided between the anode and the cathode, and further includes one or more layers of a hole blocking layer an electron injection layer, an electron transport layer, and an electron injection and transport layer between the cathode and the light emitting layer, and the light emitting layer includes the compound of Chemical Formula 1.

In an exemplary embodiment of the present specification, the organic light emitting device includes: an anode; a cathode; and a light emitting layer provided between the anode and the cathode, and includes a hole blocking layer and an electron injection and transport layer between the cathode and the light emitting layer, and the light emitting layer includes the compound of Chemical Formula 1.

In an exemplary embodiment of the present specification, the organic light emitting device has a structure in which an anode; a light emitting layer; a hole blocking layer; an electron injection and transport layer; and a cathode are sequentially stacked, and the light emitting layer includes the compound of Chemical Formula 1. In this case, an additional organic material layer may be further provided between each of the layers.

In an exemplary embodiment of the present specification, the organic light emitting device has a structure in which an anode; a hole injection layer; a hole transport layer; an electron blocking layer; a light emitting layer; a hole blocking layer; an electron injection and transport layer; and a cathode are sequentially stacked, and the light emitting layer includes the compound of Chemical Formula 1. In this case, the electron blocking layer may or may not include the compound of Chemical Formula 1.

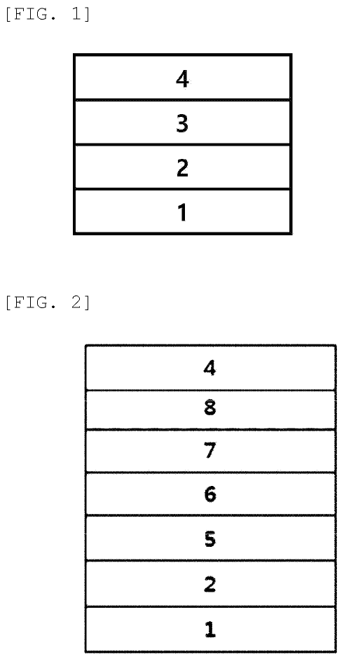

For example, the structure of the organic light emitting device of the present specification may have structures illustrated in FIGS. 1 to 3, but is not limited thereto.

FIG. 1 illustrates an example of an organic light emitting device composed of a substrate 1, an anode 2, an organic material layer 3, and a cathode 4.

FIG. 2 illustrates an example of an organic light emitting device composed of a substrate 1, an anode 2, a hole injection layer 5, a hole transport layer 6, a light emitting layer 7, an electron transport layer 8, and a cathode 4.

FIG. 3 illustrates an example of an organic light emitting device in which a substrate 1, an anode 2, a hole injection layer 5, a hole transport layer 6, an electron blocking layer 9, a light emitting layer 7, a hole blocking layer 10, an electron injection and transport layer 11, and a cathode 4 are sequentially stacked.

Specifically, the organic light emitting device may have, for example, the stacking structure described below in addition to the structure shown in the drawings, but the stacking structure is not limited thereto.
(1) Anode/Hole transport layer/Light emitting layer/Cathode
(2) Anode/Hole injection layer/Hole transport layer/Light emitting layer/Cathode
(3) Anode/Hole transport layer/Light emitting layer/Electron transport layer/Cathode
(4) Anode/Hole transport layer/Light emitting layer/Electron transport layer/Electron injection layer/Cathode
(5) Anode/Hole injection layer/Hole transport layer/Light emitting layer/Electron transport layer/Cathode
(6) Anode/Hole injection layer/Hole transport layer/Light emitting layer/Electron transport layer/Electron injection layer/Cathode
(7) Anode/Hole transport layer/Electron blocking layer/Light emitting layer/Electron transport layer/Cathode
(8) Anode/Hole transport layer/Electron blocking layer/Light emitting layer/Electron transport layer/Electron injection layer/Cathode
(9) Anode/Hole injection layer/Hole transport layer/Electron blocking layer/Light emitting layer/Electron transport layer/Cathode
(10) Anode/Hole injection layer/Hole transport layer/Electron blocking layer/Light emitting layer/Electron transport layer/Electron injection layer/Cathode
(11) Anode/Hole transport layer/Light emitting layer/Hole blocking layer/Electron transport layer/Cathode
(12) Anode/Hole transport layer/Light emitting layer/Hole blocking layer/Electron transport layer/Electron injection layer/Cathode
(13) Anode/Hole injection layer/Hole transport layer/Light emitting layer/Hole blocking layer/Electron transport layer/Cathode
(14) Anode/Hole injection layer/Hole transport layer/Light emitting layer/Hole blocking layer/Electron transport layer/Electron injection layer/Cathode
(15) Anode/Hole injection layer/Hole transport layer/Electron blocking layer/Light emitting layer/Hole blocking layer/Electron transport layer/Electron injection layer/Cathode

In an exemplary embodiment of the present specification, the ‘Electron transport layer/Electron injection layer’ may be replaced with an ‘Electron injection and transport layer’ or ‘Layer which injects and transports electrons simultaneously’. For example, number (15) above may be an organic light emitting device having a stacking order of ‘Anode/Hole injection layer/Hole transport layer/Electron blocking layer/Light emitting layer/Hole blocking layer/Electron injection and transport layer/Cathode’.

In an exemplary embodiment of the present specification, the ‘Hole injection layer/Hole transport layer’ may be replaced with an ‘Hole injection and transport layer’ or ‘Layer which injects and transports holes simultaneously’. For example, number (15) above may be an organic light emitting device having a stacking order of ‘Anode/Hole injection and transport layer/Electron blocking layer/Light emitting layer/Hole blocking layer/Electron transport layer/Electron injection layer/Cathode’.

The anode is an electrode which injects holes, and as an anode material, materials having a high work function are usually preferred so as to facilitate the injection of holes into an organic material layer. Specific examples of the anode material which may be used in the present invention include: a metal, such as vanadium, chromium, copper, zinc, and gold, or an alloy thereof; a metal oxide, such as zinc oxide, indium oxide, indium tin oxide (ITO), and indium zinc oxide (IZO); a combination of a metal and an oxide, such as ZnO:Al or SnO₂:Sb; a conductive polymer, such as poly(3-methylthiophene), poly[3,4-(ethylene-1,2-dioxy)thiophene] (PEDOT), polypyrrole, and polyaniline; and the like, but are not limited thereto.

The cathode is an electrode which injects electrons, and as a cathode material, materials having a low work function are usually preferred so as to facilitate the injection of electrons into an organic material layer. Specific examples of the cathode material which may be used in the present invention include: a metal, such as magnesium, calcium, sodium, potassium, titanium, indium, yttrium, lithium, gadolinium, aluminum, silver, tin, and lead, or an alloy thereof; a multi-layered structural material, such as LiF/Al or LiO₂/Al, and the like, but are not limited thereto.

The hole injection layer may perform a role of smoothly injecting holes from an anode to a light emitting layer. The hole injection material is a material which may proficiently accept holes from an anode at low voltage, and the highest occupied molecular orbital (HOMO) of the hole injection material is preferably a value between the work function of the anode and the HOMO of the neighboring organic material layer. Specific examples of the hole injection material include metal porphyrin, oligothiophene, arylamine-based compounds, hexanitrile hexaazatriphenylene-based compounds, quinacridone-based compounds, perylene-based compounds, benzonitrile-based compounds, anthraquinone, polyaniline-based and polythiophene-based conductive polymers, and the like, but are not limited thereto.

Specifically, an arylamine-based compound and a benzonitrile-based compound may be used for the hole injection layer. More specifically, an arylamine-based compound substituted with a carbazole group and a benzonitrile-based compound substituted with a halogen group may be used, but the present invention is not limited thereto.

The hole injection layer may have a thickness of 1 nm to 150 nm. When the hole injection layer has a thickness of 1 nm or more, there is an advantage in that it is possible to prevent hole injection characteristics from deteriorating, and when the hole injection layer has a thickness of 150 nm or less, there is an advantage in that it is possible to prevent the driving voltage from being increased in order to improve the movement of holes due to the too thick hole injection layer.

In an exemplary embodiment of the present specification, the hole injection layer includes a compound of the following Chemical Formula HI-1.

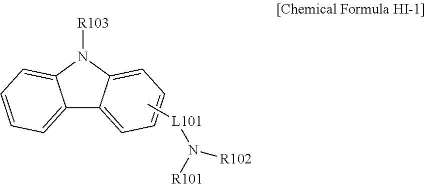

In Chemical Formula HI-1,
L101 is a direct bond or a substituted or unsubstituted arylene group, and
R101 to R103 are the same as or different from each other, and are each independently a substituted or unsubstituted aryl group.

In an exemplary embodiment of the present specification, L101 is a direct bond, a substituted or unsubstituted phenylene group, or a substituted or unsubstituted naphthylene group.

In an exemplary embodiment of the present specification, L101 is a direct bond or a substituted or unsubstituted phenylene group.

In an exemplary embodiment of the present specification, L101 is a direct bond or a phenylene group.

In an exemplary embodiment of the present specification, R101 to R103 are the same as or different from each other, and are each independently a substituted or unsubstituted monocyclic aryl group or a substituted or unsubstituted polycyclic aryl group.

In an exemplary embodiment of the present specification, R101 to R103 are the same as or different from each other, and are each independently a substituted or unsubstituted phenyl group; a substituted or unsubstituted biphenyl group; a substituted or unsubstituted terphenyl group; a substituted or unsubstituted naphthyl group; a substituted or unsubstituted anthracenyl group; a substituted or unsubstituted phenanthrenyl group; a substituted or unsubstituted triphenylenyl group; a substituted or unsubstituted pyrene group; or a substituted or unsubstituted fluorenyl group.

In an exemplary embodiment of the present specification, R101 to R103 are the same as or different from each other, and are each independently a substituted or unsubstituted phenyl group; a substituted or unsubstituted biphenyl group; or a substituted or unsubstituted fluorenyl group.

In an exemplary embodiment of the present specification, R101 to R103 are the same as or different from each other, and are each independently a phenyl group; a biphenyl group; or a fluorenyl group substituted with an alkyl group.

In an exemplary embodiment of the present specification, the compound of Chemical Formula HI-1 is any one of the following compounds.

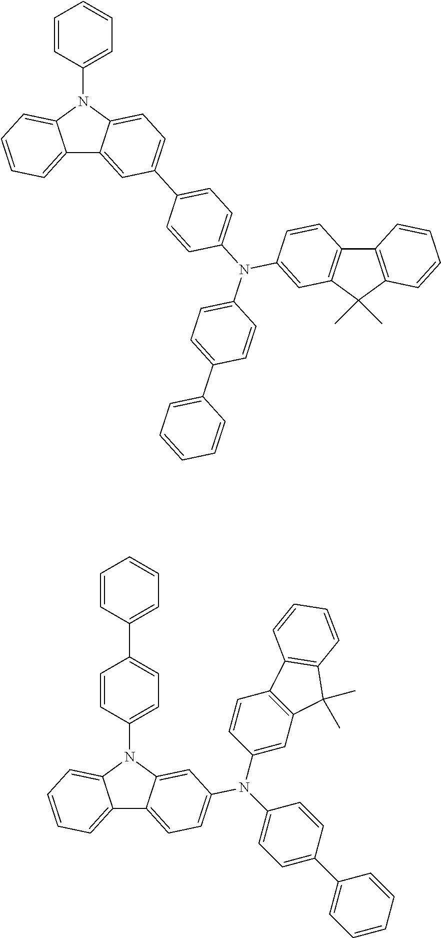 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c5ccccc5n(-c5ccc(-c6ccccc6)cc5)c4c3)cc21]

In an exemplary embodiment of the present specification, the hole injection layer includes a compound of the following Chemical Formula HI-2.

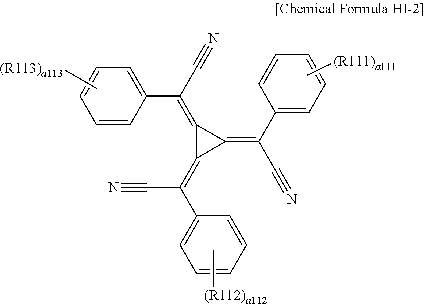

In Chemical Formula HI-2,
R111 to R113 are the same as or different from each other, and are each independently hydrogen; a halogen group; a nitrile group; a substituted or unsubstituted alkyl group; a substituted or unsubstituted aryl group; or a substituted or unsubstituted heterocyclic group,
a111 to a113 are each an integer from 1 to 5,
when a111 is 2 or higher, two or more R111s are the same as or different from each other,
when a112 is 2 or higher, two or more R112s are the same as or different from each other, and
when a113 is 2 or higher, two or more R113s are the same as or different from each other.

In an exemplary embodiment of the present specification, R111 to R113 are the same as or different from each other, and are each a halogen group or a nitrile group.

In an exemplary embodiment of the present specification, R111 to R113 are the same as or different from each other, and are each fluorine or a nitrile group.

In an exemplary embodiment of the present specification, the compound of Chemical Formula HI-2 has the following structure.

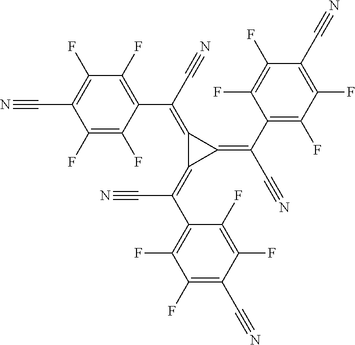 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

In an exemplary embodiment of the present specification, the hole injection layer includes the compound of Chemical Formula HI-1 and the compound of Chemical Formula HI-2.

The hole transport layer may perform a role of smoothly transporting holes. A hole transport material is suitably a material having high hole mobility which may accept holes from an anode or a hole injection layer and transfer the holes to a light emitting layer. Specific examples of the hole transport material include arylamine-based compounds, carbazole-based compounds, conductive polymers, block copolymers having both conjugated portions and non-conjugated portions, and the like, but are not limited thereto. Specifically, a carbazole-based compound substituted with an arylamine group may be used for the hole transport layer, but the present invention is not limited thereto. More specifically, the compound of Chemical Formula HI-1 may be used for the hole transport layer.

An electron blocking layer may be provided between the hole transport layer and the light emitting layer. The above-described compound or a material known in the art may be used in the electron blocking layer. Specifically, a carbazole-based compound or an indolocarbazole-based compound may be used for the electron blocking layer.

In an exemplary embodiment of the present specification, the compound of Chemical Formula 1 may be used for the electron blocking layer.

The light emitting layer may emit red, green, or blue light, and may be composed of a phosphorescent material or a fluorescent material. The light emitting material is a material which may accept holes and electrons from a hole transport layer and an electron transport layer, respectively, and combine the holes and the electrons to emit light in a visible ray region, and is preferably a material having high quantum efficiency to fluorescence or phosphorescence.

Examples of the host material for the light emitting layer include condensed aromatic ring derivatives, or hetero ring-containing compounds, and the like. For example, examples of the fused aromatic ring derivative include anthracene derivatives, pyrene derivatives, naphthalene derivatives, pentacene derivatives, phenanthrene compounds, fluoranthene compounds, and the like, and examples of the hetero ring-containing compound include carbazole derivatives, dibenzofuran derivatives, ladder-type furan compounds, pyrimidine derivatives, and the like, but the examples thereof are not limited thereto. Specifically, the compound represented by Chemical Formula 1 of the present invention may be used as the host of the light emitting layer, but is not limited thereto.

In an exemplary embodiment of the present specification, the light emitting layer includes the compound of Chemical Formula 1 as a host.

In an exemplary embodiment of the present specification, the light emitting layer includes the compound of Chemical Formula 1 as a host, and further includes one or more hosts different from the compound of Chemical Formula 1.

In an exemplary embodiment of the present specification, the host different from the compound of Chemical Formula 1 is a compound of the following Chemical Formula EN.

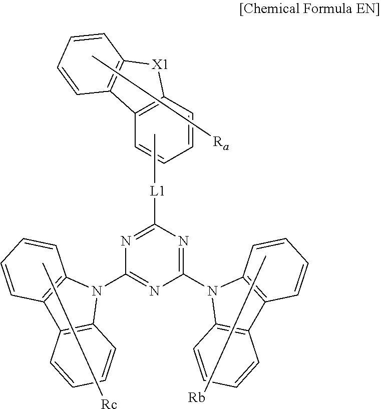

In Chemical Formula EN,
X1 is O or S,
L1 is a direct bond, or a substituted or unsubstituted arylene group, and
Ra to Rc are the same as or different from each other, and are each independently hydrogen; deuterium; a substituted or unsubstituted alkyl group; a substituted or unsubstituted aryl group; or a substituted or unsubstituted heteroaryl group.

In an exemplary embodiment of the present specification, Ra to Rc are the same as or different from each other, and are each independently hydrogen or deuterium.

In an exemplary embodiment of the present specification, Ra to Rc are the same as or different from each other, and are each independently hydrogen.

In an exemplary embodiment of the present specification, the compound of Chemical Formula EN is any one of the following compounds.

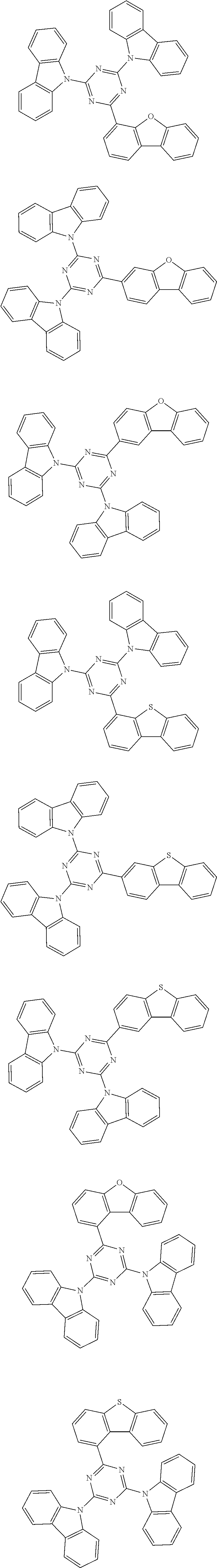

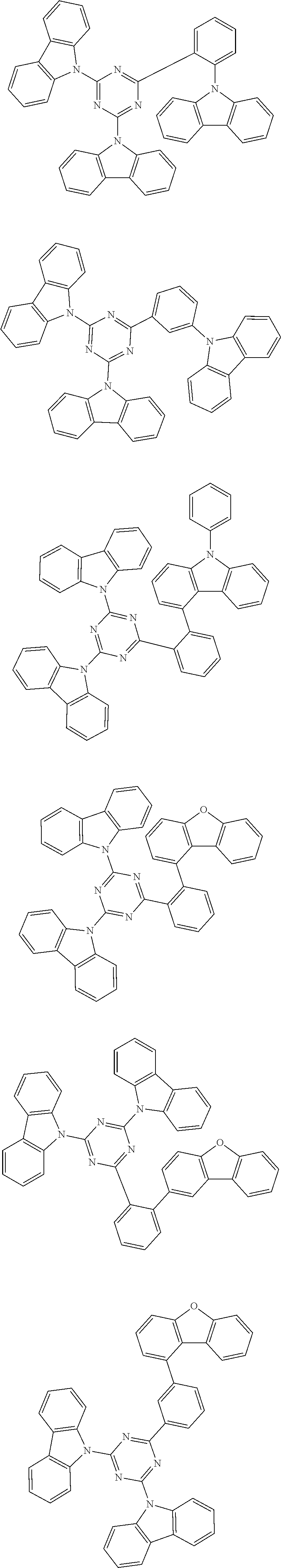

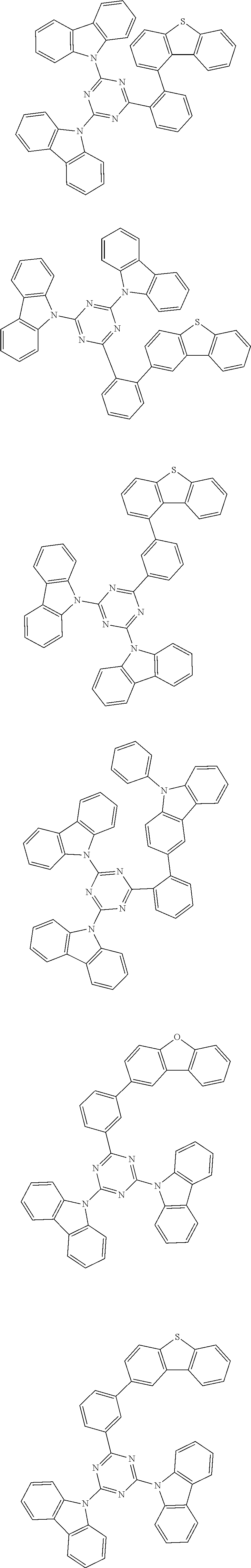

When the light emitting layer emits red light, phosphorescent materials such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr) or octaethylporphyrin platinum (PtOEP), or fluorescent materials such as tris(8-hydroxyquinolino)aluminum (Alq₃) may be used as the light emitting dopant, however, the light emitting dopant is not limited thereto. When the light emitting layer emits green light, it is possible to use a phosphorescent material such as tris(2-phenylpyridine) iridium (Ir(ppy)₃), or a fluorescent material such as Alq₃, as the light emitting dopant, but the light emitting dopant is not limited thereto. When the light emitting layer emits blue light, it is possible to use a phosphorescent material such as (4,6-F₂ppy)₂Irpic, or a fluorescent material such as spiro-DPVBi, spiro-6P, distyryl benzene (DSB), distyryl arylene (DSA), a pyrene-based compound, a PFO-based polymer or a poly(p-phenylenevinylene) (PPV)-based polymer as the light emitting dopant, but the light emitting dopant is not limited thereto. Further, a boron-based compound may be used as the light emitting dopant.

According to an exemplary embodiment of the present specification, the light emitting layer is a blue light emitting layer.

According to an exemplary embodiment of the present specification, the dopant is a metal complex compound.

According to an exemplary embodiment of the present specification, the dopant is a platinum complex compound.

According to an exemplary embodiment of the present specification, the dopant is an iridium complex compound.

According to an exemplary embodiment of the present specification, the dopant is the following Chemical Formula D-1 or D-2, but is not limited thereto.

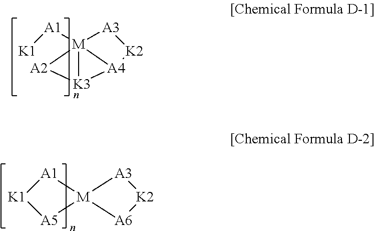

In Chemical Formulae D-1 and D-2,
M is a transition metal,
A1, A3, A5, A6, K1, K2, and K3 are the same as or different from each other, and are each independently a direct bond; O; S; a divalent ester group; a substituted or unsubstituted alkylene group; a substituted or unsubstituted divalent alkenyl group; a substituted or unsubstituted divalent allyl group; a substituted or unsubstituted arylene group; or a substituted or unsubstituted heteroarylene group,
A2 and A4 are the same as or different from each other, and are each independently a direct bond; N; a substituted or unsubstituted trivalent alkylene group; a substituted or unsubstituted trivalent aryl group; or a substituted or unsubstituted trivalent heteroaryl group, and
n is 1 or 2, and when n is 2, structures in the parentheses are the same as or different from each other.

According to an exemplary embodiment of the present specification, M is iridium or platinum.

According to an exemplary embodiment of the present specification, the dopant may be selected from the following compounds, but is not limited thereto.

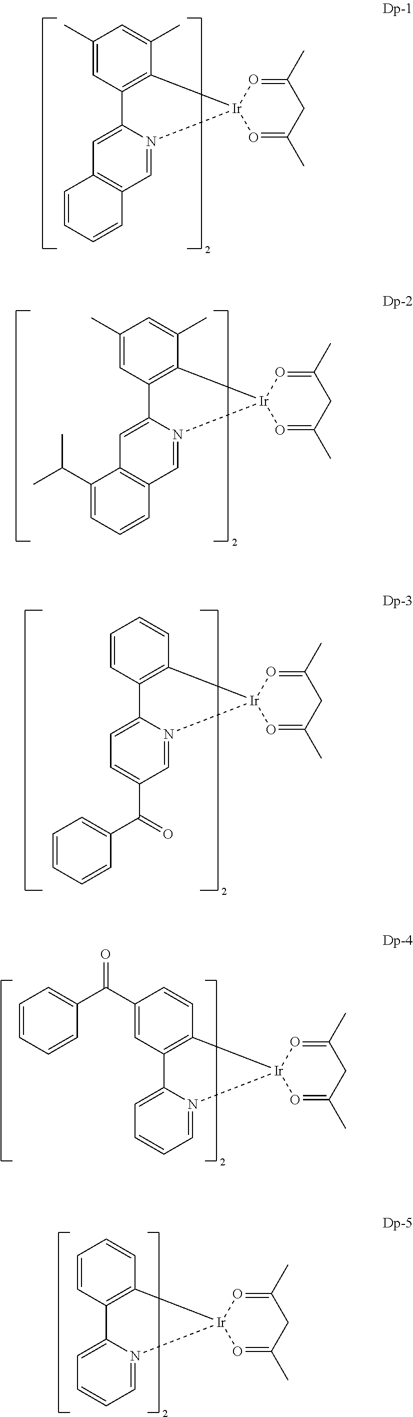

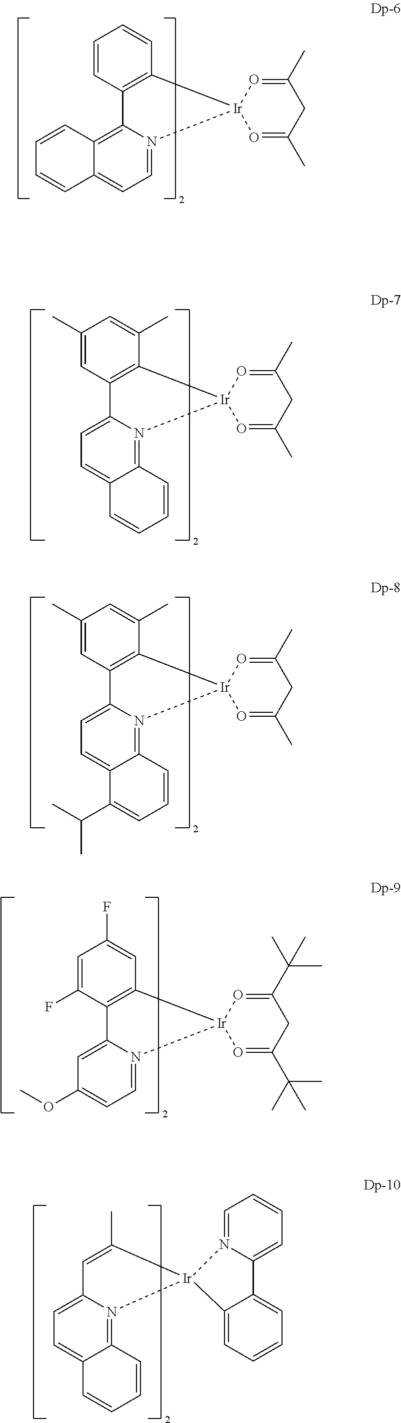

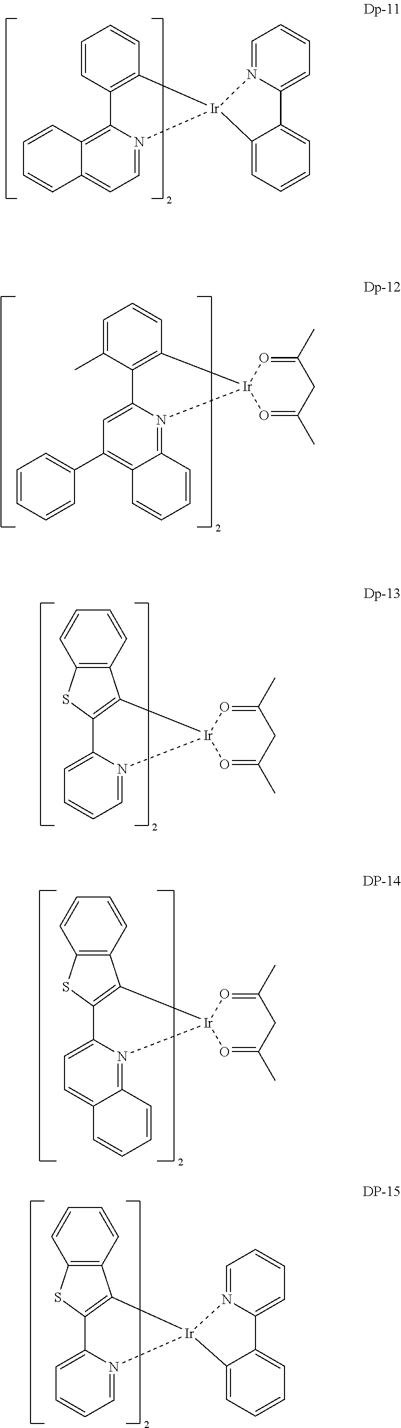

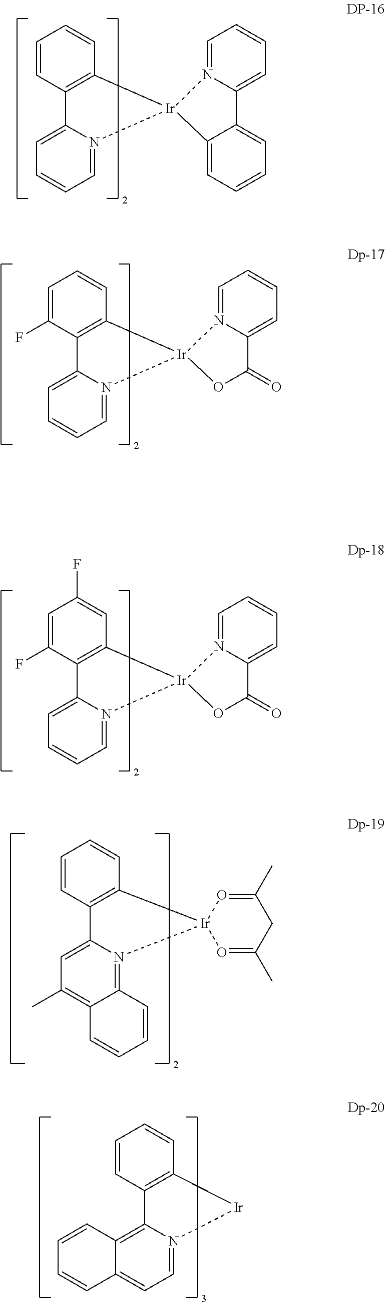

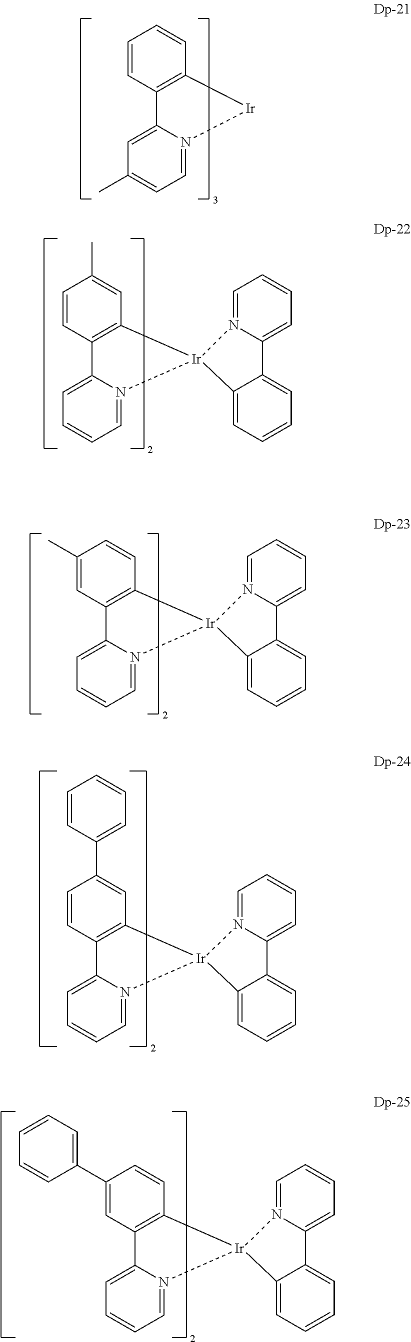

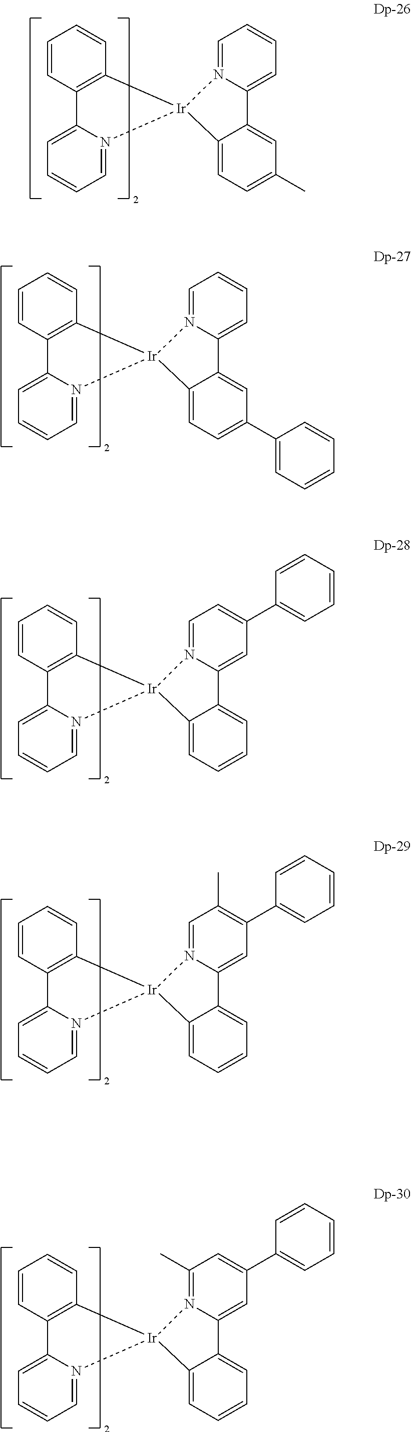

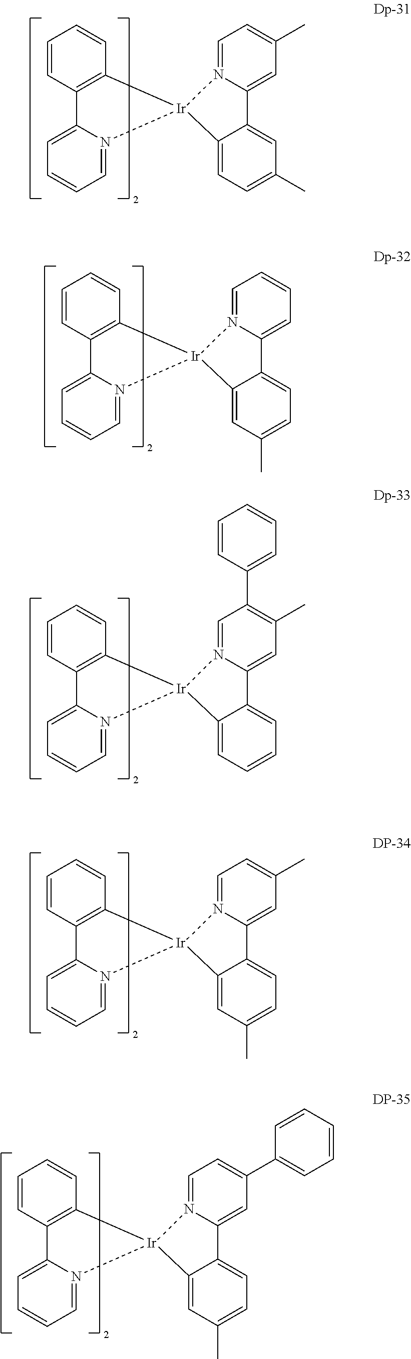

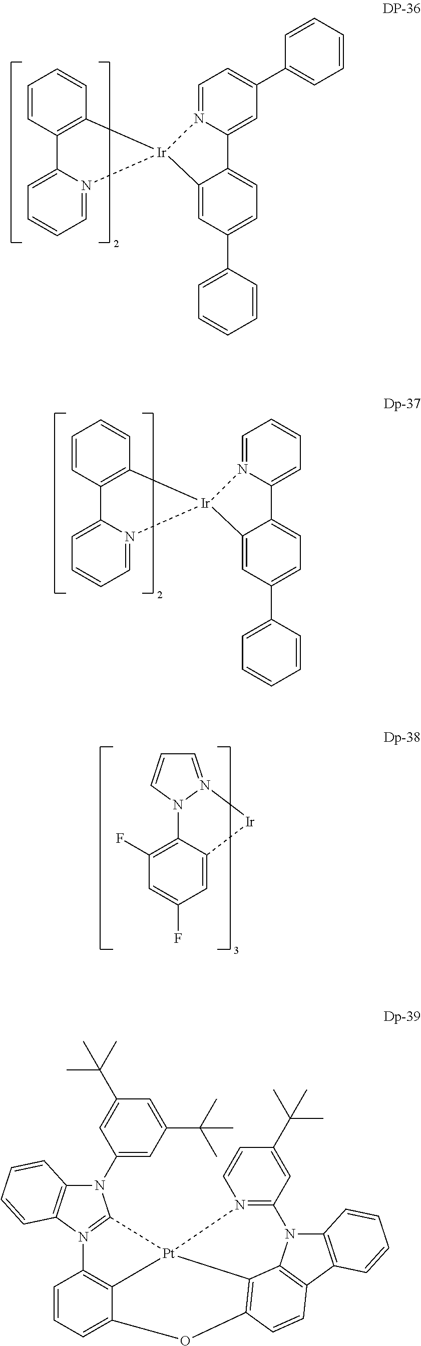

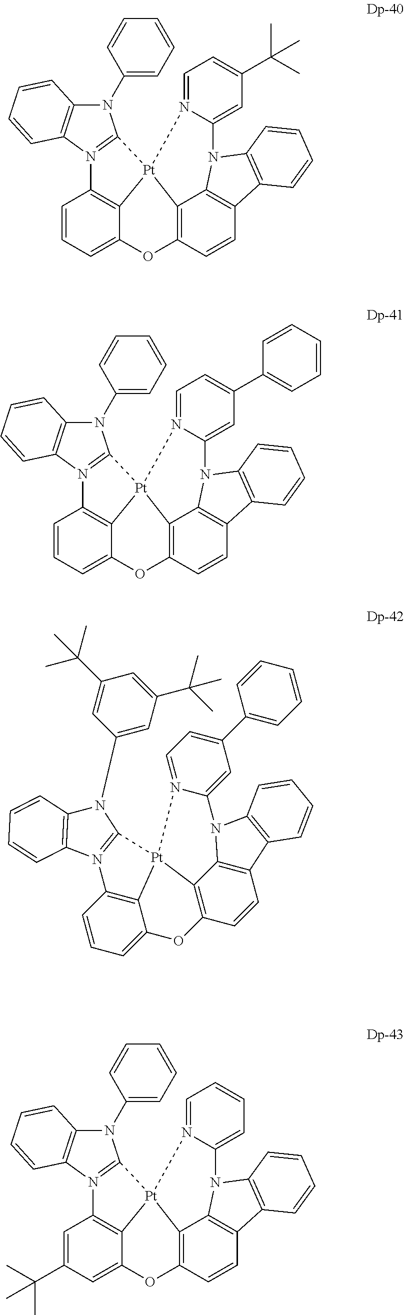

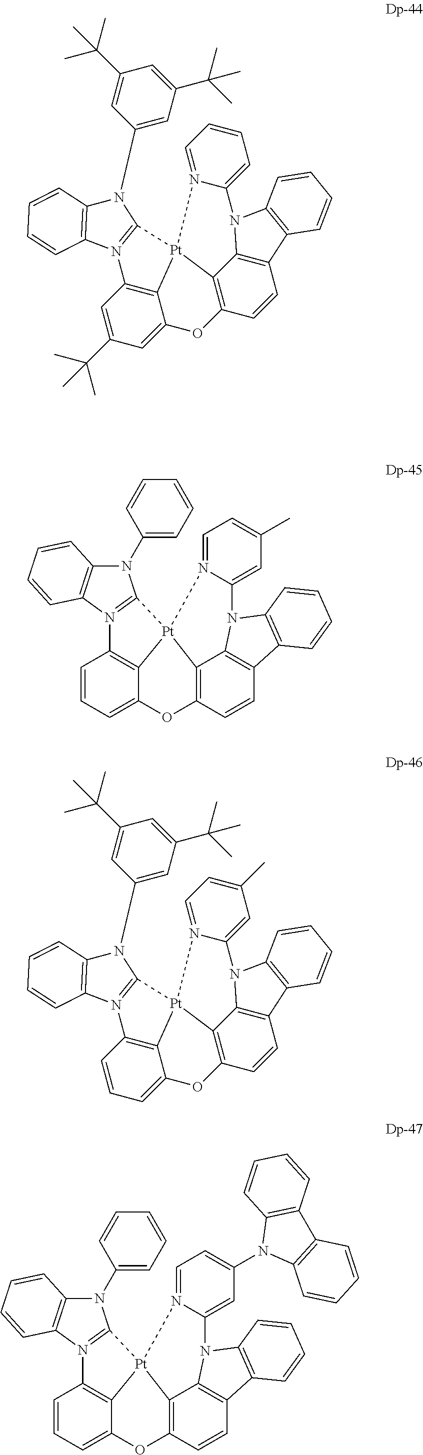

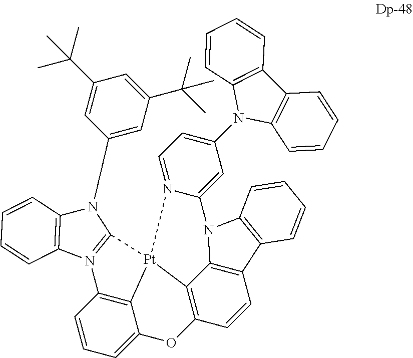

According to an exemplary embodiment of the present specification, the light emitting layer includes the compound of Chemical Formula 1 as a host of the light emitting layer, and includes the compound of Chemical Formula D-1 or D-2 as a dopant of the light emitting layer.

According to an exemplary embodiment of the present specification, the light emitting layer includes the compound of Chemical Formula 1 and the compound of Chemical Formula EN as hosts of the light emitting layer, and includes the compound of Chemical Formula D-1 or D-2 as a dopant of the light emitting layer. In this case, the compound of Chemical Formula 1 is a p-type host, and the compound of Chemical Formula EN is an n-type host.

According to an exemplary embodiment of the present invention, the weight ratio of the p-type host to the n-type host in the light emitting layer is 100:1 to 1:1. Specifically, the weight ratio is 90:1 to 1:1, 50:1 to 1:1, 30:1 to 1:1, 10:1 to 1:1 or 5:1 to 1:1.

According to an exemplary embodiment of the present specification, the light emitting layer includes the host and the dopant at a weight ratio of 99:1 to 1:99. Specifically, the light emitting layer includes the host and the dopant at a weight ratio of 99:1 to 50:50, and more specifically at a weight ratio of 99:1 to 85:15. In this case, when two or more are used as the host, the ratio is calculated based on the total weight of the host.

The hole blocking layer is layer blocking holes from reaching a cathode, and may be generally formed under the same condition as the hole injection layer. Specific examples of the hole blocking material include oxadiazole derivatives, triazole derivatives, triazine derivatives, phenanthroline derivatives, BCP, aluminum complexes, and the like, but are not limited thereto. Specifically, a triazine derivative may be used, but the present invention is not limited thereto. More specifically, the compound of Chemical Formula EN may be used for the hole blocking layer.

The electron transport layer may perform a role of smoothly transporting electrons. An electron transport material is suitably a material having high electron mobility which may proficiently accept electrons from a cathode and transfer the electrons to a light emitting layer. For example, specific examples of the electron transport material include: Al complexes of 8-hydroxyquinoline; complexes including Alq₃; organic radical compounds; hydroxyflavone-metal complexes; and the like, but are not limited thereto. The electron transport layer may have a thickness of 1 nm to 50 nm. When the electron transport layer has a thickness of 1 nm or more, there is an advantage in that it is possible to prevent electron transport characteristics from deteriorating, and when the electron transport layer has a thickness of 50 nm or less, there is an advantage in that it is possible to prevent the driving voltage from being increased in order to improve the movement of electrons due to the too thick electron transport layer.

The electron injection layer may perform a role of smoothly injecting electrons. An electron injection material is preferably a compound which has a capability of transporting electrons, an effect of injecting electrons from a cathode, and an excellent effect of injecting electrons into a light emitting layer or a light emitting material, prevents excitons produced from a light emitting layer from moving to a hole injection layer, and is excellent in the ability to form a thin film. For example, specific examples of the electron injection material include fluorenone, anthraquinodimethane, diphenoquinone, thiopyran dioxide, oxazole, oxadiazole, triazole, triazine, imidazole, perylene tetracarboxylic acid, fluorenylidene methane, anthrone or the like, and derivatives thereof, metal complex compounds, nitrogen-containing 5-membered ring derivatives, and the like, but are not limited thereto.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato) (o-cresolato)gallium, bis(2-methyl-8-quinolinato) (1-naphtholato)aluminum, bis(2-methyl-8-quinolinato) (2-naphtholato)gallium and the like, but are not limited thereto.

The electron transport layer and the electron injection layer may be formed of a single layer. For example, an electron injection and transport layer may be formed by simultaneously vacuum depositing an electron injection material and an electron transport material, or by vacuum depositing a material which simultaneously exhibits electron injection and transport effects.

The electron injection and transport layer includes a compound of the following Chemical Formula ET-1 or ET-2.

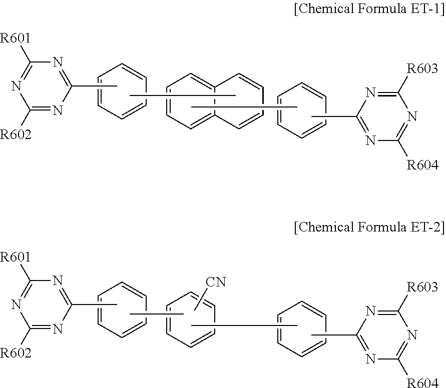

In Chemical Formula ET-1 or ET-2,
R601 to R604 are the same as or different from each other, and are each independently hydrogen; deuterium; a substituted or unsubstituted alkyl group; a substituted or unsubstituted aryl group; or a substituted or unsubstituted heterocyclic group.

In an exemplary embodiment of the present specification, R601 to R604 are the same as or different from each other, and are each independently a substituted or unsubstituted aryl group; or a substituted or unsubstituted heterocyclic group.

In an exemplary embodiment of the present specification, R601 to R604 are the same as or different from each other, and are each independently a substituted or unsubstituted aryl group.

In an exemplary embodiment of the present specification, R601 to R604 are the same as or different from each other, and are each independently a substituted or unsubstituted aryl group having 6 to 30 carbon atoms.

In an exemplary embodiment of the present specification, R601 to R604 are the same as or different from each other, and are each independently a substituted or unsubstituted aryl group having 6 to 20 carbon atoms.

In an exemplary embodiment of the present specification, R601 to R604 are the same as or different from each other, and are each independently a substituted or unsubstituted aryl group having 6 to 10 carbon atoms.

In an exemplary embodiment of the present specification, R601 to R604 are a phenyl group.

In an exemplary embodiment of the present specification, the compound of Chemical Formula ET-1 is any one of the following compounds.

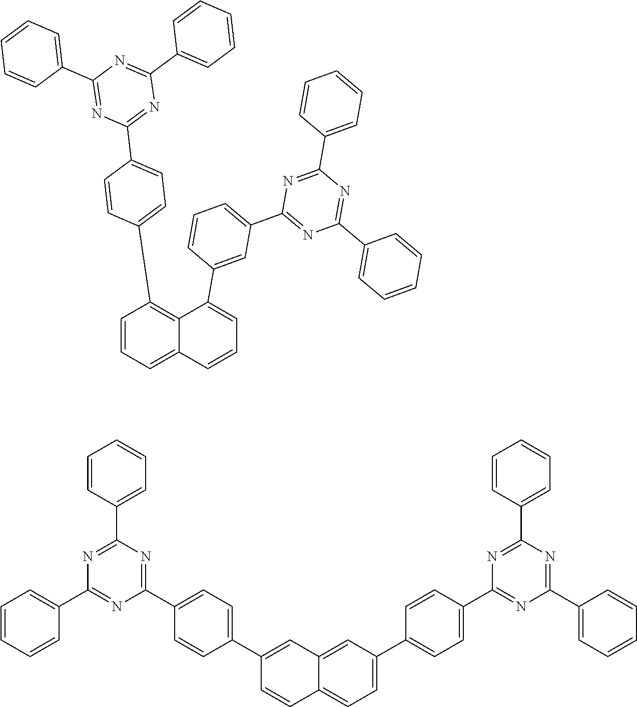 [SMILES: c1ccc(-c2nc(-c3ccccc3)nc(-c3ccc(-c4cccc5cccc(-c6cccc(-c7nc(-c8ccccc8)nc(-c8ccccc8)n7)c6)c45)cc3)n2)cc1 ; c1ccc(-c2nc(-c3ccccc3)nc(-c3ccc(-c4ccc5ccc(-c6ccc(-c7nc(-c8ccccc8)nc(-c8ccccc8)n7)cc6)cc5c4)cc3)n2)cc1]

The electron injection and transport layer may further include a metal complex. Examples of the metal complex include an Al complex of 8-hydroxyquinoline (Alq₃), LiQ, a metal complex compound, and the like, but are not limited thereto. For example, a triazine derivative and lithium quinolate (LiQ) may be used for the electron injection and transport layer, but are not limited thereto.

The organic light emitting device according to the present invention may be a top emission type, a bottom emission type, or a dual emission type according to the material to be used.

Furthermore, the organic light emitting device according to the present specification may be included and used in various electronic devices. For example, the electronic device may be a display panel, a touch panel, a solar module, a lighting device, and the like, and is not limited thereto.

### EXAMPLES

Hereinafter, the present specification will be described in detail with reference to Experimental Examples for specifically describing the present specification. However, the Examples according to the present specification may be modified in various forms, and it is not interpreted that the scope of the present application is limited to the Examples described in detail below. The Examples of the present application are provided to explain the present specification more completely to a person with ordinary skill in the art.

### <Preparation Example 1> Synthesis of Compound 1

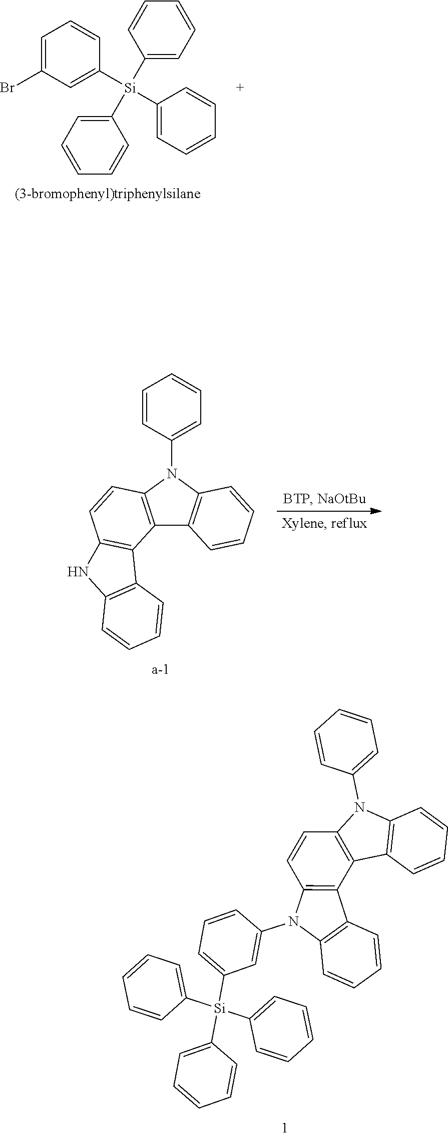 [SMILES: Brc1cccc([Si](c2ccccc2)(c2ccccc2)c2ccccc2)c1 ; c1ccc(-n2c3ccccc3c3c4c(ccc32)[nH]c2ccccc24)cc1 ; c1ccc(-n2c3ccccc3c3c4c5ccccc5n(-c5cccc([Si](c6ccccc6)(c6ccccc6)c6ccccc6)c5)c4ccc32)cc1]

After a compound (3-bromophenyl)triphenylsilane (5.50 g, 13.25 mmol) and Compound a-1 (4.84 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (BTP, 0.20 g, 0.4 mmol) was added thereinto, and then the resulting mixture was heated and stirred for 4 hours. The temperature was lowered to room temperature, the mixture was filtered to remove the base, and then the xylene was concentrated under reduced pressure, and the residue was recrystallized with 280 ml of ethyl acetate to prepare Compound 1 (6.21 g, 70%).

MS[M+H]⁺=667

### <Preparation Example 2> Synthesis of Compound 2

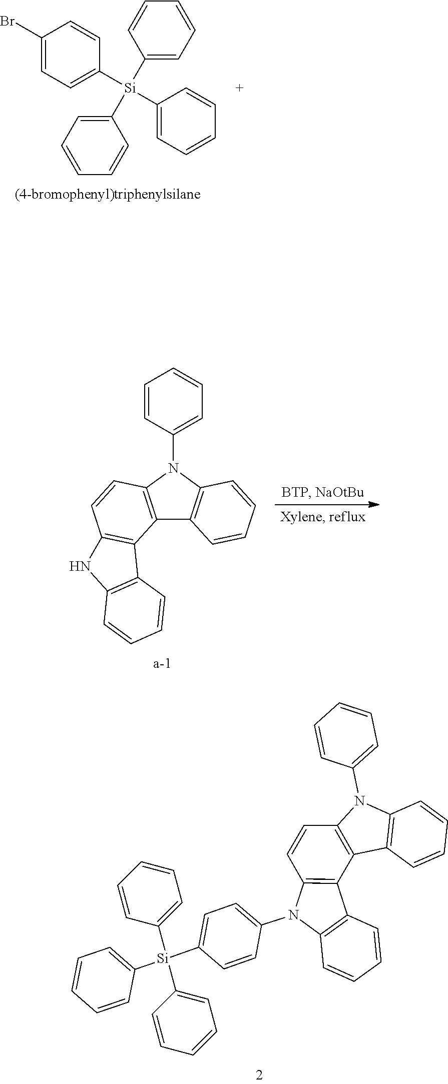 [SMILES: Brc1ccc([Si](c2ccccc2)(c2ccccc2)c2ccccc2)cc1 ; c1ccc(-n2c3ccccc3c3c4c(ccc32)[nH]c2ccccc24)cc1 ; c1ccc(-n2c3ccccc3c3c4c5ccccc5n(-c5ccc([Si](c6ccccc6)(c6ccccc6)c6ccccc6)cc5)c4ccc32)cc1]

After a compound (4-bromophenyl)triphenylsilane (5.50 g, 13.25 mmol) and Compound a-1 (4.84 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 5 hours. The temperature was lowered to room temperature, the mixture was filtered to remove the base, and then the xylene was concentrated under reduced pressure, and the residue was recrystallized with 330 ml of ethyl acetate to prepare Compound 2 (5.44 g, 62%).

MS[M+H]⁺=667

### <Preparation Example 3> Synthesis of Compound 3

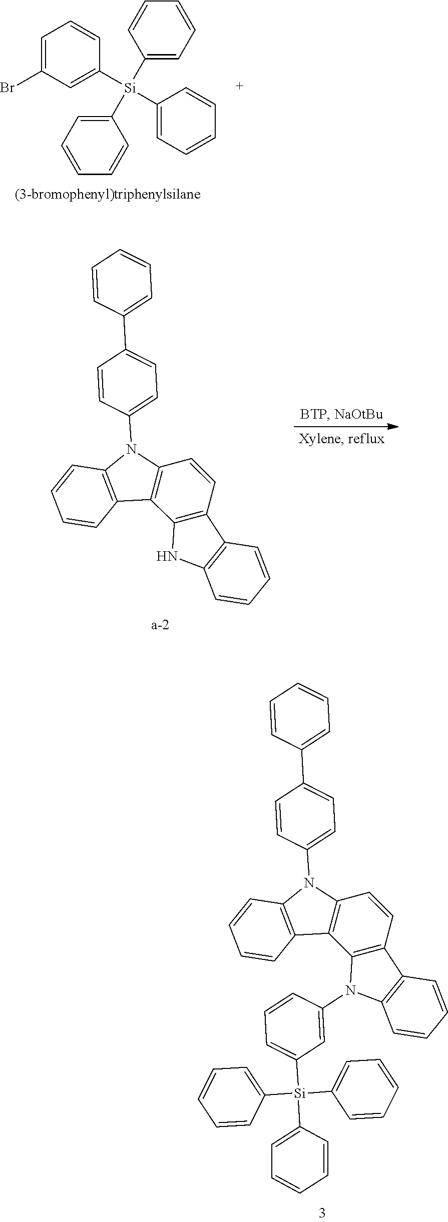 [SMILES: Brc1cccc([Si](c2ccccc2)(c2ccccc2)c2ccccc2)c1 ; c1ccc(-c2ccc(-n3c4ccccc4c4c5[nH]c6ccccc6c5ccc43)cc2)cc1 ; c1ccc(-c2ccc(-n3c4ccccc4c4c3ccc3c5ccccc5n(-c5cccc([Si](c6ccccc6)(c6ccccc6)c6ccccc6)c5)c34)cc2)cc1]

After a compound (3-bromophenyl)triphenylsilane (5.50 g, 13.25 mmol) and Compound a-2 (5.96 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 5 hours. The temperature was lowered to room temperature, the mixture was filtered to remove the base, and then the xylene was concentrated under reduced pressure, and the residue was recrystallized with 270 ml of ethyl acetate to prepare Compound 3 (7.11 g, 72%).

MS[M+H]⁺=744

### <Preparation Example 4> Synthesis of Compound 4

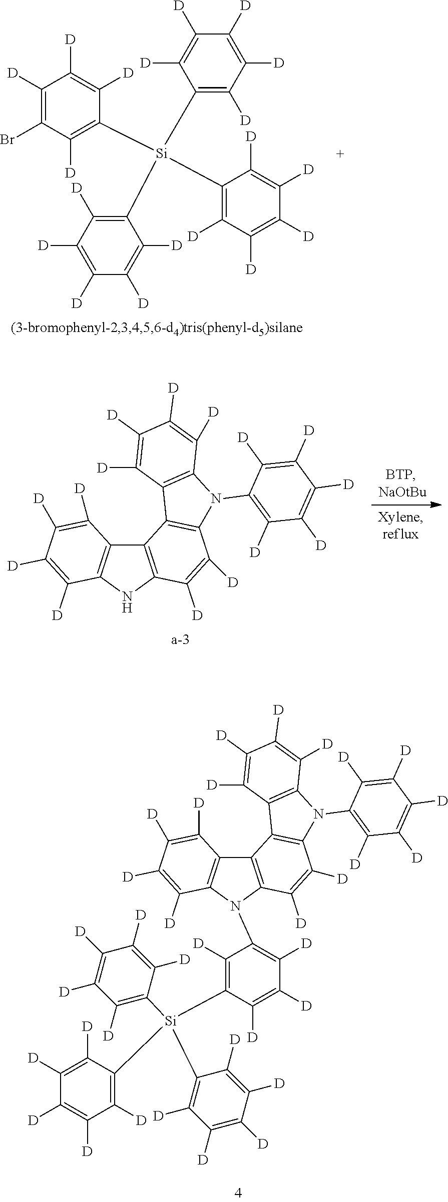

After a compound (3-bromophenyl-2,4,5,6-d4)tris(phenyl-d5)silane (5.50 g, 13.25 mmol) and Compound a-3 (5.96 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 3 hours. The temperature was lowered to room temperature, the mixture was filtered to remove the base, and then the xylene was concentrated under reduced pressure, and the residue was recrystallized with 260 ml of ethyl acetate to prepare Compound 4 (5.97 g, 61%).

MS[M+H]⁺=702

### <Preparation Example 5> Synthesis of Compound 5

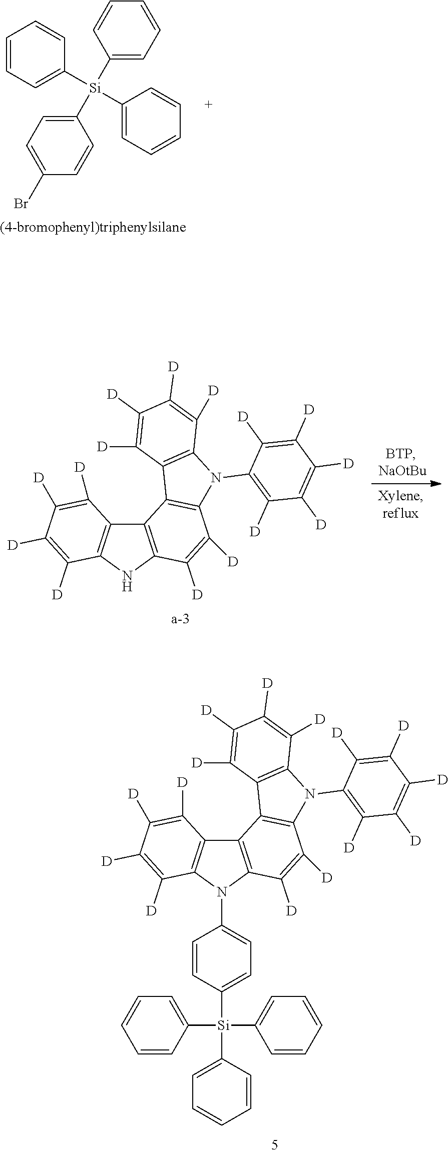 [SMILES: Brc1ccc([Si](c2ccccc2)(c2ccccc2)c2ccccc2)cc1 ; [2H]c1c([2H])c([2H])c(-n2c3c([2H])c([2H])c([2H])c([2H])c3c3c4c([nH]c5c([2H])c([2H])c([2H])c([2H])c54)c([2H])c([2H])c32)c([2H])c1[2H] ; [2H]c1c([2H])c([2H])c(-n2c3c([2H])c([2H])c([2H])c([2H])c3c3c4c5c([2H])c([2H])c([2H])c([2H])c5n(-c5ccc([Si](c6ccccc6)(c6ccccc6)c6ccccc6)cc5)c4c([2H])c([2H])c32)c([2H])c1[2H]]

After a compound (4-bromophenyl)triphenylsilane (5.50 g, 13.25 mmol) and Compound a-3 (5.96 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 3 hours. The temperature was lowered to room temperature, the mixture was filtered to remove the base, and then the xylene was concentrated under reduced pressure, and the residue was recrystallized with 260 ml of ethyl acetate to prepare Compound 5 (6.34 g, 64%).

MS[M+H]⁺=682

### <Preparation Example 6> Synthesis of Compound 6

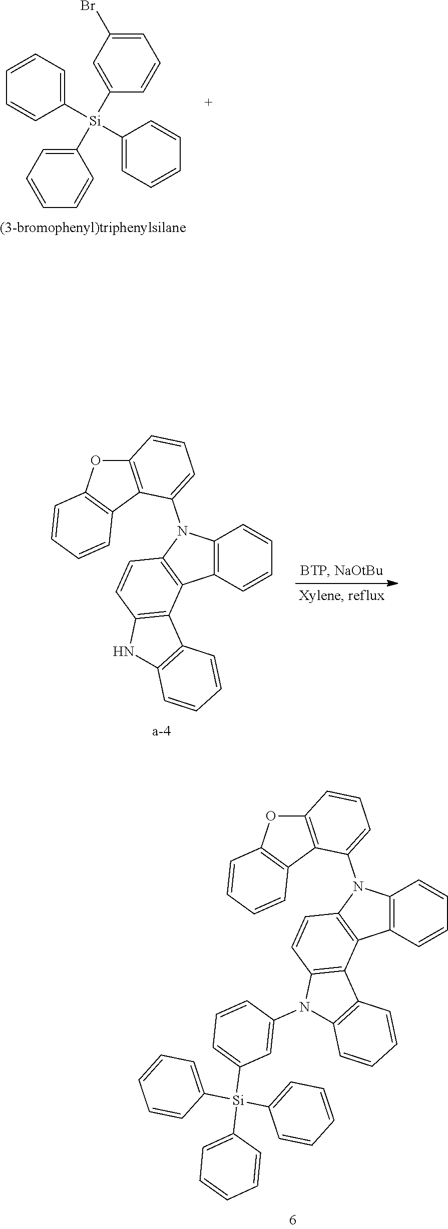 [SMILES: Brc1cccc([Si](c2ccccc2)(c2ccccc2)c2ccccc2)c1 ; c1ccc2c(c1)[nH]c1ccc3c(c4ccccc4n3-c3cccc4oc5ccccc5c34)c12 ; c1ccc([Si](c2ccccc2)(c2ccccc2)c2cccc(-n3c4ccccc4c4c5c6ccccc6n(-c6cccc7oc8ccccc8c67)c5ccc43)c2)cc1]

After a compound (3-bromophenyl)triphenylsilane (5.50 g, 13.25 mmol) and Compound a-4 (6.15 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 4 hours. The temperature was lowered to room temperature, the mixture was filtered to remove the base, and then the xylene was concentrated under reduced pressure, and the residue was recrystallized with 250 ml of ethyl acetate to prepare Compound 6 (6.58 g, 66%).

MS[M+H]⁺=757

### <Preparation Example 7> Synthesis of Compound 7

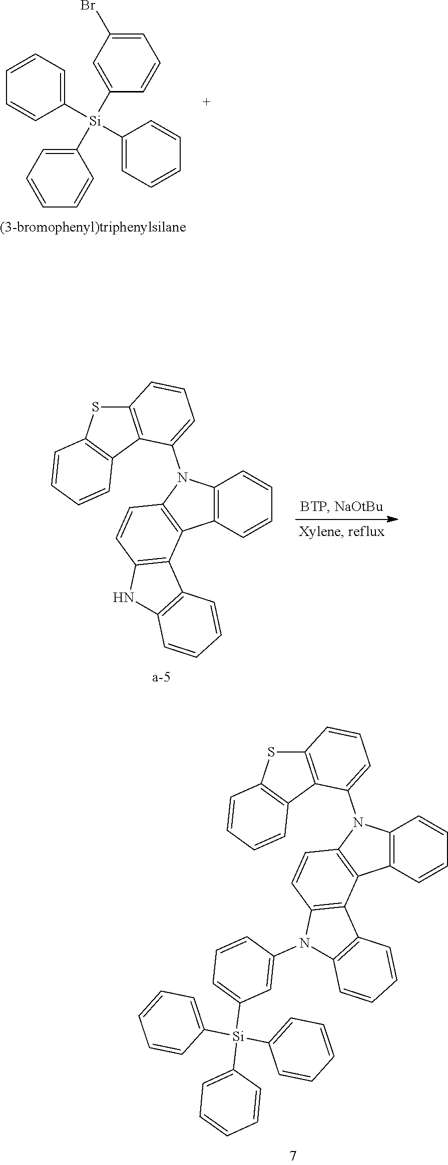 [SMILES: Brc1cccc([Si](c2ccccc2)(c2ccccc2)c2ccccc2)c1 ; c1ccc2c(c1)[nH]c1ccc3c(c4ccccc4n3-c3cccc4sc5ccccc5c34)c12 ; c1ccc([Si](c2ccccc2)(c2ccccc2)c2cccc(-n3c4ccccc4c4c5c6ccccc6n(-c6cccc7sc8ccccc8c67)c5ccc43)c2)cc1]

After a compound (3-bromophenyl)triphenylsilane (5.50 g, 13.25 mmol) and Compound a-5 (6.15 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 5 hours. The temperature was lowered to room temperature, the mixture was filtered to remove the base, and then the xylene was concentrated under reduced pressure, and the residue was recrystallized with 260 ml of ethyl acetate to prepare Compound 7 (5.94 g, 59%).

MS[M+H]⁺=774

### <Preparation Example 8> Synthesis of Compound 8

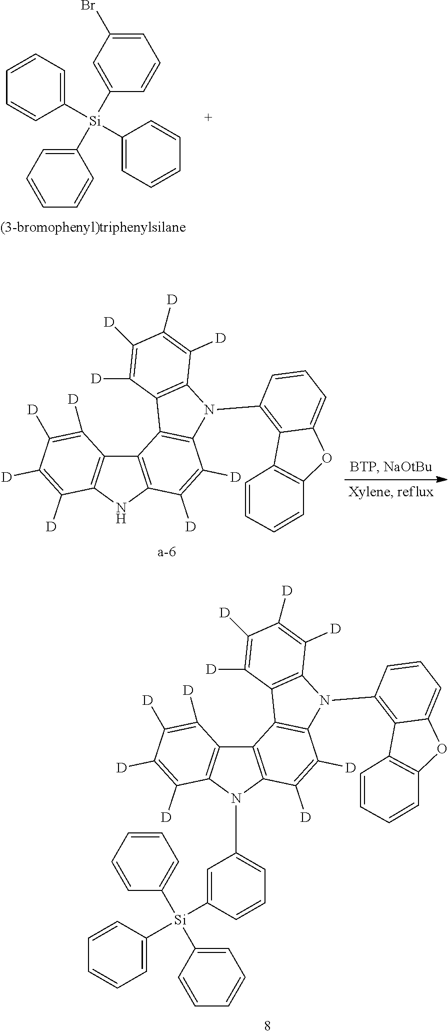 [SMILES: Brc1cccc([Si](c2ccccc2)(c2ccccc2)c2ccccc2)c1 ; [2H]c1c([2H])c([2H])c2c([nH]c3c([2H])c([2H])c4c(c5c([2H])c([2H])c([2H])c([2H])c5n4-c4cccc5oc6ccccc6c45)c32)c1[2H] ; [2H]c1c([2H])c([2H])c2c(c1[2H])c1c3c4c([2H])c([2H])c([2H])c([2H])c4n(-c4cccc5oc6ccccc6c45)c3c([2H])c([2H])c1n2-c1cccc([Si](c2ccccc2)(c2ccccc2)c2ccccc2)c1]

After a compound (3-bromophenyl)triphenylsilane (5.50 g, 13.25 mmol) and Compound a-6 (6.15 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 6 hours. The temperature was lowered to room temperature, the mixture was filtered to remove the base, and then the xylene was concentrated under reduced pressure, and the residue was recrystallized with 250 ml of ethyl acetate to prepare Compound 8 (6.51 g, 65%).

MS[M+H]⁺=768

### <Preparation Example 9> Synthesis of Compound 9

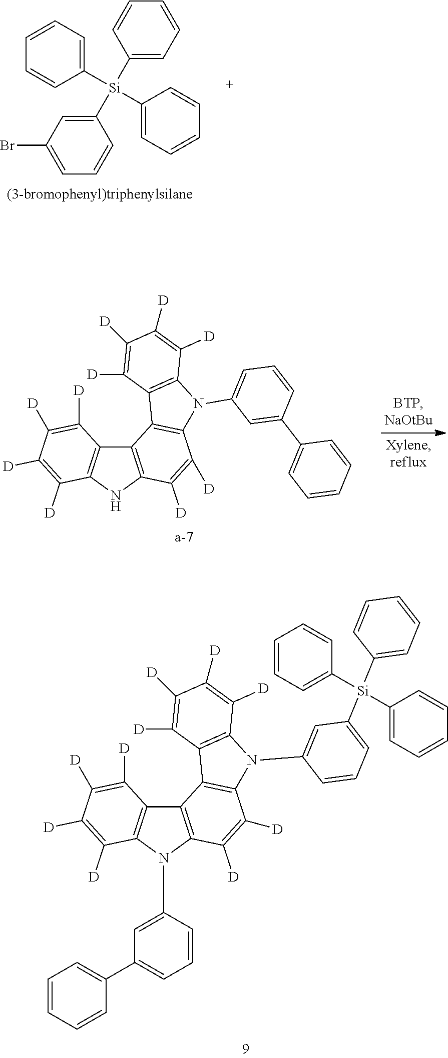 [SMILES: Brc1cccc([Si](c2ccccc2)(c2ccccc2)c2ccccc2)c1 ; [2H]c1c([2H])c([2H])c2c([nH]c3c([2H])c([2H])c4c(c5c([2H])c([2H])c([2H])c([2H])c5n4-c4cccc(-c5ccccc5)c4)c32)c1[2H] ; [2H]c1c([2H])c([2H])c2c(c1[2H])c1c3c4c([2H])c([2H])c([2H])c([2H])c4n(-c4cccc([Si](c5ccccc5)(c5ccccc5)c5ccccc5)c4)c3c([2H])c([2H])c1n2-c1cccc(-c2ccccc2)c1]

After a compound (3-bromophenyl)triphenylsilane (5.50 g, 13.25 mmol) and Compound a-7 (4.99 g, 14.58 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 3 hours. The temperature was lowered to room temperature, the mixture was filtered to remove the base, and then the xylene was concentrated under reduced pressure, and the residue was recrystallized with 240 ml of ethyl acetate to prepare Compound 9 (5.55 g, 62%).

MS[M+H]⁺=754

### <Preparation Example 10> Synthesis of Compound 10

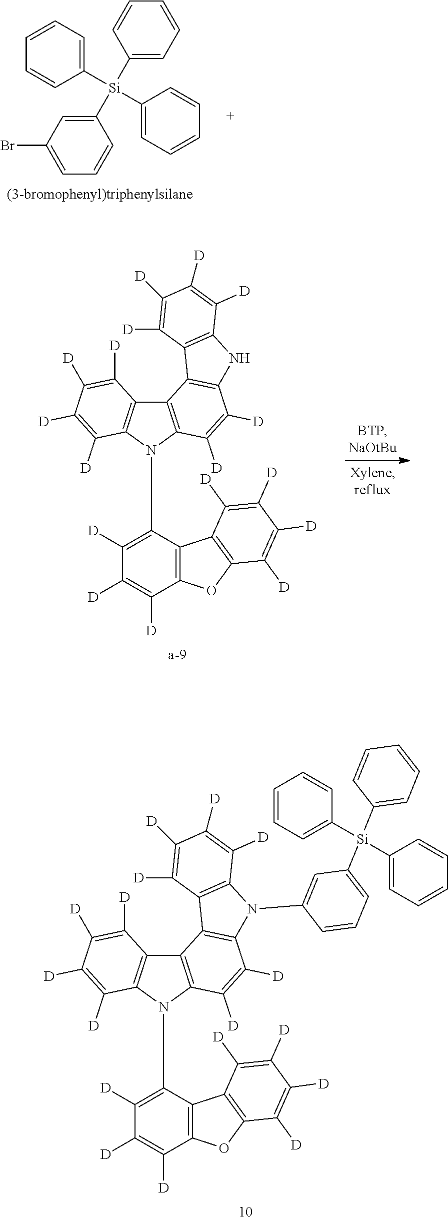 [SMILES: Brc1cccc([Si](c2ccccc2)(c2ccccc2)c2ccccc2)c1 ; [2H]c1c([2H])c([2H])c2c([nH]c3c([2H])c([2H])c4c(c5c([2H])c([2H])c([2H])c([2H])c5n4-c4c([2H])c([2H])c([2H])c5oc6c([2H])c([2H])c([2H])c([2H])c6c45)c32)c1[2H] ; [2H]c1c([2H])c([2H])c2c(oc3c([2H])c([2H])c([2H])c(-n4c5c([2H])c([2H])c([2H])c([2H])c5c5c6c7c([2H])c([2H])c([2H])c([2H])c7n(-c7cccc([Si](c8ccccc8)(c8ccccc8)c8ccccc8)c7)c6c([2H])c([2H])c54)c32)c1[2H]]

After a compound (3-bromophenyl)triphenylsilane (5.50 g, 8.55 mmol) and Compound a-9 (7.24 g, 15.28 mmol) were completely dissolved in 260 ml of xylene in a 500-mL round bottom flask under a nitrogen atmosphere, sodium tert-butoxide (NaOtBu) (1.91 g, 19.88 mmol) was added thereto, bis(tri-tert-butylphosphine) palladium(0) (0.20 g, 0.4 mmol) was added thereinto, and then the resulting mixture was heated and stirred for 3 hours. The temperature was lowered to room temperature, the mixture was filtered to remove the base, and then the xylene was concentrated under reduced pressure, and the residue was recrystallized with 290 ml of ethyl acetate to prepare Compound 10 (4.77 g, 58%).

MS[M+H]⁺=775

### Example 1-1

A glass substrate thinly coated with indium tin oxide (ITO) to have a thickness of 800 Å was put into distilled water in which a detergent was dissolved, and ultrasonically washed. In this case, a product manufactured by the Fischer Co., was used as the detergent, and distilled water twice filtered using a filter manufactured by Millipore Co., was used as the distilled water. After the ITO was washed for 30 minutes, ultrasonic washing was repeated twice by using distilled water for 10 minutes. After the washing using distilled water was completed, ultrasonic washing was conducted by using isopropyl alcohol, acetone, and methanol solvents, and the resulting product was dried and then transported to a plasma washing machine. The substrate was cleaned by using oxygen plasma for 5 minutes, and then was transported to a vacuum deposition machine.

Compounds of the following Compound HT1 and the following Compound HI1 were thermally vacuum deposited to have a thickness of 100 Å at a ratio of 98:2 (molar ratio) on the transparent ITO electrode that is an anode thus prepared, thereby forming a hole injection layer. A compound of the following Chemical Formula HT1 (300 Å) was vacuum deposited on the hole injection layer, thereby forming a hole transport layer. Subsequently, Compound 1 (p-type) synthesized in Preparation Example 1 was vacuum deposited to have a film thickness of 50 Å on the hole transport layer, thereby forming an electron blocking layer. Subsequently, on the electron blocking layer, a compound in which the following Chemical Formula BH (n-type) and Compound 1 (p-type) synthesized in Preparation Example 1 were mixed at 1:1 (a weight ratio) used as a host of the light emitting layer, and a compound of the following Chemical Formula BD as a dopant of the light emitting layer were vacuum deposited at a weight ratio of 88:12 to form a light emitting layer having a thickness of 300 Å. The following Chemical Formula BH (n-type) was vacuum deposited to have a film thickness of 50 Å on the light emitting layer, thereby forming a hole blocking layer. Subsequently, a compound of the following Chemical Formula ET1 and a compound of the following Chemical Formula LiQ were vacuum deposited at a weight ratio of 1:1 on the hole blocking layer, thereby forming an electron injection and transport layer having a thickness of 300 Å. Lithium fluoride (LiF) and aluminum were sequentially deposited on the electron injection and transport layer to have a thickness of 10 Å and 800 Å, respectively, thereby forming a cathode.

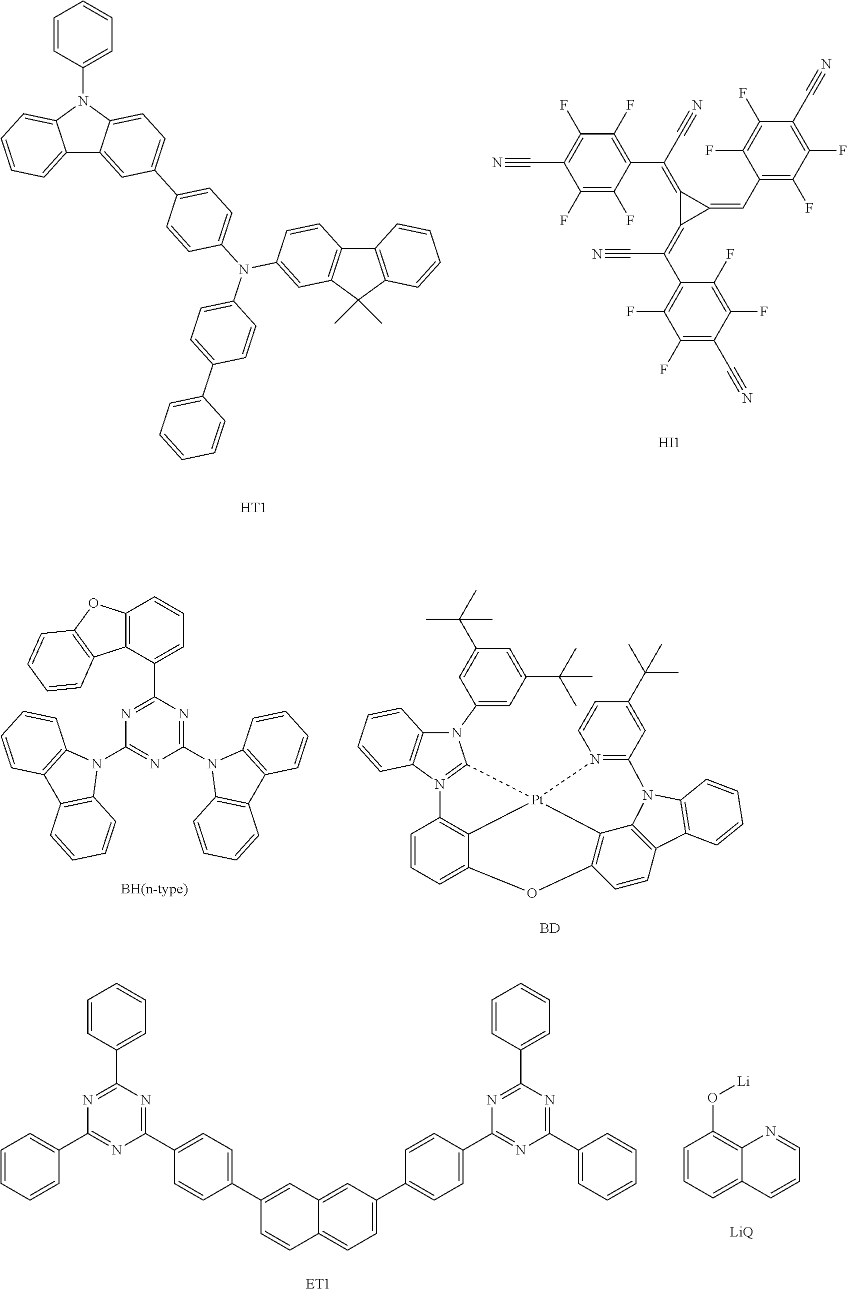

In the aforementioned procedure, the deposition rate of the organic material was maintained at 0.4 Å/sec to 0.7 Å/sec, the deposition rates of lithium fluoride and aluminum of the cathode were maintained at 0.3 Å/sec and at 2 Å/sec, respectively, and the degree of vacuum during the deposition was maintained at 2×10⁻⁷ to 5×10⁻⁶ torr, thereby manufacturing an organic light emitting device.

### Examples 1-2 to 1-10

Organic light emitting devices were manufactured in the same manner as in Example 1-1, except that compounds described in the following Table 1 were used instead of Compound 1 when the electron blocking layer and the light emitting layer were prepared in Example 1-1.

### Comparative Examples 1-1 to 1-6

Organic light emitting devices were manufactured in the same manner as in Example 1-1, except that compounds described in the following Table 1 were used instead of Compound 1 when the electron blocking layer and the light emitting layer were prepared in Example 1-1. The compounds of BH1 (p-type) to BH6 (p-type) used in the following Table 1 are as follows.

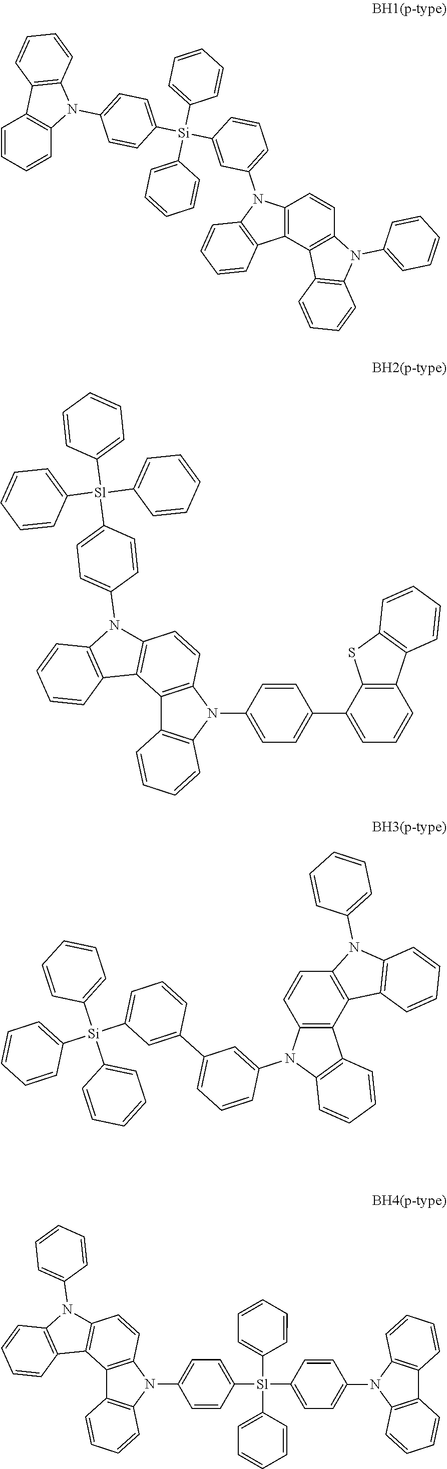

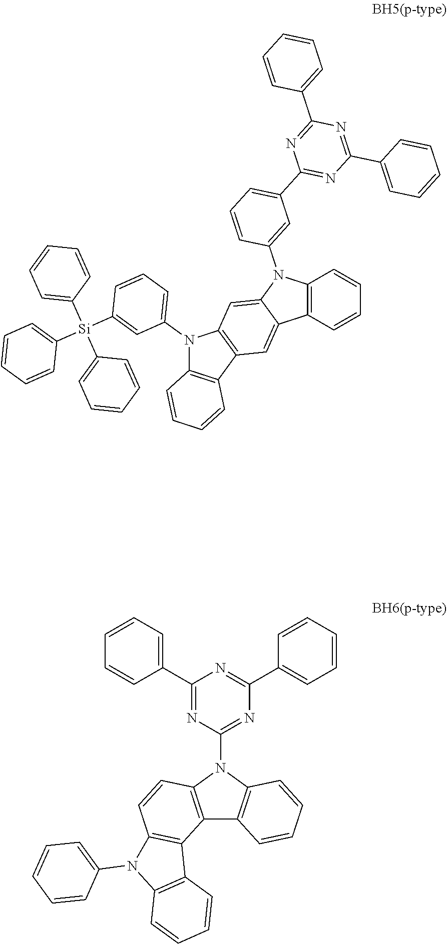 [SMILES: c1ccc(-c2nc(-c3ccccc3)nc(-c3cccc(-n4c5ccccc5c5cc6c7ccccc7n(-c7cccc([Si](c8ccccc8)(c8ccccc8)c8ccccc8)c7)c6cc54)c3)n2)cc1 ; c1ccc(-c2nc(-c3ccccc3)nc(-n3c4ccccc4c4c5c6ccccc6n(-c6ccccc6)c5ccc43)n2)cc1]

### Experimental Example 1

When current was applied to the organic light emitting devices manufactured in Examples 1-1 to 1-10 and Comparative Examples 1-1 to 1-6, the voltages, efficiencies, color coordinates, and service lives were measured, and the results are shown in the following Table 1.

In the following Table 1, T90 means the time taken for the luminance to decrease to 90% of the initial luminance (1600 nits), and the relative value is described based on Comparative Example 1-1.

TABLE 1

| | | voltage | efficiency | Color | |
|---|---|---|---|---|---|
| | Compound | (V@10 | (cd/A@10 | coordinate | |
| | (p-type host) | ma/cm²) | ma/cm²) | (x, y) | T90 |
| Example 1-1 | Compound 1 | 3.99 | 18.2 | (0.135, 0.155) | 128 |
| Example 1-2 | Compound 2 | 3.98 | 18.1 | (0.136, 0.154) | 122 |
| Example 1-3 | Compound 3 | 3.96 | 18.3 | (0.136, 0.156) | 127 |
| Example 1-4 | Compound 4 | 3.91 | 19.1 | (0.135, 0.151) | 182 |
| Example 1-5 | Compound 5 | 3.92 | 18.9 | (0.136, 0.153) | 167 |
| Example 1-6 | Compound 6 | 3.96 | 18.3 | (0.136, 0.155) | 112 |
| Example 1-7 | Compound 7 | 3.97 | 18.4 | (0.136, 0.156) | 115 |
| Example 1-8 | Compound 8 | 3.93 | 18.5 | (0.135, 0.154) | 148 |
| Example 1-9 | Compound 9 | 3.94 | 18.6 | (0.136, 0.156) | 152 |
| Example 1-10 | Compound 10 | 3.92 | 18.8 | (0.136, 0.156) | 173 |
| Comparative | BH1 | 4.24 | 16.6 | (0.134, 0.158) | 79 |
| Example 1-1 | | | | | |
| Comparative | BH2 | 4.28 | 16.9 | (0.135, 0.159) | 85 |
| Example 1-2 | | | | | |
| Comparative | BH3 | 4.36 | 16.7 | (0.134, 0.158) | 72 |
| Example 1-3 | | | | | |
| Comparative | BH4 | 4.32 | 16.8 | (0.136, 0.164) | 68 |
| Example 1-4 | | | | | |
| Comparative | BH5 | 4.81 | 8.1 | (0.136, 0.164) | 15 |
| Example 1-5 | | | | | |
| Comparative | BH6 | 4.92 | 6.3 | (0.136, 0.164) | 8 |
| Example 1-6 | | | | | |

As shown in Table 1, an organic light emitting device, in which the compound of Chemical Formula 1 of the present specification, in which -L1-SIR4R5R6 and Ar are bonded to the 8th position and the 5th position of an indolo[2,3-c]carbazole core, respectively, was used as a host (p-type) of an electron blocking layer and a light emitting layer, exhibited excellent characteristics in terms of the efficiency, driving voltage, and stability of the organic light emitting device. Specifically, Examples 1-1 to 1-10 of the present invention in which any one of Compounds 1 to 10 was used, in which by including -L1-SIR4R5R6, which is a bulky-structured silyl group to be involved in a conjugation system through a hyperconjugation effect, the excited and polaronic states of the compound are stabilized and by including an indolo[3,2-c]carbazole core to increase the LUMO energy level of the compound, the host-guest electrostatic bonding state of the organic material layer of an organic light emitting device including the compound is prevented, have better efficiency, driving voltage, and service life due to the above-described structural characteristics than Comparative Examples 1-1 to 1-6 in which the compound was not used. Although the preferred exemplary embodiments of the present invention have been described above, the present invention is not limited thereto, and can be implemented with various modifications within the scope of the claims and detailed description of the invention, and also falls within the scope of the invention.

1. A compound of the following Chemical Formula 1: 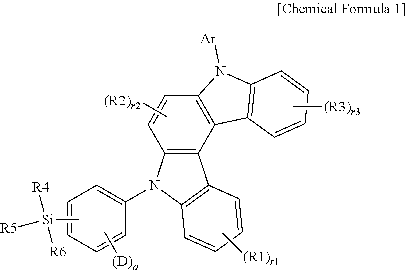
wherein, in Chemical Formula 1,
Ar is an aryl group having 6 to 18 carbon atoms, which is unsubstituted or substituted with at least one selected from the group consisting of deuterium, a cyano group, an alkyl group, a cycloalkyl group, and an aryl group, or a substituted or unsubstituted heteroaryl group having 2 to 18 carbon atoms, comprising at least one of O and S,
R1 to R3 are the same as or different from each other, and are each independently hydrogen, deuterium, or a substituted or unsubstituted aryl group,
R4 to R6 are the same as or different from each other, and are each independently an aryl group having 6 to 12 carbon atoms, which is unsubstituted or substituted with deuterium, or an alkyl group that is unsubstituted or substituted with deuterium,
r1 is an integer from 1 to 4, and when r1 is 2 or higher, two or more R1s are the same as or different from each other,
r2 is 1 or 2, and when r2 is 2, the two R2s are the same as or different from each other,
r3 is an integer from 1 to 4, and when r3 is 2 or higher, two or more R3s are the same as or different from each other, and
a is an integer from 0 to 4, and means the number of deuterium atoms represented by D.

2. The compound of claim 1, wherein R1 to R3 are the same as or different from each other, and are each independently hydrogen or deuterium.

3. The compound of claim 1, wherein Chemical Formula 1 is any one of the following Chemical Formulae 1-1 to 1-3: 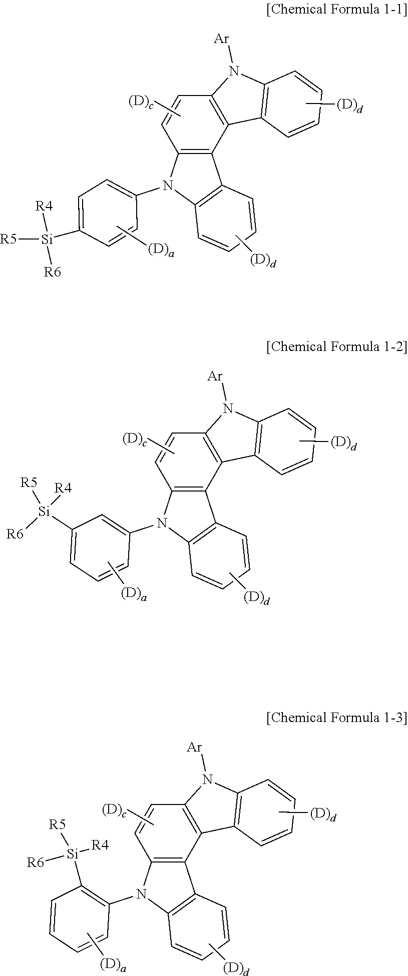
wherein in Chemical Formulae 1-1 to 1-3,
Ar, a, and R4 to R6 are the same as those defined in Chemical Formula 1, and
b and d are each an integer from 0 to 4, c is an integer from 0 to 2, and b to d each mean the number of deuterium atoms represented by D.

4. The compound of claim 1, wherein R4 to R6 are the same as or different from each other, and are each independently an aryl group having 6 to 12 carbon atoms, which is unsubstituted or substituted with deuterium.

5. The compound of claim 1, wherein Ar is any one of the following structures, and the following structures are unsubstituted or substituted with deuterium: 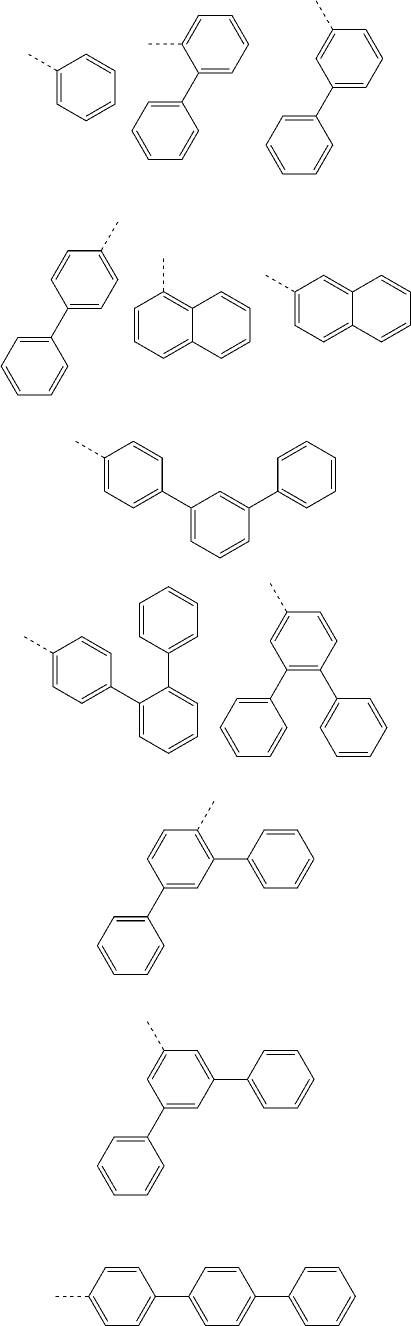 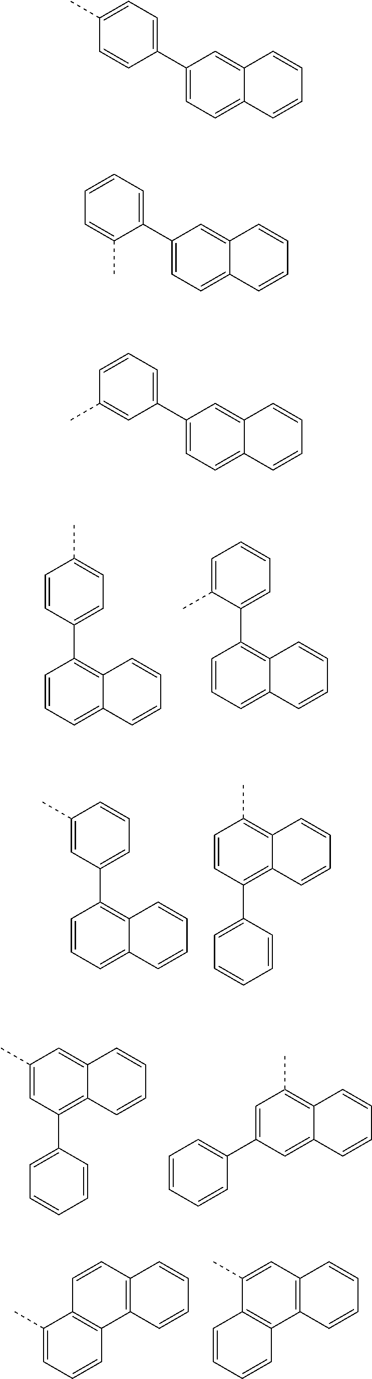 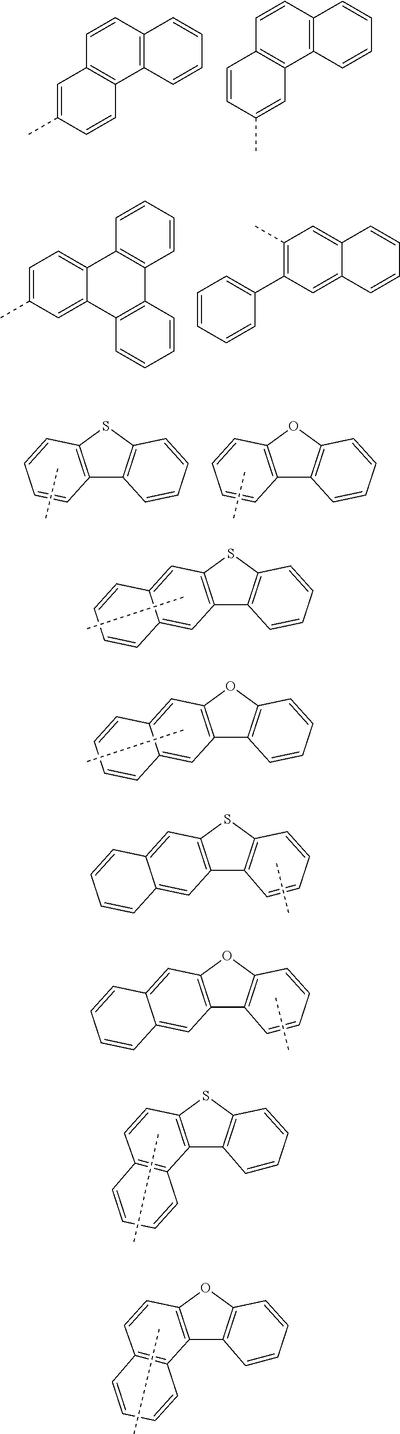 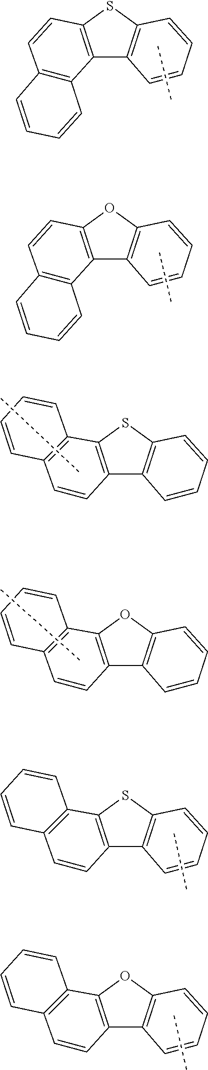
wherein in the structures, [symbol] is a moiety bonded to Chemical Formula 1.

6. The compound of claim 1, wherein the compound of Chemical Formula 1 is any one compound selected from among the following compounds:

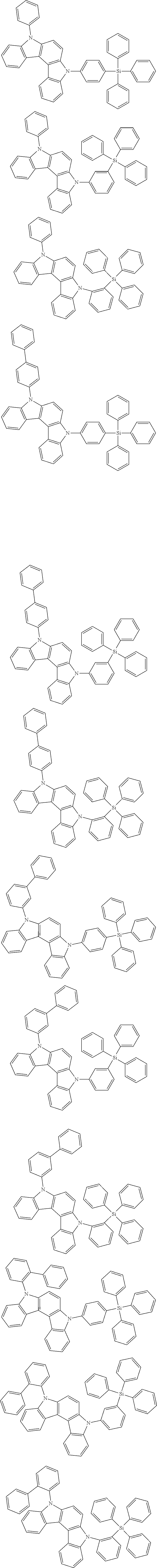

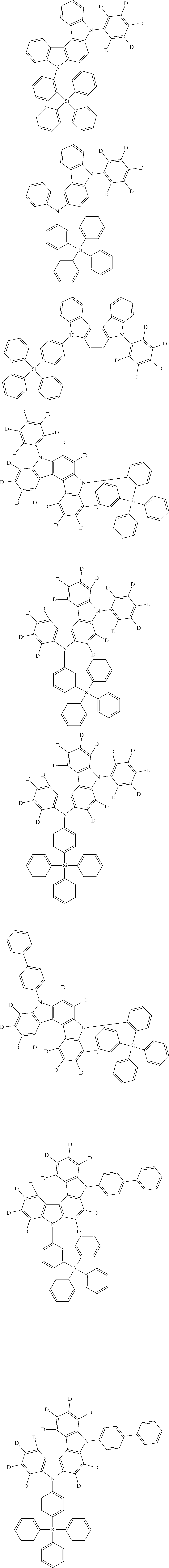

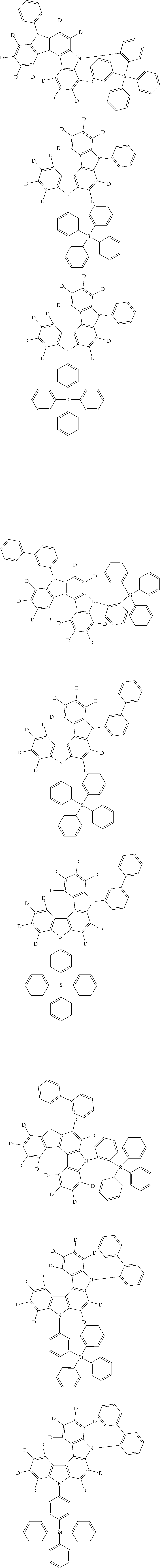

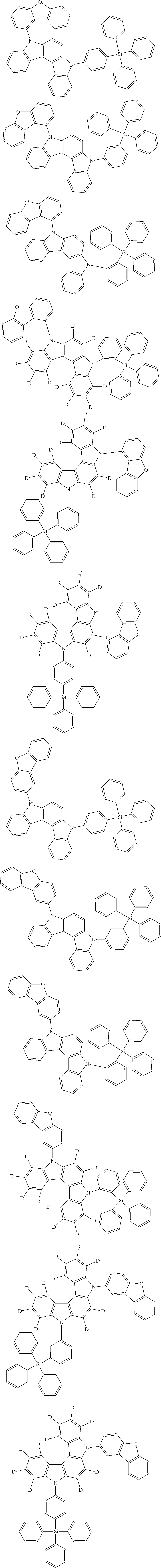

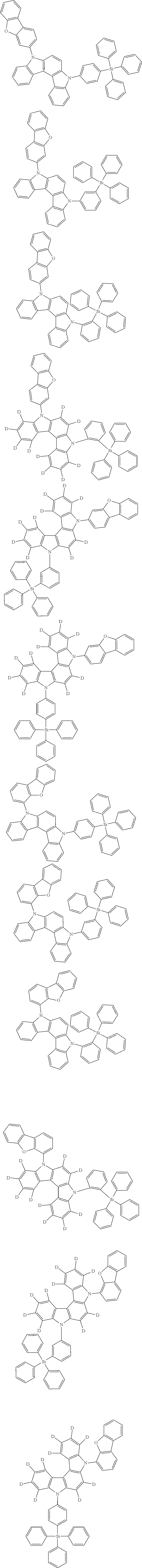

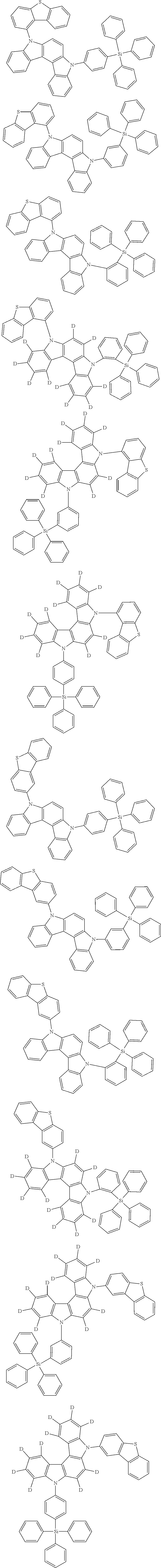

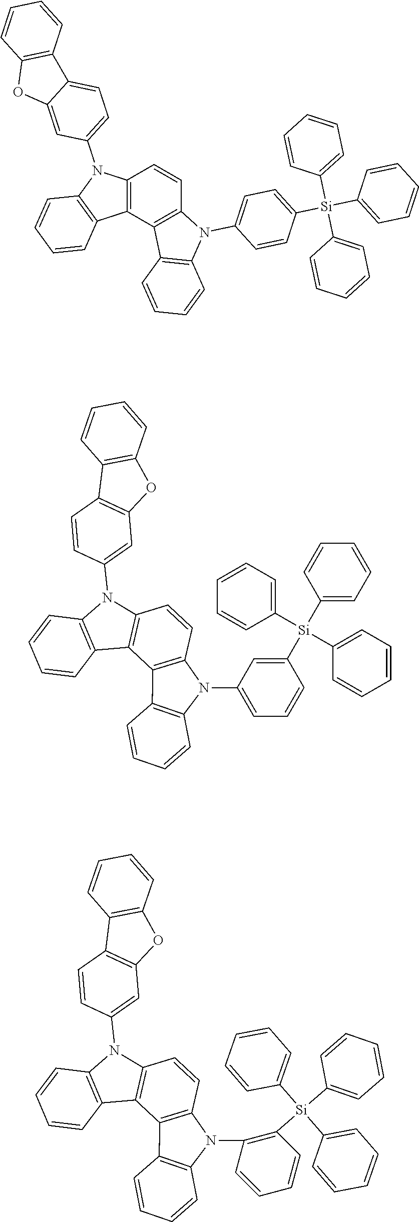 [SMILES: c1ccc([Si](c2ccccc2)(c2ccccc2)c2ccc(-n3c4ccccc4c4c5c6ccccc6n(-c6ccc7c(c6)oc6ccccc67)c5ccc43)cc2)cc1 ; c1ccc([Si](c2ccccc2)(c2ccccc2)c2cccc(-n3c4ccccc4c4c5c6ccccc6n(-c6ccc7c(c6)oc6ccccc67)c5ccc43)c2)cc1 ; c1ccc([Si](c2ccccc2)(c2ccccc2)c2ccccc2-n2c3ccccc3c3c4c5ccccc5n(-c5ccc6c(c5)oc5ccccc56)c4ccc32)cc1]

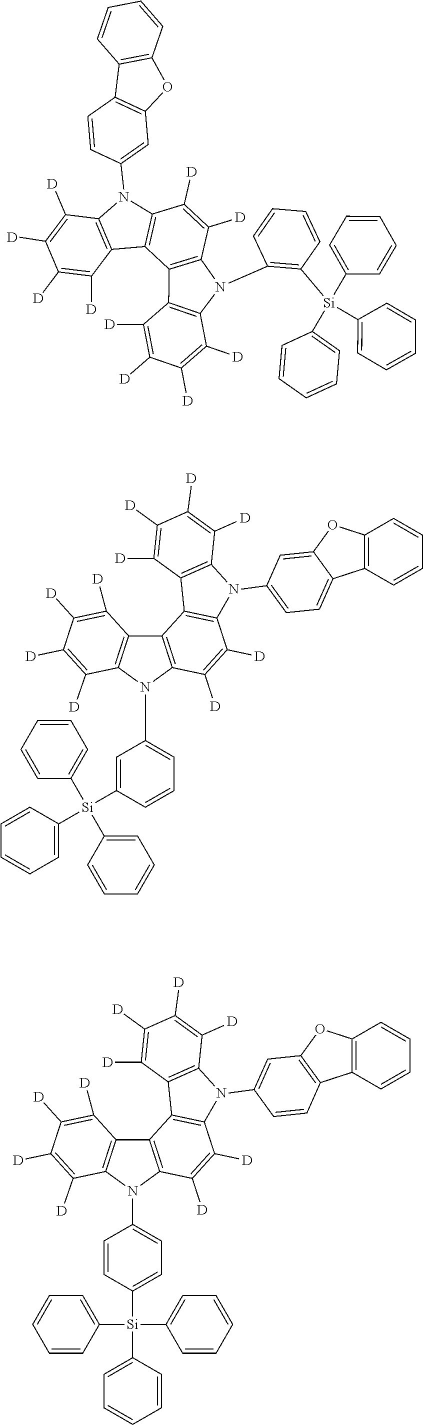 [SMILES: [2H]c1c([2H])c([2H])c2c(c1[2H])c1c3c4c([2H])c([2H])c([2H])c([2H])c4n(-c4ccccc4[Si](c4ccccc4)(c4ccccc4)c4ccccc4)c3c([2H])c([2H])c1n2-c1ccc2c(c1)oc1ccccc12 ; [2H]c1c([2H])c([2H])c2c(c1[2H])c1c3c4c([2H])c([2H])c([2H])c([2H])c4n(-c4ccc5c(c4)oc4ccccc45)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4ccc5c(c4)oc4ccccc45)c3c([2H])c([2H])c1n2-c1ccc([Si](c2ccccc2)(c2ccccc2)c2ccccc2)cc1]

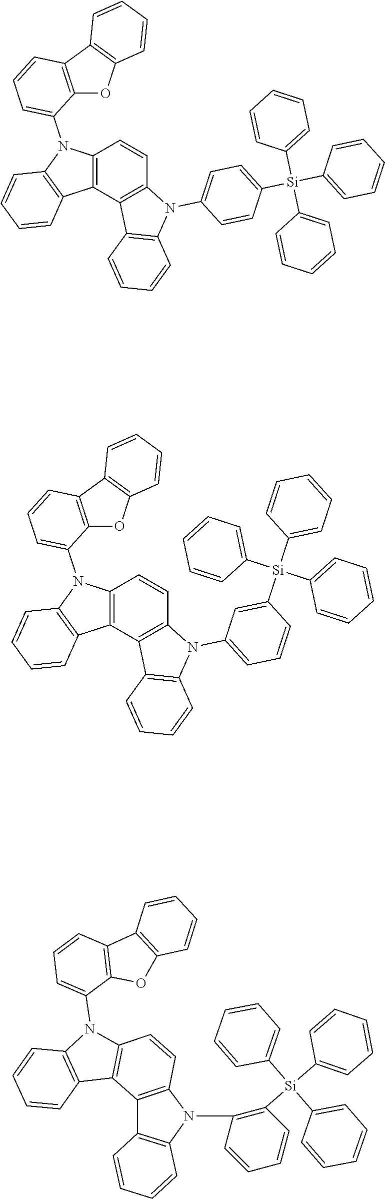 [SMILES: c1ccc([Si](c2ccccc2)(c2ccccc2)c2ccc(-n3c4ccccc4c4c5c6ccccc6n(-c6cccc7c6oc6ccccc67)c5ccc43)cc2)cc1 ; c1ccc([Si](c2ccccc2)(c2ccccc2)c2cccc(-n3c4ccccc4c4c5c6ccccc6n(-c6cccc7c6oc6ccccc67)c5ccc43)c2)cc1 ; c1ccc([Si](c2ccccc2)(c2ccccc2)c2ccccc2-n2c3ccccc3c3c4c5ccccc5n(-c5cccc6c5oc5ccccc56)c4ccc32)cc1]

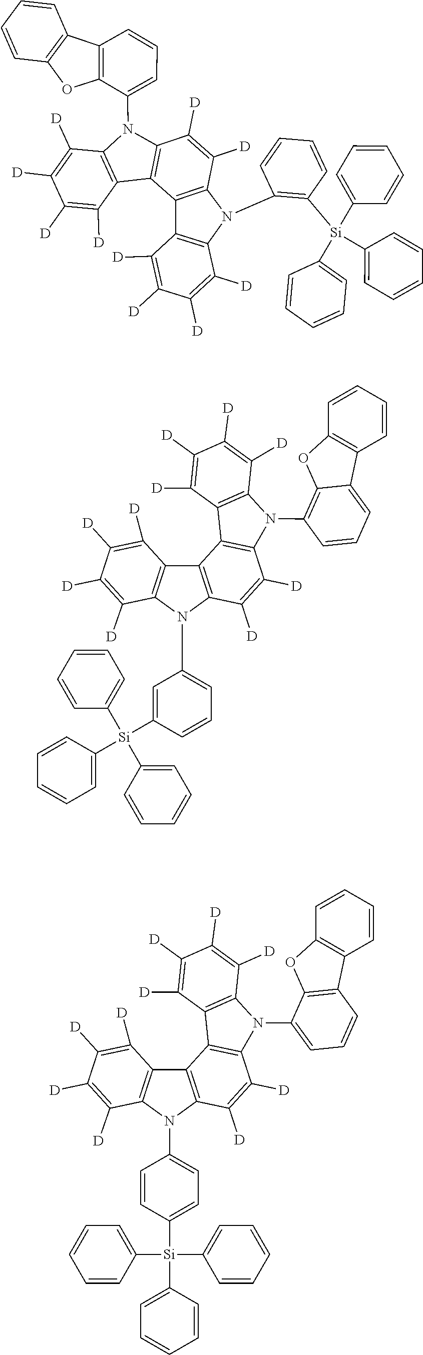 [SMILES: [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1ccccc1[Si](c1ccccc1)(c1ccccc1)c1ccccc1 ; [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1cccc([Si](c2ccccc2)(c2ccccc2)c2ccccc2)c1 ; [2H]c1c([2H])c([2H])c2c(c1[2H])c1c3c4c([2H])c([2H])c([2H])c([2H])c4n(-c4cccc5c4oc4ccccc45)c3c([2H])c([2H])c1n2-c1ccc([Si](c2ccccc2)(c2ccccc2)c2ccccc2)cc1]

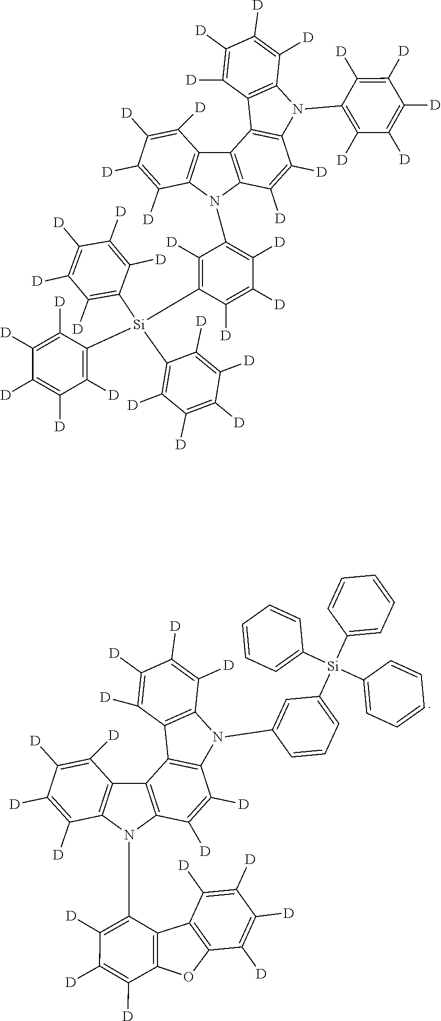 [SMILES: [2H]c1c([2H])c([2H])c(-n2c3c([2H])c([2H])c([2H])c([2H])c3c3c4c5c([2H])c([2H])c([2H])c([2H])c5n(-c5c([2H])c([2H])c([2H])c([Si](c6c([2H])c([2H])c([2H])c([2H])c6[2H])(c6c([2H])c([2H])c([2H])c([2H])c6[2H])c6c([2H])c([2H])c([2H])c([2H])c6[2H])c5[2H])c4c([2H])c([2H])c32)c([2H])c1[2H] ; [2H]c1c([2H])c([2H])c2c(oc3c([2H])c([2H])c([2H])c(-n4c5c([2H])c([2H])c([2H])c([2H])c5c5c6c7c([2H])c([2H])c([2H])c([2H])c7n(-c7cccc([Si](c8ccccc8)(c8ccccc8)c8ccccc8)c7)c6c([2H])c([2H])c54)c32)c1[2H]]

7. An organic light emitting device comprising:
an anode;
a cathode; and
one or more organic material layers provided between the anode and the cathode,
wherein one or more layers of the one or more organic material layers comprise the compound of Chemical Formula 1 of claim 1.

8. The organic light emitting device of claim 7, wherein one of the one or more layers comprising the compound of Chemical Formula 1 is an electron blocking layer or a light emitting layer.

9. The organic light emitting device of claim 7, wherein one of the one or more layers comprising the compound of Chemical Formula 1 is a light emitting layer, and the light emitting layer comprises the compound as a host.

10. The organic light emitting device of claim 9, wherein the light emitting layer further comprises one or more hosts different from the compound of Chemical Formula 1.

11. The organic light emitting device of claim 10, wherein the host different from the compound of Chemical Formula 1 is a compound of the following Chemical Formula EN: 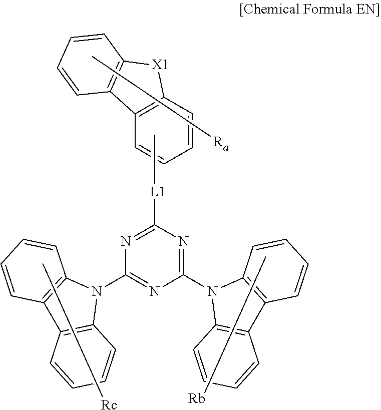
wherein in Chemical Formula EN,
X1 is O or S,
L1 is a direct bond or a substituted or unsubstituted arylene group, and
Ra to Rc are the same as or different from each other, and are each independently hydrogen, deuterium, a substituted or unsubstituted alkyl group, a substituted or unsubstituted aryl group, or a substituted or unsubstituted heteroaryl group.
